(19) United States
(12) Patent Application Publication
(10) Pub. No.: US 2025/0150092 A1
(43) Pub. Date: May 8, 2025

(54) APPLICATION ACCELERATION IN CLOSED NETWORK SYSTEMS

(71) Applicant: AtomBeam Technologies Inc., Moraga, CA (US)

(72) Inventors: Joshua Cooper, Columbia, SC (US); Julius D'Souza, New York, NY (US)

(21) Appl. No.: 19/017,327

(22) Filed: Jan. 10, 2025

Related U.S. Application Data
(63) Continuation-in-part of application No. 18/809,587, filed on Aug. 20, 2024.
Application No. 18/809,587 is a continuation of application No. 18/657,719, filed on May 7, 2024, now Pat. No. 12,166,506.
Application No. 18/657,719 is a continuation-in-part of application No. 18/423,287, filed on Jan. 25, 2024, now Pat. No. 12,218,696.
Application No. 18/423,287 is a continuation of application No. 18/501,987, filed on Nov. 4, 2023, now Pat. No. 11,967,974.
Application No. 18/501,987 is a continuation-in-part of application No. 18/190,044, filed on Mar. 24, 2023, now Pat. No. 11,831,343.
Application No. 18/190,044 is a continuation-in-part of application No. 17/875,201, filed on Jul. 27, 2022, now Pat. No. 11,700,013.
Application No. 17/875,201 is a continuation of application No. 17/514,913, filed on Oct. 29, 2021, now Pat. No. 11,424,760.
Application No. 17/514,913 is a continuation-in-part of application No. 17/404,699, filed on Aug. 17, 2021, now Pat. No. 11,385,794.
Application No. 17/404,699 is a continuation-in-part of application No. 16/455,655, filed on Jun. 27, 2019, now Pat. No. 10,509,771.
Application No. 16/455,655 is a continuation-in-part of application No. 16/200,466, filed on Nov. 26, 2018, now Pat. No. 10,476,519.
Application No. 16/200,466 is a continuation-in-part of application No. 15/975,741, filed on May 9, 2018, now Pat. No. 10,303,391.
Application No. 17/875,201 is a continuation of application No. 17/458,747, filed on Aug. 27, 2021, now Pat. No. 11,422,978.
Application No. 17/458,747 is a continuation-in-part of application No. 16/923,039, filed on Jul. 7, 2020, now Pat. No. 11,232,076.
Application No. 16/923,039 is a continuation-in-part of application No. 16/716,098, filed on Dec. 16, 2019, now Pat. No. 10,706,018.
Application No. 16/716,098 is a continuation of application No. 16/455,655, filed on Jun. 27, 2019, now Pat. No. 10,509,771.
Application No. 16/455,655 is a continuation-in-part of application No. 17/727,913, filed on Apr. 25, 2022, now Pat. No. 11,620,051.
Application No. 17/727,913 is a continuation of application No. 17/404,699, filed on Aug. 17, 2021, now Pat. No. 11,385,794.
Application No. 18/657,719 is a continuation-in-part of application No. 18/410,980, filed on Jan. 11, 2024, now Pat. No. 12,068,761.
Application No. 18/410,980 is a continuation-in-part of application No. 18/537,728, filed on Dec. 12, 2023, now Pat. No. 12,058,333.
(60) Provisional application No. 62/578,824, filed on Oct. 30, 2017.
(60) Provisional application No. 63/027,166, filed on May 19, 2020.
(60) Provisional application No. 62/926,723, filed on Oct. 28, 2019.
(60) Provisional application No. 63/388,411, filed on Jul. 12, 2022.

(51) Int. Cl. H03M 7/30; G06N 20/00

(52) U.S. Cl. CPC H03M 7/3059; G06N 20/00; H03M 7/6005

(57) ABSTRACT

A system and method for accelerating applications in closed networks through intelligent compression and routing. The system includes a flow analysis system that classifies network traffic as latency-critical or bandwidth-critical, enabling optimized handling of different flow types. Latency-critical flows are transmitted directly to minimize delay, while bandwidth-critical flows undergo compression using dynamically selected methods including Huffman, alphabetic, and Tunstall coding. The system maintains synchronized codebooks across network nodes while enabling node-specific optimizations based on local traffic patterns. A network topology manager maintains comprehensive network state awareness, enabling intelligent route selection based on flow classification and current conditions. The system continuously monitors performance and adapts compression and routing strategies in real-time. This approach enables significant performance improvements in closed network environments where all compression-accelerated applications are developed by the same team.

### CROSS-REFERENCE TO RELATED APPLICATIONS

Priority is claimed in the application data sheet to the following patents or patent applications, each of which is expressly incorporated herein by reference in its entirety:
Ser. No. 18/809,587
Ser. No. 18/657,719
Ser. No. 18/423,287
Ser. No. 18/501,987
Ser. No. 18/190,044
Ser. No. 17/875,201
Ser. No. 17/514,913
Ser. No. 17/404,699
Ser. No. 16/455,655
Ser. No. 16/200,466
Ser. No. 15/975,741
62/578,824
Ser. No. 17/458,747
Ser. No. 16/923,039
63/027,166
Ser. No. 16/716,098
62/926,723
63/388,411
Ser. No. 17/727,913
Ser. No. 18/410,980
Ser. No. 18/537,728

### BACKGROUND OF THE INVENTION

### Field of the Art

The present invention is in the field of network application acceleration, and more particularly is directed to optimizing application performance in closed networks through intelligent compression and routing techniques.

### Discussion of the State of the Art

Network application acceleration represents a critical challenge in modern computing environments, particularly in scenarios where both high throughput and low latency are essential for application performance. Traditional approaches to network optimization typically focus on either maximizing bandwidth utilization through compression or minimizing latency through direct transmission, but rarely address both aspects simultaneously in an integrated manner. This limitation becomes particularly apparent in high-performance applications where different types of data flows have distinct performance requirements.

Current compression technologies employed in network environments generally apply a single compression method uniformly across all data types and operate with limited knowledge of the applications they serve. In closed network environments, where all applications are developed and maintained by the same team, this represents a missed opportunity to leverage deep application knowledge for enhanced optimization. Furthermore, the management of compression operations across network nodes presents significant challenges, with existing systems either maintaining independent compression states at each node or implementing rigid, network-wide compression schemes.

The challenges become particularly acute in high-performance applications where minor inefficiencies can have significant impacts. For example, in financial trading systems, milliseconds of added latency can affect trading outcomes, while inefficient bandwidth utilization can limit the amount of market data that can be processed. Recovery mechanisms in existing systems often focus on maintaining basic connectivity and data integrity but may not adequately address the need to maintain application performance during failure scenarios.

What is needed is a comprehensive approach to network application acceleration that can intelligently handle different types of data flows, dynamically select and apply appropriate compression methods, maintain coordinated compression states across nodes, and optimize performance based on real-time network conditions and application requirements. Such a system can be particularly valuable in closed network environments where deep application knowledge can be leveraged for enhanced optimization.

### SUMMARY OF THE INVENTION

Accordingly, the inventor has conceived and reduced to practice, a system and method for accelerating applications in closed networks through intelligent compression and routing. The system includes a flow analysis system that classifies network traffic as latency-critical or bandwidth-critical, enabling optimized handling of different flow types. Latency-critical flows are transmitted directly to minimize delay, while bandwidth-critical flows undergo compression using dynamically selected methods including Huffman, alphabetic, and Tunstall coding. The system maintains synchronized codebooks across network nodes while enabling node-specific optimizations based on local traffic patterns. A network topology manager maintains comprehensive network state awareness, enabling intelligent route selection based on flow classification and current conditions. The system continuously monitors performance and adapts compression and routing strategies in real-time. This approach enables significant performance improvements in closed network environments where all compression-accelerated applications are developed by the same team.

According to a preferred embodiment, a system for network-optimized multi-type data compression and transmission, comprising: a plurality of network nodes, each node comprising at least a memory and a processor; a plurality of programming instructions stored in the memory and operable on the processor of each node, wherein the programming instructions, when operating on the processor, cause each network node to: maintain a synchronized codebook repository; analyze incoming data flows to: classify data segments as either latency-critical or bandwidth-critical; and determine optimal coding selection for bandwidth-critical segments; process the data flows by: transmitting latency-critical segments without compression; compressing bandwidth-critical segments using at least one selected coding method from the synchronized codebook repository; and maintain network synchronization by: monitoring codebook utilization across nodes; updating shared codebooks based on data flow patterns; and propagating codebook updates to connected nodes.

According to another preferred embodiment, a method for network-optimized multi-type data compression and transmission, comprising the steps of: maintaining, on each node of a plurality of network nodes, a synchronized codebook repository; analyzing incoming data flows to: classify data segments as either latency-critical or bandwidth-critical; and determine optimal coding selection for bandwidth-critical segments; processing the data flows by: transmitting latency-critical segments without compression; compressing bandwidth-critical segments using at least one selected coding method from the synchronized codebook repository; and maintaining network synchronization by: monitoring codebook utilization across nodes; updating shared codebooks based on data flow patterns; and propagating codebook updates to connected nodes.

According to an aspect of an embodiment, determining optimal coding selection comprises: analyzing data characteristics, the data characteristics comprising one or more of symbol distribution patterns, sequence repetitions, ordering requirements, and compression ratio targets; evaluating network conditions, the network conditions comprising one or more of available processing capacity, current bandwidth utilization, and end-to-end latency requirements.

According to an aspect of an embodiment, processing the data flows further comprises: maintaining separate optimization strategies for: different data types; different flow characteristics; and different network conditions; and implementing dynamic switching between coding methods based on: observed performance metrics; changing data patterns; and network state changes.

According to an aspect of an embodiment, maintaining network synchronization further comprises: implementing version control for codebooks through: tracking codebook versions across nodes; managing atomic updates; and maintaining rollback capabilities; and coordinating updates between nodes using: distributed consensus protocols; conflict resolution mechanisms; and consistency verification checks.

According to an aspect of an embodiment, each network node is further caused to: monitor compression performance through: tracking compression ratios; measuring processing overhead; calculating end-to-end latency; and evaluating resource utilization; and adapt compression strategies based on: historical performance data; current network conditions; and application requirements.

According to an aspect of an embodiment, processing the data flows further comprises: implementing hybrid coding approaches by: applying different coding methods to different parts of the same data flow; maintaining coding method boundaries; and managing coding method transitions; and optimizing coding parameters based on: observed data characteristics; available resources; and performance requirements.

According to an aspect of an embodiment, each network node is further caused to: implement route optimization by: maintaining topology awareness; monitoring path performance metrics; and selecting optimal routes based on flow classification; and manage network resources through: dynamic resource allocation; load balancing; and congestion avoidance.

According to an aspect of an embodiment, classifying data segments comprises: analyzing incoming flows using: pattern recognition algorithms; temporal characteristics; and application-specific requirements; and maintaining adaptive classification thresholds based on: historical performance data; current network conditions; and observed flow patterns.

According to an aspect of an embodiment, the synchronized codebook repository comprises at least: a first codebook implementing Huffman coding; a second codebook implementing alphabetic coding; and a third codebook implementing Tunstall coding.

### BRIEF DESCRIPTION OF THE DRAWING FIGURES

FIG. 1 is a diagram showing an embodiment of the system for multi-type data compression or decompression with a virtual management layer.

FIG. 2 is a diagram showing an embodiment of the system for multi-type data compaction with a virtual management layer where the system has been configured for data decompression.

FIG. 3 is a diagram showing an embodiment of the system for multi-type data compaction with a virtual management layer, specifically, a configuration of input and output streams.

FIG. 4 is a flow diagram illustrating an exemplary method for compression using a multi-type data compaction with a virtual management layer system.

FIG. 5 is a flow diagram illustrating an exemplary method for decompression using a multi-type data compaction with virtual management layer system.

FIG. 6 is a diagram showing an embodiment of a codebook-based compression and decompression subsystem in which all components of the system are operated locally.

FIG. 7 is a diagram showing an embodiment of one aspect of the codebook-based compression and decompression subsystem, the data deconstruction engine.

FIG. 8 is a diagram showing an embodiment of one aspect of the codebook-based compression and decompression subsystem, the data reconstruction engine.

FIG. 9 is a diagram showing an embodiment of one aspect of the system, the library management module.

FIG. 10 is a diagram showing another embodiment of the codebook-based compression and decompression subsystem in which data is transferred between remote locations.

FIG. 11 is a diagram showing an embodiment in which a standardized version of the sourceblock library and associated algorithms would be encoded as firmware on a dedicated processing chip included as part of the hardware of a plurality of devices.

FIG. 12 is a diagram showing an example of how data might be converted into reference codes using an aspect of an embodiment.

FIG. 13 is a method diagram showing the steps involved in using an embodiment to store data.

FIG. 14 is a method diagram showing the steps involved in using an embodiment to retrieve data.

FIG. 15 is a method diagram showing the steps involved in using an embodiment to encode data.

FIG. 16 is a method diagram showing the steps involved in using an embodiment to decode data.

FIG. 17 is a diagram showing an exemplary system architecture, according to a preferred embodiment of the invention.

FIG. 18 is a diagram showing a more detailed architecture for a customized library generator.

FIG. 19 is a diagram showing a more detailed architecture for a library optimizer.

FIG. 20 is a diagram showing a more detailed architecture for a transmission and storage engine.

FIG. 21 is a block diagram illustrating an exemplary system architecture for a neural network-based compression or decompression subsystem, according to an embodiment.

FIGS. 22A and 22B illustrate an exemplary architecture for an AI deblocking network configured to provide deblocking on dual-channel data stream comprising SAR I/Q data, according to an embodiment.

FIG. 23 is a block diagram illustrating an exemplary architecture for a component of the neural network-based compression or decompression subsystem, the channel-wise transformer.

FIG. 24 is a flow diagram illustrating an exemplary method for a neural network-based compression or decompression subsystem, according to an embodiment.

FIG. 25 is a flow diagram illustrating and exemplary method for a neural network-based compression or decompression subsystem, according to an embodiment.

FIG. 26 is a flow diagram illustrating an exemplary method for deblocking using a trained deep learning algorithm, according to an embodiment.

FIGS. 27A and 27B illustrate an exemplary architecture for an AI deblocking network configured to provide deblocking for a general N-channel data stream, according to an embodiment.

FIG. 28 is a block diagram illustrating an exemplary system architecture for N-channel data compression with predictive recovery, according to an embodiment.

FIG. 29 is a flow diagram illustrating an exemplary method for processing a compressed n-channel bit stream using an AI deblocking network, according to an embodiment.

FIG. 30 is a block diagram illustrating a system for training a neural network to perform upsampling of decompressed data after lossy compression, according to an embodiment.

FIG. 31 is a flow diagram illustrating an exemplary method for training a neural network to perform upsampling of decompressed data after lossy compression, according to an embodiment.

FIG. 32 is a block diagram illustrating an exemplary architecture for a neural upsampler configured to process N-channel time-series data, according to an embodiment.

FIG. 33 is a block diagram illustrating an exemplary system architecture for upsampling of decompressed sensor data after lossy compression using a neural network, according to an embodiment.

FIG. 34 is a block diagram illustrating an exemplary system architecture network-centric compression configured for providing application acceleration in a closed network system, according to an embodiment.

FIG. 35 is a flow diagram illustrating an exemplary method for applying flow classification at a node of a plurality of closed network nodes, according to an embodiment

FIG. 36 is a flow diagram illustrating an exemplary method for compression scheme selection, according to an embodiment.

FIG. 37 is a flow diagram illustrating an exemplary method for route optimization between and among nodes in a closed network system, according to an embodiment.

FIG. 38 illustrates an exemplary computing environment on which an embodiment described herein may be implemented, in full or in part.

### DETAILED DESCRIPTION OF THE INVENTION

The inventor has conceived, and reduced to practice, a system and method for accelerating applications in closed networks through intelligent compression and routing. The system includes a flow analysis system that classifies network traffic as latency-critical or bandwidth-critical, enabling optimized handling of different flow types. Latency-critical flows are transmitted directly to minimize delay, while bandwidth-critical flows undergo compression using dynamically selected methods including Huffman, alphabetic, and Tunstall coding. The system maintains synchronized codebooks across network nodes while enabling node-specific optimizations based on local traffic patterns. A network topology manager maintains comprehensive network state awareness, enabling intelligent route selection based on flow classification and current conditions. The system continuously monitors performance and adapts compression and routing strategies in real-time. This approach enables significant performance improvements in closed network environments where all compression-accelerated applications are developed by the same team.

The network-centric compression architecture may utilize a plurality of coding methods including, but not limited to, Huffman, alphabetic, and Tunstall coding, each optimized for specific data characteristics and compression requirements. Each method can be implemented through dedicated components within a local codebook management system, with specialized structures and algorithms to maximize compression efficiency while maintaining processing speed.

Huffman coding can be implemented as a variable-length prefix coding method, particularly effective for data with skewed probability distributions. According to an aspect, the system maintains dynamic Huffman trees that adapt to observed symbol frequencies in the data stream. For each node type (e.g., market data, order messages, etc.), the system tracks symbol frequencies using sliding windows to capture both immediate and longer-term patterns. The Huffman implementation includes specialized optimizations for high-performance requirements, such as lookup tables for frequent symbols and balanced tree structures to minimize worst-case encoding time. The system maintains separate Huffman trees for different data types, allowing for specialized optimization based on the characteristics of each type. For example, market data feeds might have a Huffman tree optimized for price tick patterns, while order messages might have trees optimized for order type distributions.

Alphabetic coding, also known as Hu-Tucker coding, may be implemented to maintain lexicographic ordering in the compressed output, a requirement for certain data types in financial and database systems. The implementation maintains order-preserving binary trees where the leaf ordering corresponds to the original symbol ordering. This property makes it particularly valuable for compressing sorted data where order relationships must be preserved, such as price levels in order books or sorted database indices. The system implements efficient tree construction algorithms that balance compression efficiency with maintenance of ordering constraints. It includes specialized optimizations for common financial data patterns, such as price level distributions and identifier sequences. The alphabetic coding implementation also includes mechanisms for handling dynamic symbol sets while maintaining order preservation, which is useful for evolving data structures.

Tunstall coding may be implemented as a variable-to-fixed length coding method, particularly effective for handling long sequences and repeated patterns in data streams. The system maintains Tunstall trees that encode variable-length input sequences into fixed-length output codes. This implementation is especially effective for streaming data where pattern repetition is common, such as market state messages or transaction logs. The Tunstall implementation may comprise one or more pattern recognition algorithms to identify and optimize for frequently occurring sequences. It maintains adaptive dictionaries that evolve based on observed data patterns, with separate dictionaries for different data types and flow characteristics. The system implements efficient lookup structures for quick pattern matching and includes optimizations for handling partial matches and sequence boundaries.

The integration of these coding methods may be managed through a control layer that selects the appropriate method based on data characteristics and requirements. For incoming data flows, the system can analyze key characteristics such as symbol distribution, sequence patterns, and ordering requirements. Based on this analysis and historical performance metrics, it can select the optimal coding method or combination of methods. For example, a market data stream might use Huffman coding for tick-by-tick updates while using Tunstall coding for market state snapshots. Order book updates might use alphabetic coding for price levels while using Huffman coding for quantity updates.

According to various embodiments, the systems and methods described herein may be configured to support conditional variants of the various coding schemes employed. The conditional variants of coding schemes in the system architecture represent sophisticated adaptations of traditional compression algorithms, designed to meet specific operational constraints while maintaining compression efficiency. The implementation of these variants allows the system to balance compression ratios with practical limitations imposed by hardware, memory, or performance requirements.

Length-constrained Huffman coding represents an exemplary conditional variant where codewords are restricted to a maximum length N. This modification is particularly valuable in database operations where predictable decode times are essential. In some implementations, the system uses a modified Huffman tree construction algorithm that enforces the length constraint by redistributing probabilities when a codeword would exceed length N. For example, in a scenario where N=8, if the standard Huffman algorithm would generate a codeword of length 10 for rare values, the algorithm instead allocates an 8-bit codeword, slightly reducing compression efficiency but ensuring consistent decode performance. This variant is particularly useful for high-performance transaction processing where predictable operation timing is crucial.

Alphabetic coding can implement conditional variants that maintain order-preservation while adhering to specific balance constraints. One such variant enforces a maximum height difference between sibling nodes in the coding tree, ensuring more uniform access patterns. This modification is particularly valuable for range queries on compressed data, as it prevents extreme variations in codeword lengths that could impact query performance. The system may be configured to enforce a constraint where the length difference between any two sibling nodes cannot exceed 2, trading some compression efficiency for more consistent query performance.

Tunstall coding can be adapted with conditional variants that maintain fixed-length output blocks while optimizing for specific input patterns. For example, a variant may be constrained to generate codewords that align with hardware memory page sizes, optimizing for system-level I/O operations. Another variant may optimize the dictionary selection based on observed query patterns, prioritizing frequently accessed data patterns even if they don't provide optimal compression ratios.

Neural compression implementations can incorporate conditional variants that balance compression ratio with computational complexity. For example, the autoencoder architecture may be constrained to produce latent representations of fixed dimensionality, or the model complexity might be bounded to ensure encoding/decoding operations complete within a specified time budget. These constraints are particularly important in maintaining predictable performance in production database environments.

According to an aspect, the system implements these conditional variants through a selection process that considers both the constraints and their impact on network, application, and/or system operations. For example, when compressing a column that requires both order preservation and predictable decode times, the system might select a length-constrained alphabetic coding variant that balances these requirements. The selection process includes performance simulation with actual workload patterns to ensure the chosen variant meets both the conditional constraints and the operational requirements of the system.

According to various embodiments, the system provides a flexible and intuitive interface for users to set conditional variants and constraints on compression schemes. At the system level, users can establish global compression policies through a configuration management interface (which may be implemented as subsystem of a client interface) that allows specification of constraints such as maximum codeword lengths, tree balance requirements, and performance thresholds. These global settings can be refined at the database, table, or column level through an extended SQL syntax that integrates naturally with standard database definition language. For example, when creating or modifying tables, users can specify compression constraints such as Huffman coding with a maximum codeword length of 8 bits, alphabetic coding with balanced tree requirements, or neural compression with fixed latent dimensionality and encode/decode time limits. The system may be further configured to implement a hierarchical configuration system where more specific settings override global defaults, allowing for fine-grained control over compression behavior. Users can modify these settings dynamically through administrative commands or programmatically through the system's management application programming interface (API), with the system ensuring that any changes maintain data consistency and operational integrity. The system also provides monitoring and validation capabilities to ensure that specified constraints are being met and to alert administrators when compression performance deviates from configured requirements.

According to some embodiments, the system may implement hybrid coding approaches where different methods can be combined for optimal compression performance. In such embodiments, a hybrid coding module may be implemented to apply one or more coding schemes to different portions of single data segment which is currently being processed by a network node. This may comprise partitioning data streams and applying different coding methods to each partition, or implementing cascaded coding where one method's output feeds into another. For example, a complex market data message might use alphabetic coding for sorted price levels, Huffman coding for quantities, and Tunstall coding for repeated state information. The system carefully manages coding method boundaries and includes necessary metadata for proper decoding.

Performance optimization is continuous across all coding methods. The system tracks compression ratios, processing overhead, and latency impacts for each method across different data types and network conditions. This information feeds back into the selection and configuration process, allowing the system to refine its coding method choices over time. The implementation includes one or more monitoring and adaptation mechanisms that can adjust coding parameters and selection criteria based on observed performance and changing conditions.

Recovery mechanisms may be implemented for each coding method to handle failure scenarios and ensure data integrity. This may comprise maintaining fallback coding options, implementing robust error detection and correction, and ensuring proper handling of coding method boundaries. The system may comprise mechanisms for graceful degradation when optimal coding methods become unavailable or unsuitable due to changing conditions.

This comprehensive implementation of multiple coding methods, combined with selection and optimization mechanisms, enables the system to achieve optimal compression performance across diverse data types and network conditions. The ability to intelligently select and combine coding methods, while maintaining high performance and reliability, makes it particularly well-suited for demanding closed network environments.

In at least one embodiment, the system comprises compression or decompression subsystems which use statistical compression or decompression techniques. Additionally, the system may include compression or decompression subsystems which use codebook or neural network-based compression or decompression techniques.

One or more different aspects may be described in the present application. Further, for one or more of the aspects described herein, numerous alternative arrangements may be described; it should be appreciated that these are presented for illustrative purposes only and are not limiting of the aspects contained herein or the claims presented herein in any way. One or more of the arrangements may be widely applicable to numerous aspects, as may be readily apparent from the disclosure. In general, arrangements are described in sufficient detail to enable those skilled in the art to practice one or more of the aspects, and it should be appreciated that other arrangements may be utilized and that structural, logical, software, electrical and other changes may be made without departing from the scope of the particular aspects. Particular features of one or more of the aspects described herein may be described with reference to one or more particular aspects or figures that form a part of the present disclosure, and in which are shown, by way of illustration, specific arrangements of one or more of the aspects. It should be appreciated, however, that such features are not limited to usage in one or more particular aspects or figures with reference to which they are described. The present disclosure is neither a literal description of all arrangements of one or more of the aspects nor a listing of features of one or more of the aspects that must be present in all arrangements.

Headings of sections provided in this patent application and the title of this patent application are for convenience only and are not to be taken as limiting the disclosure in any way.

Devices that are in communication with each other need not be in continuous communication with each other, unless expressly specified otherwise. In addition, devices that are in communication with each other may communicate directly or indirectly through one or more communication means or intermediaries, logical or physical.

A description of an aspect with several components in communication with each other does not imply that all such components are required. To the contrary, a variety of optional components may be described to illustrate a wide variety of possible aspects and in order to more fully illustrate one or more aspects. Similarly, although process steps, method steps, algorithms or the like may be described in a sequential order, such processes, methods, and algorithms may generally be configured to work in alternate orders, unless specifically stated to the contrary. In other words, any sequence or order of steps that may be described in this patent application does not, in and of itself, indicate a requirement that the steps be performed in that order. The steps of described processes may be performed in any order practical. Further, some steps may be performed simultaneously despite being described or implied as occurring non-simultaneously (e.g., because one step is described after the other step). Moreover, the illustration of a process by its depiction in a drawing does not imply that the illustrated process is exclusive of other variations and modifications thereto, does not imply that the illustrated process or any of its steps are necessary to one or more of the aspects, and does not imply that the illustrated process is preferred. Also, steps are generally described once per aspect, but this does not mean they must occur once, or that they may only occur once each time a process, method, or algorithm is carried out or executed. Some steps may be omitted in some aspects or some occurrences, or some steps may be executed more than once in a given aspect or occurrence.

When a single device or article is described herein, it will be readily apparent that more than one device or article may be used in place of a single device or article. Similarly, where more than one device or article is described herein, it will be readily apparent that a single device or article may be used in place of more than one device or article.

The functionality or the features of a device may be alternatively embodied by one or more other devices that are not explicitly described as having such functionality or features. Thus, other aspects need not include the device itself.

Techniques and mechanisms described or referenced herein will sometimes be described in singular form for clarity. However, it should be appreciated that particular aspects may include multiple iterations of a technique or multiple instantiations of a mechanism unless noted otherwise. Process descriptions or blocks in figures should be understood as representing modules, segments, or portions of code which include one or more executable instructions for implementing specific logical functions or steps in the process. Alternate implementations are included within the scope of various aspects in which, for example, functions may be executed out of order from that shown or discussed, including substantially concurrently or in reverse order, depending on the functionality involved, as would be understood by those having ordinary skill in the art.

### Definitions

The term “bit” refers to the smallest unit of information that can be stored or transmitted. It is in the form of a binary digit (either 0 or 1). In terms of hardware, the bit is represented as an electrical signal that is either off (representing 0) or on (representing 1).

The term “codebook” refers to a database containing sourceblocks each with a pattern of bits and reference code unique within that library. The terms “library” and “encoding/decoding library” are synonymous with the term codebook.

The terms “compression” and “deflation” as used herein mean the representation of data in a more compact form than the original dataset. Compression and/or deflation may be either “lossless”, in which the data can be reconstructed in its original form without any loss of the original data, or “lossy” in which the data can be reconstructed in its original form, but with some loss of the original data.

The terms “compression factor” and “deflation factor” as used herein mean the net reduction in size of the compressed data relative to the original data (e.g., if the new data is 70% of the size of the original, then the deflation/compression factor is 30% or 0.3.)

The terms “compression ratio” and “deflation ratio”, and as used herein all mean the size of the original data relative to the size of the compressed data (e.g., if the new data is 70% of the size of the original, then the deflation/compression ratio is 70% or 0.7.)

The term “data set” refers to a grouping of data for a particular purpose. One example of a data set might be a word processing file containing text and formatting information. Another example of a data set might comprise data gathered/generated as the result of one or more radars in operation.

The term “sourcepacket” as used herein means a packet of data received for encoding or decoding. A sourcepacket may be a portion of a data set.

The term “sourceblock” as used herein means a defined number of bits or bytes used as the block size for encoding or decoding. A sourcepacket may be divisible into a number of sourceblocks. As one non-limiting example, a 1-megabyte sourcepacket of data may be encoded using 512-byte sourceblocks. The number of bits in a sourceblock may be dynamically optimized by the system during operation. In one aspect, a sourceblock may be of the same length as the block size used by a particular file system, typically 512 bytes or 4,096 bytes.

The term “codeword” refers to the reference code form in which data is stored or transmitted in an aspect of the system. A codeword consists of a reference code to a sourceblock in the library plus an indication of that sourceblock's location in a particular data set.

The term “deblocking” as used herein refers to a technique used to reduce or eliminate blocky artifacts that can occur in compressed images or videos. These artifacts are a result of lossy compression algorithms, such as JPEG for images or various video codecs like H.264, H.265 (HEVC), and others, which divide the image or video into blocks and encode them with varying levels of quality. Blocky artifacts, also known as “blocking artifacts,” become visible when the compression ratio is high, or the bitrate is low. These artifacts manifest as noticeable edges or discontinuities between adjacent blocks in the image or video. The result is a visual degradation characterized by visible square or rectangular regions, which can significantly reduce the overall quality and aesthetics of the content. Deblocking techniques are applied during the decoding process to mitigate or remove these artifacts. These techniques typically involve post-processing steps that smooth out the transitions between adjacent blocks, thus improving the overall visual appearance of the image or video. Deblocking filters are commonly used in video codecs to reduce the impact of blocking artifacts on the decoded video frames. A primary goal of deblocking is to enhance the perceptual quality of the compressed content, making it more visually appealing to viewers. It's important to note that deblocking is just one of many post-processing steps applied during the decoding and playback of compressed images and videos to improve their quality.

The term “closed network” refers to a specialized computing environment that combines network-based architecture with single-team development control. In this system, all applications that utilize compaction-based acceleration techniques are developed by the same team, creating a controlled and unified development ecosystem.

### Conceptual Architecture

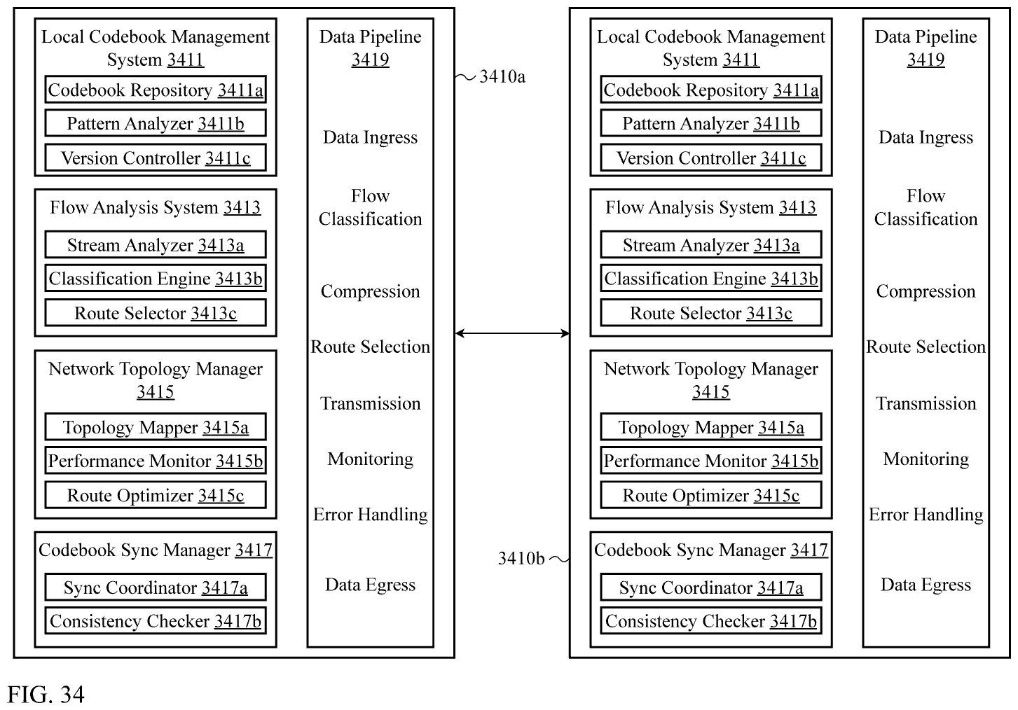

FIG. 34 is a block diagram illustrating an exemplary system architecture network-centric compression configured for providing application acceleration in a closed network system, according to an embodiment. The network-centric compression architecture is designed for closed networks where all compression-accelerated applications are developed by the same team. This enables tight integration between nodes and optimized data flow handling based on application-specific requirements. In such an arrangement the system enables network-optimized multi-type data compression and transmission in closed network environments.

According to the embodiment, the architecture consists of a plurality of interconnected nodes (two exemplary nodes are illustrated 3410a, 3410b), each comprising four primary subsystems: local codebook management system 3411 (LCMS), flow analysis system 3413 (FAS), network topology manager 3415 (NTM), and codebook synchronization manager 3417 (CSM). These subsystems work together to enable efficient data transmission while maintaining compression effectiveness across the network.

The LCMS 3411 may be configured to maintain node-specific codebook repositories optimized for local traffic patterns. Each node's LCMS tracks the frequency of data patterns in its traffic and maintains separate codebooks for different compression methods (e.g., Huffman, Tunstall, and alphabetic coding, etc.). In some implementations, codebooks can be segmented based on usage patterns wherein frequently used patterns remain in active memory while less common patterns are stored in secondary storage. For example, in a financial trading application, a node handling market data feeds can optimize its codebooks for numeric data and trading symbols, while a node processing trade confirmations can optimize for transaction record formats.

According to some embodiments, LCMS 3411 operates as a hierarchical system with three main internal components: a pattern analysis engine (i.e., pattern analyzer) 3411b, codebook repository 3411a, and optimization controller 3411c. The pattern analysis engine continuously monitors data flowing through the node, maintaining frequency counters for data patterns at multiple granularities. It may employ a sliding window mechanism to identify both short-term and long-term pattern trends, using multiple window sizes to capture patterns at different scales. For example, it might track 1-minute, 5-minute, and 1-hour pattern frequencies to balance responsiveness with stability.

The codebook repository implements a multi-tiered storage structure. In some implementations, the primary tier holds frequently used patterns in memory using a modified LRU (least recently used) cache that considers both recency and frequency. The secondary tier stores less common patterns in a memory-mapped structure for efficient access while managing memory usage. Each codebook entry may further comprise metadata such as (but not limited to) usage frequency, last access time, and performance metrics (e.g., compression ratio achieved, processing time required).

The optimization controller periodically analyzes pattern usage data and performance metrics to evolve the codebooks. In some embodiments, it implements a cost-benefit analysis for pattern inclusion, considering factors like pattern frequency, compression ratio improvement, and processing overhead. The controller also manages codebook segmentation, grouping related patterns to improve cache locality during compression operations. When pattern usage changes significantly, it triggers a controlled reorganization of the codebook structure to maintain optimal performance.

The FAS 3413 analyzes incoming data streams to classify them as either latency-critical or bandwidth-critical. This classification drives routing and compression decisions. The FAS maintains configurable thresholds based on application requirements and network conditions. Continuing the financial trading example, market data updates and order executions may be classified as latency-critical and transmitted without compression, while historical data transfers and end-of-day reports can be classified as bandwidth-critical and compressed before transmission.

The FAS 3413 comprises three core subsystems: the stream analyzer 3413a, classification engine 3413b, and route selector 3413c. The stream analyzer implements a multi-phase analysis pipeline that examines incoming data streams at both macro and micro levels. At the macro level, it analyzes traffic patterns, burst characteristics, and temporal dependencies. At the micro level, it examines data structure, entropy, and pattern repetition. This dual-level analysis feeds into the classification decision process.

In some embodiments, classification engine 3413b maintains a dynamic decision tree for flow classification, with decision boundaries that adapt based on current network conditions and application requirements. It may employ a weighted scoring system that considers multiple (non-limiting) factors: data characteristics from the stream analyzer, current network conditions, application-specified priorities, and historical performance metrics. The engine implements separate classification models for different data types, recognizing that classification criteria may vary significantly between, for example, structured database traffic and streaming media content.

The route selector component within the FAS is configured as a path optimization engine designed to determine optimal transmission routes based on flow classification, current network conditions, and application-specific requirements. A path qualification engine serves as the first line of evaluation for potential routes, maintaining separate qualification criteria for different flow types. For latency-critical flows, it continuously validates paths against strict performance requirements including maximum allowable latency, jitter tolerance, and reliability metrics. When handling bandwidth-critical flows, the engine shifts its focus to identify paths that can effectively leverage compression capabilities while maintaining acceptable delivery timeframes. This dual-mode operation ensures that each flow type receives appropriate path consideration based on its specific requirements.

Working in conjunction with the path qualification engine, the real-time decision matrix implements a scoring system that weighs multiple factors in real-time to select optimal routes. For latency-critical flows, the matrix may heavily weight factors such as end-to-end latency, hop count, and historical reliability. When handling bandwidth-critical flows, it may consider additional factors including available bandwidth, compression capabilities along potential paths, and historical compression ratios for similar data types. This dynamic scoring system continuously adapts to changing network conditions and flow characteristics.

An adaptive route cache plays may be implemented for optimizing route selection performance by maintaining recently computed routes in a multi-level cache structure. According to an aspect, the cache may comprise three distinct levels: a fast-path cache for the most common flows, a main cache for regular flows, and an overflow cache for occasional flows. Cache entry lifetimes may be dynamically adjusted based on network stability, with proactive invalidation occurring in response to topology changes. This caching system significantly reduces route computation overhead while maintaining route optimality through careful cache management and update strategies.

Supporting these primary subsystems, a flow monitoring subsystem continuously tracks active flows and their performance metrics. It collects detailed measurements including end-to-end latency, achieved throughput, compression ratios for bandwidth-critical flows, and path stability metrics. This monitoring data feeds back into the decision matrix, enabling continuous refinement of routing decisions based on actual performance outcomes. The monitoring subsystem also maintains historical performance data, which helps inform future routing decisions for similar flow types.

Integration with other system components forms an important aspect of the route selector's operation. It maintains dedicated communication channels with the network topology manager for real-time updates on network conditions, the classification engine for immediate routing of newly classified flows, and the compression subsystem for coordinating compression resources. This tight integration enables rapid response to changing network conditions and ensures optimal resource utilization across the system.

The route selector implements one or more optimization strategies to enhance overall system performance. Predictive routing analyzes flow patterns to anticipate future routing needs and pre-compute likely routes. Resource reservation coordinates with network nodes to ensure critical flows have necessary resources available along their paths. Route coalescing identifies opportunities to combine similar flows while maintaining necessary isolation, optimizing resource usage across multiple flows while respecting individual flow requirements.

In practice, this sophisticated architecture enables highly efficient handling of diverse traffic types. For example, in a financial trading application, market data flows classified as latency-critical receive immediate routing through pre-validated low-latency paths, while historical data transfers classified as bandwidth-critical are routed through paths optimized for compression effectiveness. When network conditions change, such as during periods of congestion, the route selector rapidly adapts, re-routing latency-critical flows to maintain performance while adjusting bandwidth-critical flow paths to optimize resource utilization under the new conditions.

This comprehensive approach to route selection, combining real-time decision making with predictive optimization and continuous monitoring, ensures optimal data flow handling across the network while maintaining the distinct requirements of different flow types. The system's ability to adapt to changing conditions while maintaining performance guarantees makes it particularly well-suited for high-performance applications in closed network environments where predictable performance is important.

A performance feedback loop continuously monitors the impact of classification decisions on application performance. It tracks metrics like end-to-end latency, effective throughput, and application-specific performance indicators. This feedback mechanism enables classification engine 3413b to fine-tune its decision boundaries and weighting factors. The system can maintain a historical database of classification decisions and their outcomes, using this data to improve future classification accuracy.

According to an embodiment, FAS 3413 in the network-centric compression architecture implements a real-time monitoring and adaptation system operating across multiple levels. According to an aspect, the FAS includes a real-time performance monitor (RPM) that continuously tracks key metrics across the network, including compression ratios, processing latency, memory utilization, and network throughput. The RPM component implements high-precision timing mechanisms to measure compression and decompression operations with microsecond accuracy, while maintaining minimal overhead through efficient sampling techniques.

The FAS's may further comprise a dynamic method switching controller (DMSC) that works in conjunction with the RPM to enable seamless transitions between compression methods based on observed performance metrics and changing conditions. When the RPM detects performance degradation or changing data patterns, the DMSC evaluates alternative compression methods and can initiate method switches without disrupting data flow. The switching process may comprise state management to ensure no data is lost during transitions and that decompression remains consistent across the switch boundary.

Network condition adaptation (NCA) extends the FAS's optimization framework by incorporating network state into compression decisions. The NCA may be present and configured to maintain real-time models of network behavior, including, but not limited to, bandwidth utilization, latency patterns, and congestion levels across different paths. These models inform both compression method selection and parameter tuning. For example, during periods of high network congestion, the FAS might favor higher compression ratios even at the cost of increased processing overhead, while during periods of low latency, it might optimize for processing speed over compression ratio.

The integration of these three FAS subsystems (RPM, DMSC, and NCA) enables performance optimization scenarios. For example, consider a financial trading application where market data flows suddenly increase during high volatility periods: the FAS's RPM detects increased data flow and changing pattern distributions in real-time; the FAS's DMSC evaluates current compression performance and might switch from Huffman to Tunstall coding for better handling of the new patterns; and the FAS's NCA adjusts compression parameters based on current network capacity and latency requirements.

This coordinated response within the FAS ensures optimal performance even as conditions change dramatically. The FAS may maintain separate optimization strategies for different data types and flow characteristics, enabling fine-grained control over performance trade-offs. Historical performance data can be maintained to inform future optimization decisions, while real-time metrics enable immediate responses to changing conditions.

The FAS's performance optimization framework also implements one or more failure detection and recovery mechanisms. If a particular compression method begins to perform poorly, the system can quickly switch to alternative methods while diagnosing the cause of the degradation. This includes, but is not limited to, maintaining fallback configurations that prioritize reliability over optimal performance when needed.

The FAS within each node maintains its own optimization state while coordinating with peer FAS instances to ensure consistent compression behavior across the network. This distributed optimization approach allows for local adaptation to node-specific conditions while maintaining global consistency where needed. The FAS includes mechanisms for resolving conflicts between local optimization goals and network-wide requirements, ensuring stable operation even with competing optimization objectives.

The result is a highly adaptive Flow Analysis System that can maintain optimal performance across a wide range of operating conditions and data characteristics. The tight integration of real-time monitoring, dynamic method switching, and network-aware adaptation within the FAS enables sophisticated optimization strategies that would be impossible with simpler approaches.

The NTM 3415 maintains a real-time map of the network topology, tracking available bandwidth, current latency, and node health metrics. It continuously updates optimal routes for different traffic types based on current network conditions. The NTM coordinates with peer nodes to maintain a consistent view of the network state and adapts routing decisions as conditions change. For instance, if a primary route between trading nodes becomes congested, the NTM may automatically redirect latency-critical order flow through alternate paths while allowing bandwidth-critical reporting data to use the congested route.

The NTM is structured around various subsystems: the topology mapping engine (i.e., topology mapper) 3415a, performance monitor 3415b, and route optimization engine (i.e., route optimizer) 3415c. According to some embodiments, the topology mapping engine maintains a graph-based representation of the network, where nodes represent network endpoints and edges represent connections. Each edge maintains both static attributes (like physical bandwidth capacity) and dynamic metrics (like current utilization and latency). The engine implements efficient graph update algorithms to maintain current topology information while minimizing processing overhead.

The performance monitor implements distributed monitoring through a combination of active probing and passive measurement. It can use adaptive sampling rates based on network stability and application requirements. For stable paths, it may reduce monitoring frequency to minimize overhead, while increasing monitoring frequency for paths showing variability or performance issues. The monitor maintains sliding windows of performance metrics at multiple time scales to support both immediate decision-making and trend analysis.

The route optimization engine implements multiple routing strategies optimized for different traffic types. For latency-critical flows, it can maintain pre-computed primary and backup paths, updated whenever significant topology changes occur. For bandwidth-critical flows, it can implement a cost-based routing algorithm that considers current utilization, available compression options, and application priorities. The engine also implements predictive routing based on historical patterns and current trends.

A state distribution controller may be present and configured to manage the exchange of topology and routing information between nodes. It may implement an efficient delta-based update protocol, sending only changed information to minimize network overhead. According to an aspect, the controller uses a hierarchical distribution system, where nodes are organized into update groups based on their network proximity and traffic patterns (or other criteria). This helps balance the need for current information with system scalability.

The CSM 3417 ensures codebook consistency across nodes while allowing for node-specific optimizations. In some aspects, it implements a distributed synchronization protocol that maintains version control of codebooks and handles atomic updates across affected nodes. When a node's LCMS identifies new optimal patterns for its traffic, the CSM coordinates the update of relevant codebooks across all nodes that might handle that traffic type. The CSM also manages fallback procedures for synchronization failures to ensure system reliability.

CSM 3417 implements its functionality through a variety of subsystems: the synchronization coordinator 3417a and consistency checker system 3417b. The synchronization coordinator implements a distributed consensus protocol modified for codebook management. It handles both planned updates (like pattern optimization) and reactive changes (like adding new patterns). In some embodiments, the coordinator implements a two-phase commit protocol for updates, ensuring all affected nodes can support a change before it's applied. It may further comprise a fast path for emergency updates when critical patterns need to be added quickly.

In some embodiments, a version control manager is present and configured to maintain a distributed version history of codebooks across the network. It may implement a branching structure that allows for both network-wide base codebooks and node-specific optimizations. The manager tracks dependencies between codebook versions and maintains rollback points for recovery scenarios. According to an aspect, it can use a combination of vector clocks and Lamport timestamps to maintain causal ordering of updates across the distributed system.

The consistency checker monitors codebook states across nodes and detects inconsistencies. It may implement both periodic full verification and continuous incremental checking. When inconsistencies are detected, it can trigger different recovery mechanisms based on the severity and scope of the inconsistency. For minor issues, it can initiate background synchronization; for critical inconsistencies, it can force immediate resynchronization. The system also maintains performance metrics about synchronization operations, using this data to optimize the frequency and scope of consistency checks.

Each component maintains its own monitoring and diagnostic capabilities, collecting detailed metrics about its operation. This includes, but is not limited to, performance counters, error rates, resource utilization, and operation latencies. The components also implement their own health check mechanisms, allowing them to detect and report internal issues that might affect system operation. These metrics and health indicators feed into the overall system monitoring framework, enabling proactive maintenance and optimization of the compression architecture.

As an example, consider a high-performance trading application running in a closed network with nodes for market data processing, order management, execution, and reporting. When market data arrives at an ingress node:
1. The FAS classifies the incoming data stream based on message types. Trading-critical messages (e.g., orders, executions) are marked as latency-critical, while market statistics and analytics are marked as bandwidth-critical.
2. For latency-critical messages, the NTM determines the optimal route to the destination node(s) based on current network conditions, and the messages are transmitted immediately without compression.
3. For bandwidth-critical messages, the LCMS selects appropriate compression methods and codebooks. Market statistics might use Huffman coding for numeric data, while text-based analytics might use Tunstall coding for longer sequences.
4. Before transmission of compressed data, the CSM verifies codebook synchronization with destination nodes. If necessary, it initiates codebook updates to ensure successful decompression.
5. The receiving node's systems reverse the process, verifying codebook versions, decompressing data if necessary, and delivering to the application.

Control signals flow between subsystems and across nodes to maintain system consistency and optimize performance:
1. The LCMS sends periodic optimization metrics to peer nodes, allowing each node to benefit from patterns discovered across the network.
2. The NTM exchanges topology updates with peer nodes whenever significant changes in network conditions are detected.
3. The CSM maintains a continuous synchronization protocol, ensuring codebook consistency while allowing for node-specific optimizations.
4. The FAS shares classification rules and thresholds across nodes to maintain consistent handling of similar traffic types.

The network-centric architecture continuously optimizes performance through several mechanisms:
1. The LCMS tracks compression ratios and processing overhead for different data types and adjusts pattern selection accordingly.
2. The FAS adapts classification thresholds based on observed application performance and network conditions.
3. The NTM maintains historical performance metrics to predict optimal routes for different traffic types.
4. The CSM monitors synchronization overhead and adjusts update frequency to balance consistency with performance.

In the trading application example, this results in optimal handling of different message types: market data updates and order messages flow through low-latency paths without compression overhead, while market statistics and analytical data are efficiently compressed to maximize network utilization. The system automatically adapts to changing conditions, for instance, during high-volatility periods when order traffic increases, the FAS might adjust its classification thresholds to ensure critical messages continue to receive priority handling.

This architecture can enable a 1.5× performance improvement for applications with a 50/50 split between latency-critical and bandwidth-critical data, assuming a 3× compression ratio for bandwidth-critical data. The actual improvement varies based on application characteristics and network conditions, but the system continuously optimizes itself to maintain maximum efficiency within the given constraints.

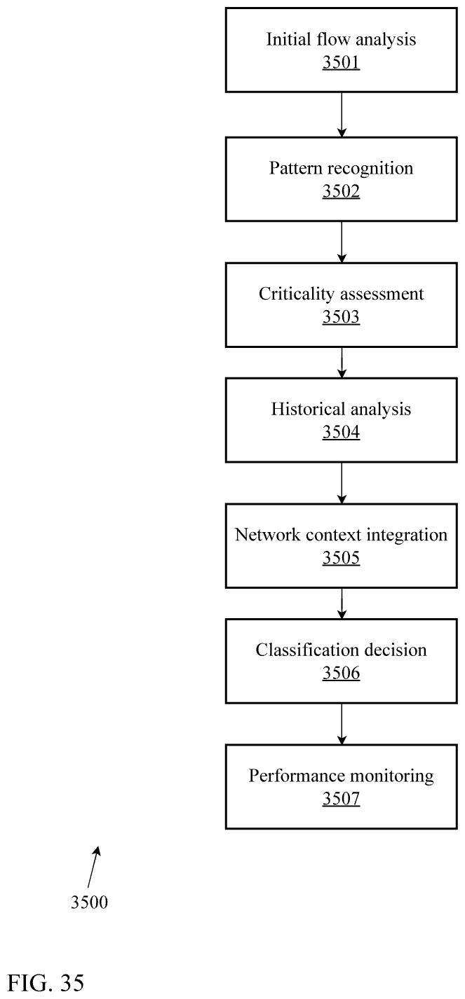

FIG. 35 is a flow diagram illustrating an exemplary method 3500 for applying flow classification at a node of a plurality of closed network nodes, according to an embodiment. The flow classification method implements a comprehensive approach to analyzing and categorizing network traffic within the FAS. According to the embodiment, the process begins at step 3501 with initial flow analysis, which serves as the foundation for all subsequent classification decisions. When data enters the system, the initial flow analysis first creates a flow signature by extracting key metadata including, but not limited to, source, destination, protocol information, and initial size metrics. The signature generation process implements specialized parsers for different data formats, for example, in a financial trading system, separate parsers handle market data feeds, order messages, and historical data transfers. The method then performs deep packet inspection to identify data structures and patterns within the flow, generating a preliminary characteristic profile that includes metrics like message sizes, update frequencies, and structural patterns.

The pattern recognition phase at step 3502 builds upon this initial analysis by implementing one or more sequence detection algorithms. The system maintains pattern databases specific to different data types, allowing it to recognize common sequences and predict flow characteristics. Pattern recognition operates at multiple time scales: microsecond-level analysis for immediate pattern detection and longer-term analysis for identifying broader trends. In a trading system implementation, this may comprise recognizing the burst patterns typical of market data feeds during high volatility periods versus the more regular patterns of normal trading conditions. A pattern recognition engine employs sliding window analysis with multiple window sizes to capture both short-term patterns and longer-term trends.

At step 3503 a criticality assessment is performed wherein the system evaluates the time-sensitivity and performance requirements of the flow. This assessment may begin by checking application-specified priorities, which may be encoded in the data or inferred from flow characteristics. The method calculates concrete latency requirements based on multiple factors including, but not limited to, application specifications, historical performance data, and current network conditions. For trading applications, for example, this may comprise classifying order execution messages as highly latency-critical while categorizing end-of-day reconciliation data as bandwidth-critical. The assessment also evaluates dependencies between different flows, for example, recognizing that market data updates must maintain ordering relationships while allowing parallel processing of independent order flows.

The historical analysis at step 3504 leverages accumulated performance data to refine classification decisions. The system can be configured to maintain detailed historical records of flow characteristics, classification decisions, and resulting performance metrics. According to an aspect, these records are organized in a multi-level structure that enables both quick lookups for common patterns and deeper analysis for complex scenarios. The method implements one or more pattern matching algorithms to compare current flows against historical patterns, using similarity metrics that account for both exact matches and partial pattern alignment. This historical analysis is particularly valuable in handling edge cases and adapting to changing conditions. For example, if a typically bandwidth-critical data feed suddenly shows characteristics similar to historical patterns of latency-critical flows during market events, the system can adjust its classification accordingly.

At step 3505 network context integration is performed wherein the system incorporates real-time network state into its classification decisions. This integration begins with gathering current network metrics including but not limited to, bandwidth utilization, latency measurements, and congestion indicators across all potential routes. The process may evaluate node capabilities along these routes, considering factors like available processing power and compression resources. This network awareness enables sophisticated trade-offs, for instance, a normally bandwidth-critical flow might be reclassified as latency-critical if current network conditions show abundant bandwidth but constrained processing resources for compression.

The classification decision at step 3506 synthesizes all gathered information to make final flow categorization decisions. A decision engine implements a weighted scoring system that considers all analyzed factors. Each factor's weight can be dynamically adjusted based on historical effectiveness and current conditions. The decision process may comprise multiple checkpoints where preliminary decisions can be refined based on additional context. For trading systems, this may comprise initial classification based on message type, refined by current market conditions, and further adjusted based on network state. According to an aspect, the system maintains separate decision models for different flow types, allowing for specialized optimization of classification criteria.

At step 3507 the system supports performance monitoring via continuous evaluation of classification effectiveness. A monitoring system can track key performance indicators including, but not limited to, end-to-end latency, throughput achieved, and resource utilization. It maintains sliding windows of performance metrics at multiple time scales, enabling both immediate feedback and longer-term trend analysis. For example, in a trading application, the system may track message latencies at microsecond resolution while also maintaining hourly and daily performance profiles. This monitoring data feeds back into the classification process, enabling continuous refinement of classification criteria and adaptation to changing conditions.

As an example, consider a financial trading system handling multiple message types during a market volatility event. As market data update frequencies increase, the initial flow analysis detects changed message patterns. Pattern recognition identifies these patterns as similar to previous volatility events. The criticality assessment elevates the priority of market data flows based on application requirements for high-frequency trading. Historical analysis confirms that similar patterns during past volatility events benefited from latency-critical classification. Network context integration verifies available low-latency paths through the network. The classification decision engine then adjusts its criteria to ensure market data receives optimal handling, while the performance monitoring system tracks the effectiveness of these adjustments and provides feedback for future optimization.

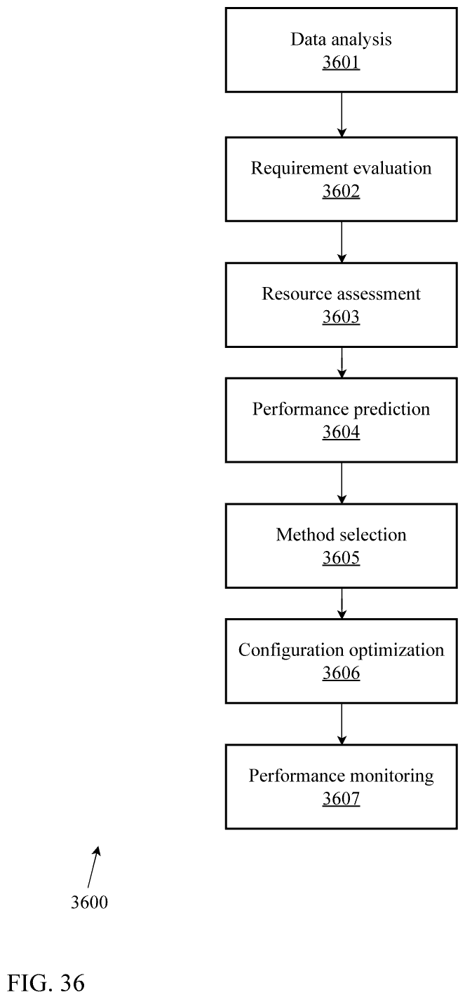

FIG. 36 is a flow diagram illustrating an exemplary method 3600 for compression scheme selection, according to an embodiment. The compression method selection process implements a comprehensive approach to dynamically choosing and applying optimal compression techniques within the network-centric architecture. According to the embodiment, the process begins at step 3601 with data analysis, which forms the foundation for intelligent compression method selection. When a bandwidth-critical flow enters the system, the data analysis phase can perform deep structural analysis of the incoming data. This analysis may include, but is not limited, generating statistical profiles of symbol distributions, identifying repeated patterns at multiple scales, and calculating entropy metrics. The system employs specialized analyzers for different data types, for example, in a financial trading system, separate analyzers handle market data snapshots, historical price series, and order book updates. The analysis phase may further comprise examining temporal characteristics of the data, identifying burst patterns, update frequencies, and data dependencies that might impact compression effectiveness.

The requirement evaluation phase at step 3602 builds upon the initial analysis by incorporating application-specific constraints and requirements. This evaluation begins by checking for ordering preservation requirements which is useful for data like price levels in order books where maintaining sort order is essential. The system can assess latency constraints, determining maximum acceptable compression processing overhead based on application specifications and current network conditions. Compression ratio targets may be calculated based on current network utilization and available bandwidth. For trading applications, this may comprise different targets for different message types: aggressive compression for historical data while maintaining lower latency for near-real-time market data updates.

Resource assessment at step 3603 evaluates available system resources and their impact on compression choices. This assessment can start with a detailed analysis of available processing capacity at both source and destination nodes. The system checks codebook availability and synchronization status across relevant nodes, ensuring selected compression methods will have necessary resources. Memory constraints may be evaluated both for compression operations and for maintaining compression state information. For example, in a trading system handling multiple data types, the resource assessment can determine that sufficient resources exist for Tunstall coding of market snapshots while simpler Huffman coding should be used for continuous updates to conserve resources.

At step 3604 performance prediction leverages historical data and analytical models to forecast compression effectiveness. The system maintains detailed performance histories for each compression method across different data types and network conditions. These histories include achieved compression ratios, processing overhead, and end-to-end latency impacts. The prediction engine uses sophisticated pattern matching to identify similar historical scenarios and predict likely performance outcomes. For instance, when handling market data during high volatility periods, the system might predict that Huffman coding will provide better overall performance than Tunstall coding based on historical patterns during similar market conditions.

At step 3605 method selection synthesizes all gathered information to choose optimal compression approaches. A selection engine implements a weighted decision model that considers all analyzed factors. Different weights are assigned to factors based on current application priorities and network conditions. The selection process can choose hybrid approaches, applying different compression methods to different parts of the data stream based on their characteristics. For example, in a trading system, the method may select alphabetic coding for price level data to maintain ordering, while using Huffman coding for quantity updates where order preservation isn't required.

At step 3606 configuration optimization fine-tunes the selected compression methods for optimal performance. This may comprise setting compression parameters like block sizes and buffer lengths based on observed data characteristics and available resources. Codebook configurations can be optimized for the specific data patterns identified during analysis. Processing paths are configured to minimize latency and maximize throughput. For instance, when compressing order book updates, the system can configure smaller block sizes to reduce latency while using larger blocks for end-of-day data where latency is less critical.

At step 3607 performance monitoring is implemented using continuous evaluation of compression effectiveness through a metrics collection and analysis system. The monitoring system tracks multiple performance indicators including, but not limited to, achieved compression ratios, processing overhead, end-to-end latency, and resource utilization. These metrics are maintained at multiple time scales, enabling both immediate performance feedback and longer-term trend analysis. For example, in a trading application, the system can track compression performance at millisecond resolution for critical data flows while maintaining hourly and daily performance profiles for optimization purposes.

As a practical example, consider a financial trading system during market hours. As market data updates arrive, the data analysis phase identifies a mix of price updates and order book changes. Requirement evaluation determines that price updates need order preservation while order book changes have strict latency requirements. Resource assessment confirms available processing capacity for multiple compression methods. Performance prediction suggests that alphabetic coding has historically performed well for price data during similar market conditions. The Method selection engine chooses a hybrid approach: alphabetic coding for price updates and Huffman coding for order book changes. Configuration optimization sets appropriate block sizes and buffer configurations for each method. Performance monitoring tracks the effectiveness of these choices, providing feedback for ongoing optimization of the selection process.

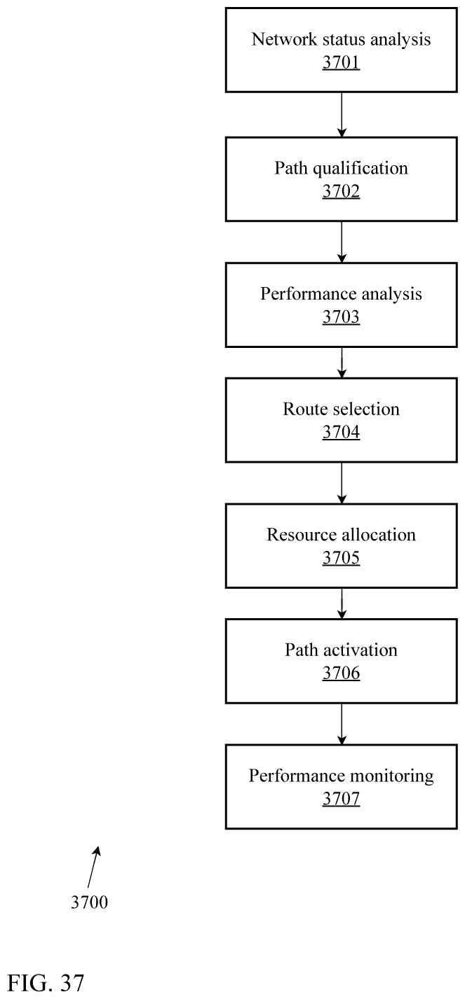

FIG. 37 is a flow diagram illustrating an exemplary method 3700 for route optimization between and among nodes in a closed network system, according to an embodiment. The route optimization method implements a sophisticated approach to path selection and management within the network-centric architecture. According to the embodiment, the process begins at step 3701 with network state analysis, which establishes a comprehensive understanding of current network conditions. When evaluating the network state, the system constructs a detailed topology map incorporating both static infrastructure information and dynamic performance metrics. This analysis may comprise gathering real-time data about link utilization, latency measurements, and available bandwidth across all network paths. According to an aspect, the system employs distributed monitoring agents at each node to collect granular performance data. For example, in a financial trading system, these agents can track microsecond-level latency variations and bandwidth utilization patterns across different trading sessions.

At step 3702 path qualification builds upon the network state analysis by evaluating all possible routes between source and destination nodes. This step implements one or more filtering algorithms that consider both static path capabilities and dynamic performance characteristics. Each potential path is evaluated against multiple criteria including bandwidth capacity, current utilization, end-to-end latency, and historical reliability metrics. The qualification process maintains separate evaluation criteria for different flow types, for instance, paths for latency-critical trading orders might require consistent sub-millisecond latency, while paths for market data distribution might prioritize bandwidth availability and reliable delivery.

At step 3703 performance analysis is performed wherein historical and current performance data are combined to predict path behavior. The system can be configured to maintain detailed performance histories for each network path, including patterns of degradation, congestion events, and recovery characteristics. These histories are analyzed using one or more pattern recognition algorithms to identify conditions that might impact future performance. For trading applications, this may comprise correlating path performance with market volatility patterns or known high-activity periods such as market opens and closes.

Route selection at step 3704 synthesizes all gathered information to choose optimal paths for different flow types. A selection engine can implement a multi-factor decision model that weights various performance criteria based on flow requirements and current conditions. For latency-critical flows, the engine might prioritize paths with consistent low latency and minimal jitter, even if they have lower overall bandwidth. For bandwidth-critical flows, it might select paths that offer the best combination of available bandwidth and compression opportunities. The selection process also identifies and maintains backup paths that can be activated quickly if primary paths degrade.

Resource allocation at step 3705 implements resource management across the selected paths. This step begins by reserving necessary network resources along chosen routes, including bandwidth allocations and processing capacity at intermediate nodes. The allocation system implements fair-sharing algorithms that balance resources across different flows while maintaining priority for critical traffic. In trading applications, this may involve reserving dedicated bandwidth for order flow while allowing market data to use remaining capacity dynamically.

At step 3706 path activation is performed wherein selected routes are put into service. This process comprises configuring network elements along the path, setting up monitoring points, and initializing backup routes. The activation system implements state management to ensure smooth transitions between paths when needed. For trading systems, this may include maintaining hot-standby paths for critical order flow that can be activated within microseconds if primary paths show signs of degradation.

At step 3708 performance monitoring implements continuous evaluation of routing decisions through a comprehensive metrics collection and analysis system. The monitoring system tracks multiple performance indicators including, but not limited to, latency, throughput, packet loss, and path stability. These metrics are maintained at multiple time scales, enabling both immediate detection of problems and longer-term trend analysis. For example, in a trading application, the system can track path latency at microsecond resolution while also maintaining hourly and daily performance profiles for capacity planning.

As a practical example, consider a financial trading system during market hours. As trading activity increases, the network state analysis identifies increasing utilization on primary paths. Path qualification determines that several alternate routes meet the strict latency requirements for order flow. Performance analysis predicts potential congestion on current paths based on historical patterns during similar market conditions. The route selection engine chooses to redirect order flow to alternate paths while maintaining current routes for market data. Resource allocation reserves necessary bandwidth and processing capacity along the new paths. Path activation smoothly transitions order flow to the new routes while keeping backup paths ready. Performance monitoring tracks the effectiveness of these changes, providing feedback for ongoing optimization of the routing process.

The method continuously adapts to changing network conditions and application requirements through its monitoring and feedback mechanisms. For instance, if the system detects that a selected path begins showing increased latency variation, it can proactively initiate a transition to backup paths before application performance is impacted. This adaptive approach ensures optimal routing across varying network conditions while maintaining the strict performance requirements of high-performance applications.

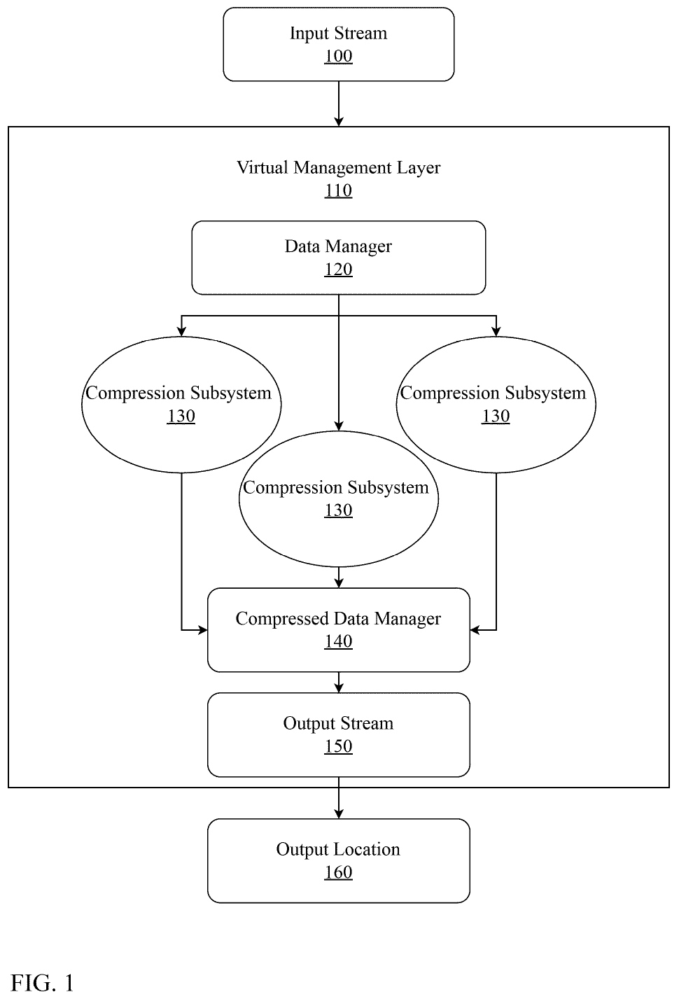

FIG. 1 is a diagram showing an embodiment of the system for multi-type data compression or decompression with a virtual management layer. In one embodiment, the system may include an input stream 100, a virtual management layer 110, a data manager 120, a plurality of compression subsystems 130, a compressed data manager 140, a plurality of output streams 150, and an output location 160. The input stream 100 may include a single stream of information or a plurality of streams of information. Information may take the form of any data type which convey information, including but not limited to text, imagers, audio, video, structured data, scientific data, genomic data, or point cloud data. If unsupported data types are presented to the system, the system may give the user an error which conveys why compression or decompression wasn't possible. Additionally, the user may be prompted with the possible data type inputs based on the plurality of available compression or decompression subsystems at the time.

Generally, information may be collected from a plurality of data sources. Different data sources may produce different types of data. For example, a satellite may produce images which also have corresponding metadata. The plurality of data would pass through the virtual management layer 110 in the form of an input stream 100. The virtual management layer 110 may then parse the incoming input steam 100 and categorize each set of incoming data into a particular type. For example, all incoming image data may be grouped together, likewise, all incoming text data may be grouped separately. In one embodiment, the virtual management layer 110 groups incoming data based on the plurality of available compression or decompression subsystems. Each compression or decompression subsystem may be comprised of different compression or decompression algorithms and systems. Each compression or decompression subsystem may be tailored to a particular data type present in the input stream 100.

In one embodiment, the virtual management layer 110 may include an index where each data types, or data subtype is mapped to a corresponding compression or decompression technique. The index may be updated based on user preferences and goals. For example, if the user is attempting to compress image data but some loss in information is acceptable, the user may want to map the image type or subtype to a lossy technique that maximizes efficiency. In some embodiments, the map may be generated and updated by the user based on which data types are being worked with. In another embodiment, the virtual management system 110 may utilize neural network architecture to classify incoming data and map them to a technique based on machine learning. The network may be trained using compressed and decompressed data over a variety of compression or decompression subsystems where the virtual management system 110 is able to learn which subsystems are best suited for each data type. A neural network can additionally be used in connection with an index where the index is updated by the neural network.

Once the input stream 100 is grouped into data sets of like type, the virtual management layer may pass each set of data through a data manager 120. The data manager 120 may flag sets of data that are associated with other data sets of a different type. For example, if the virtual management system 110 receives image data with corresponding metadata. The virtual management system 110 may split the two types of data into two distinct groups including the image data in one and the metadata in another. The data manager 120 may then flag both the image data and the metadata with a marker to indicate the image data and the metadata are associated data sets. A marker may be any digital indicator that a plurality of sets are associated with one another. The data manager 120 may apply flags or markers to a data set through a plurality of methods, including but not limited to metadata tagging, linked identifiers, cross-referencing, embedded markers, or custom flagging schemes based on user preferences and goals. Metadata tagging may include adding metadata tags to each set where the tag indicates the set's associations and relationships to other sets. Metadata tags include but are not limited to timestamps, source information, custom tags, or unique identifiers that are digital in nature. Linked identifiers may include unique identifiers where are digitally assigned to each data set. Unique identifiers may be generated using techniques such Universally Unique Identifier or hashing functions.

The data manager 120 may embed markers into the data sets themselves where the embedded marker may be a special character, header, or tag. The data manager 120 may additionally allow a user to develop and deploy a custom flagging scheme where the scheme is tailored to the specific needs of the user and their goal.

After each data set has been marked, each set may be passed through a compression subsystem 130 corresponding with the particular data set's data type. The plurality of compression or decompression subsystems 130 may include systems that utilize various compression or decompression techniques such as but not limited to statistical techniques, codebook techniques, or neural network techniques. Each technique generally provides its own pros and cons depending on the incoming data type. For example, some compression techniques are lossy or lossless where lossy techniques are generally better for video or image data types. Likewise, lossless techniques are better suited for text data types where loss of information can erode the integrity of the original file.

As mentioned, the compression or decompression technique used for a particular data type may be selected to maximize efficiency for a particular data type. For example, of the virtual management system 110 determined that the incoming data type is a text file, the compression or decompression subsystems 130 may include but are not limited to, Huffman Coding, Arithmetic Coding, Run-Length Encoding, or Burrows-Wheeler Transforms. For images which include but are not limited to Joint Photographic Experts Groups (JPEGs), Portable Network Graphics (PNGs), and Graphic Interchange Formats (GIFs), the compression or decompression subsystems 130 may include but are not limited to Discrete Cosine Transforms, Deflate Algorithms, Wavelet Transforms, and Lempel-Ziv-Welch Transforms. Generally, image compression may involve compression and decompression techniques that operate in a spatial domain, a frequency domain, or both, where spatial domain techniques operate directly on pixels where frequency domain techniques break images into color components and then operate on the components.

If the incoming data type is audio in nature, such as but not limited to MPEG-1 Audio Layer 3 (MP3) files, the compression and decompression subsystems 130 may include techniques such as but not limited to Modified Discrete Cosine Transforms, Advanced Audio Coding, and Linear Prediction. For incoming data types that are video in nature, such as but not limited to H.264/Advanced Video Coding (AVC) files, H.265/High Efficiency Video Coding (HEVC) files, Audio Video Interleave (AVI) files, or MPEG-4 files, the compression or decompression subsystems 130 may include techniques such as but not limited to Discrete Cosine Transforms and Motion Compensation. Similar to images, video compression and decompression may also operate in a spatial or frequency domain. For data types including geometric data, compression and decompression subsystems 130 may include techniques such as but not limited to Binary Alignment Maps (BAMs), Compressed Alignment Maps (CRAMs), Variant Call Format Compression (VCF), or Reference-Based Compression. Additionally, for data types that include point cloud data, compression, and decompression subsystems 130 may include techniques such as but not limited to Octree Encoding, Geometry Compression, Attribute Compression, Entropy Coding, and Quantization and Prediction.

After the plurality of data is compressed by the plurality of compression subsystems 130, the compressed outputs are passed through a compressed data manager 140. The compressed data manager 140 may receive compressed data from any number of compression subsystems 130. Additionally, the compressed data manager 140 may merge data that has been marked as associated back together into an associated data pair. For example, if an image data type with corresponding metadata was passed through the data manager 120 and marked as associated data types, the compressed data manager 140 may link those associated data types back together after compression. The compressed data manager 140 outputs a plurality of output streams 150 where each data stream represents a particular data type that has been compressed by a corresponding compression subsystem 130. In one embodiment all of the data is preserved in a single output stream where the single output stream represents all of the compressed data from the plurality of compression subsystems 130. In another embodiment, the output streams 150 may be a plurality of streams each coming from a corresponding compression subsystem 130. When the streams are kept separate, a user may access any compressed data set from any particular compression subsystem 130. For example, a user may specifically want to access compressed image data from a compressed subsystem 130 that maximizes the compression efficiency for images specifically.

The plurality of output streams 150 may be output to an output location 160. The output locations 160 may be any plurality of locations, including but not limited to a plurality of databases, a plurality of cloud storage systems, a plurality of personal devices, or any plurality of systems which has a sufficient memory capacity to store the compressed output streams 150.

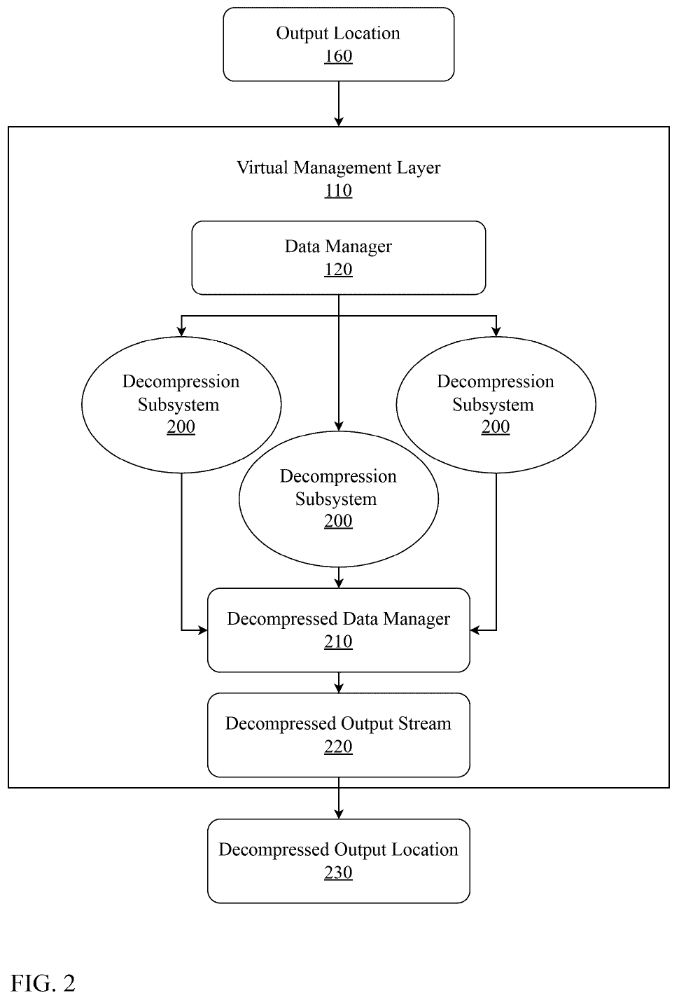

FIG. 2 is a diagram showing an embodiment of the system for multi-type data compression or decompression with a virtual management layer where the system has been configured for data decompression. In one embodiment, the system may be configured to decompress an input which has been compressed. The virtual management layer 110 may receive a compressed data set from an output location 160 which may include but is not limited to a plurality of databases, a plurality of cloud storage systems, a plurality of personal devices, or any plurality of systems which have sufficient memory capacity to store a compressed data set. The virtual management layer 120 operates the same way for both compression and decompression systems. For a decompression system, the virtual management layer 120 organizes and groups the incoming compressed data set by each data set's data type. The data grouped data types are then passed through a corresponding decompression subsystem 200 which decompresses the data type back into its original form. The plurality of decompression subsystems may include a plurality of various data decompression techniques. In some embodiments, the plurality of decompression techniques may include but are not limited to, lossy techniques, lossless techniques, statistical techniques, or techniques that utilize neural networks to maximize efficiency. Each decompression subsystem 200 may correspond to a particular data type where the decompression subsystem 200 utilizes a decompression technique that is best suited for the particular data type. For example, image and video data types generally utilize lossy data decompression which maximizes efficiency without sacrificing the quality of a compressed and decompressed data set. On the contrary, a text file may be decompressed using a lossless decompression technique so that the entire data file is preserved as close to the original as possible.

In one embodiment, the decompression subsystem 200 may be configured to identify and prevent decompression bombs. Decompression bombs are malicious files which cause harm by overwhelming a systems resource during decompression. Generally, decompression bombs appear to contain small amounts of information, but when decompressed, actually contain more information than a system can handle at a particular time. In one embodiment, the decompression subsystems 200 may monitor the decompression ratio of a particular data set. If the decompression ratio exceeds a predetermined threshold that suggests the file is a decompression bomb, the decompression subsystem 200 may be forced to abort the decompression process. In other embodiments, the decompression subsystem 200 may either be self-contained, or store the decompressed output to a location which is self-contained from the rest of the decompression system. By self-containing the output or the decompression subsystem 200, decompression bombs would be unable to draw resources from the rest of the system.

After a data set is decompressed, it may be passed through a decompressed data manager 210. The decompressed data manager may cluster associated data typed that were separated during the compression process back together based on whether they have been marked by the data manager 120 as associated. If preferred, a user may simply output each data set individually without grouping associated data sets. The decompressed data manager 210 may then output the compressed data sets as a decompressed output stream 220 which may be a single stream from a particular decompression subsystem, or a plurality of streams where associated streams are linked together by marks that were applied by the data manager 120. Decompressed data sets may be output to any location a user selects, but it will likely be a user device that has sufficient memory to store the decompressed data sets. Additional decompressed output locations 230 may include but are not limited to, a plurality of databased, a plurality of cloud storage systems, local memory in a user's electronic device, or removable memory currently plugged into a user's device.

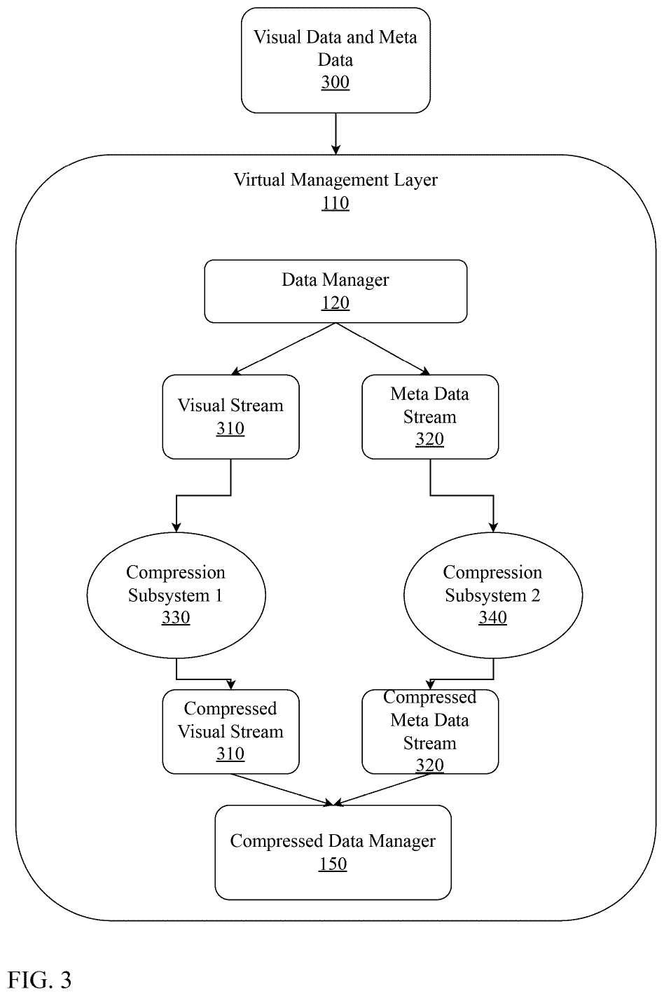

FIG. 3 is a diagram showing an embodiment of the system for multi-type data compression or decompression with a virtual management layer, specifically, a configuration of input and output streams. In one embodiment, the virtual management layer 110 may receive visual data and associated metadata 300 from a data source. The virtual management layer may pass both data types through a data manager 110 which may flag the two data types as associated. The data types would then be split into two sets, a visual stream 310 and a metadata stream 320 which would be passed through a corresponding compression subsystem which utilizes a technique best suited for compressing the incoming data type. For example, the visual stream 310 may be passed through a compression subsystem 1 330 which may include but is not limited to a lossy compression technique to efficiently compress video information without sacrificing the overall integrity of the original file. Likewise, the metadata stream 320 may be passed through a compression subsystem 2 340 which may include but is not limited to a lossless compression technique to ensure that the original form of the metadata stream is preserved as best as possible, and no data is lost during compression.

Following compression, the compression subsystems 330 and 340 may output independent streams corresponding to the input streams. In this case, compression subsystem 1 330 may output a compressed visual stream which is a compressed version of visual stream 310. Additionally, compression subsystem 2 340 may output a compressed metadata stream which is a compressed version of the metadata stream 320. Each stream may be passed through a compressed data manager 150 which allows a user to either group associated streams back together or to view independent streams individually.

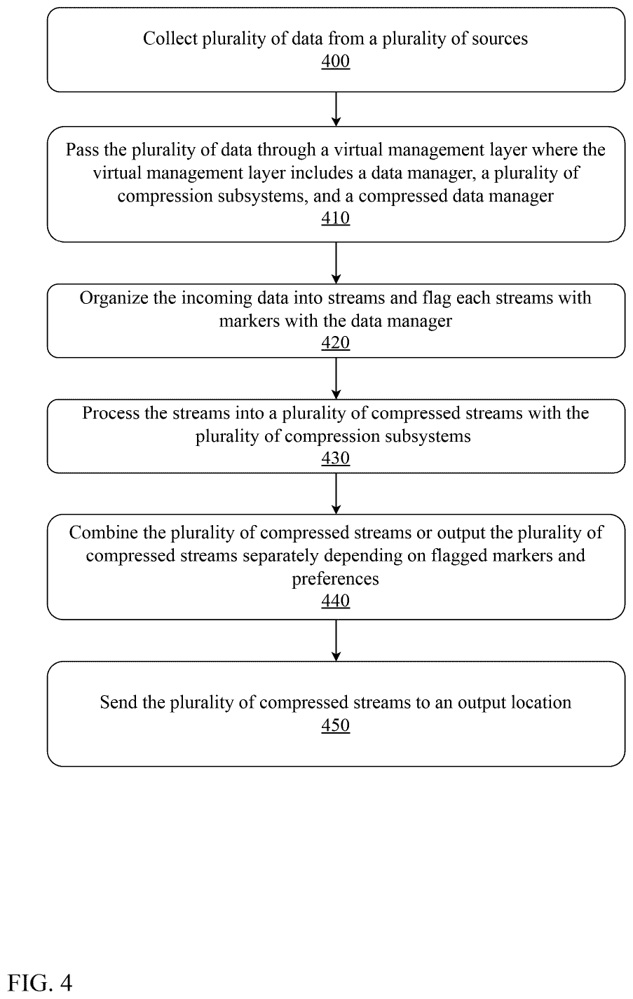

FIG. 4 is a flow diagram illustrating an exemplary method for compression using a multi-type data compression or decompression with a virtual management layer system. In a first step 400, collect a plurality of data from a plurality of sources. In a step 410, pass the plurality of data through a virtual management layer where the virtual management layer includes a data manager, a plurality of compression subsystems, and a compressed data manager. In a step 420, organize the incoming data into streams and flag each stream with markers using the data manager. In a step 430, process the streams into a plurality of compressed streams with the plurality of compression subsystems. In a step 440, combine the plurality of compressed streams or output the plurality of compressed streams separately depending on flagged markers and preferences. In a step 450, send the plurality of compressed streams to an output location.

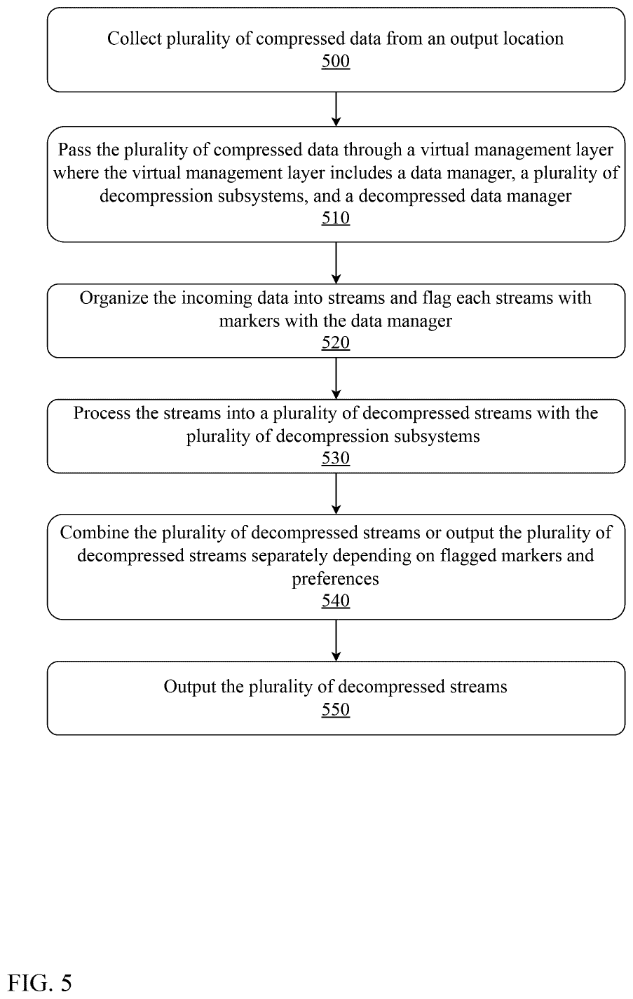

FIG. 5 is a flow diagram illustrating an exemplary method for decompression using a multi-type data compaction with virtual management layer system. In a first step 500, collect a plurality of compressed data from an output location. In a step 510, pass the plurality of compressed data through a virtual management layer where the virtual management layer includes a data manager, a plurality of decompression subsystems, and a decompressed data manager. In a step 520, organize the incoming data into streams and flag each stream with markers using the data manager. In a step 530, process the streams into a plurality of decompressed streams with the plurality of decompression subsystems. In a step 540, combine the plurality of decompressed streams or output the plurality of decompressed streams separately depending on flagged markers and preferences. In a step 550, output the plurality of decompressed streams.

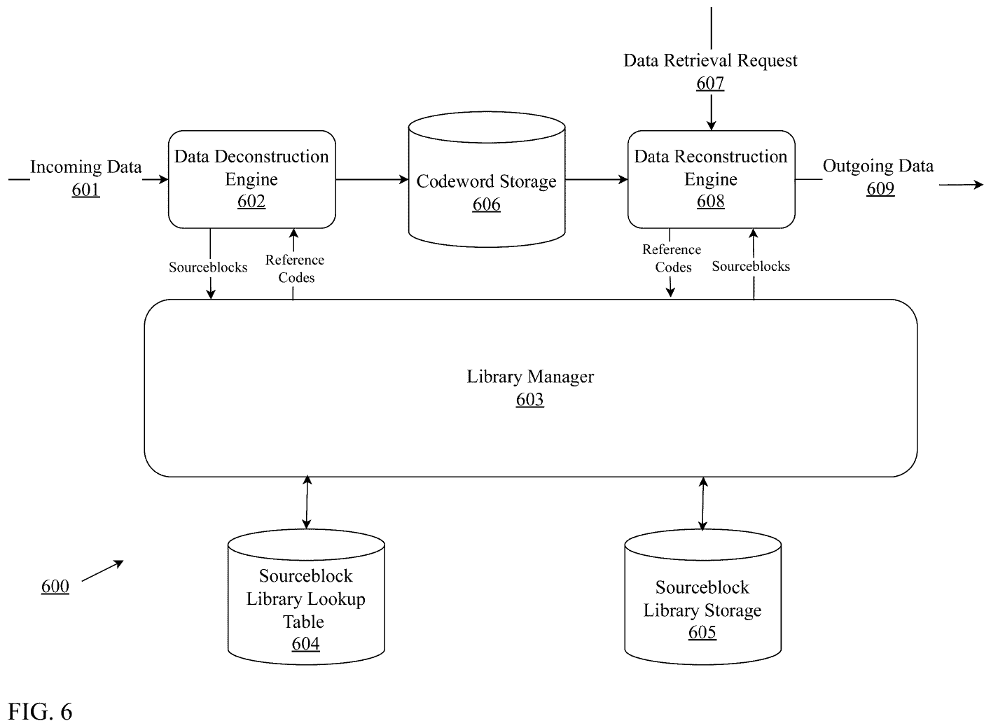

FIG. 6 is a diagram showing an embodiment 600 of a codebook-based compression and decompression system in which all components of the system are operated locally. As incoming data 601 is received by data deconstruction engine 602. Data deconstruction engine 602 breaks the incoming data into sourceblocks, which are then sent to library manager 603. Using the information contained in sourceblock library lookup table 604 and sourceblock library storage 605, library manager 603 returns reference codes to data deconstruction engine 602 for processing into codewords, which are stored in codeword storage 606. When a data retrieval request 607 is received, data reconstruction engine 608 obtains the codewords associated with the data from codeword storage 606 and sends them to library manager 603. Library manager 603 returns the appropriate sourceblocks to data reconstruction engine 608, which assembles them into the proper order and sends out the data in its original form 609.

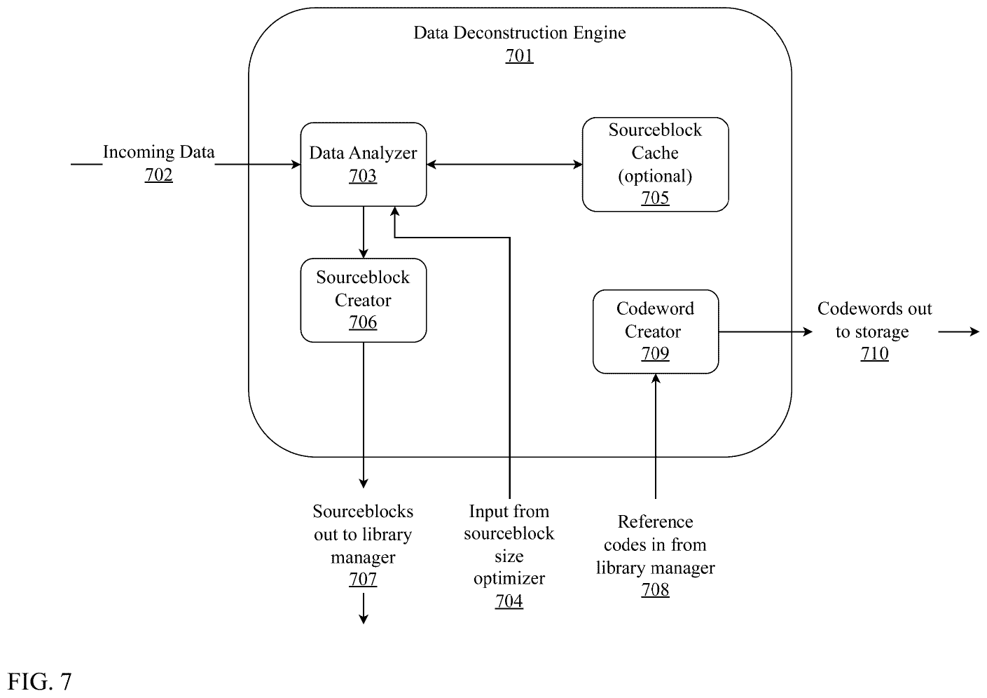

FIG. 7 is a diagram showing an embodiment of one aspect 700 of the codebook-based compression and decompression system, specifically data deconstruction engine 701. Incoming data 702 is received by data analyzer 703, which optimally analyzes the data based on machine learning algorithms and input 704 from a sourceblock size optimizer, which is disclosed below. Data analyzer may optionally have access to a sourceblock cache 705 of recently processed sourceblocks, which can increase the speed of the system by avoiding processing in library manager 603. Based on information from data analyzer 703, the data is broken into sourceblocks by sourceblock creator 706, which sends sourceblocks 707 to library manager 703 for additional processing. Data deconstruction engine 701 receives reference codes 708 from library manager 603, corresponding to the sourceblocks in the library that match the sourceblocks sent by sourceblock creator 706, and codeword creator 709 processes the reference codes into codewords comprising a reference code to a sourceblock and a location of that sourceblock within the data set. The original data may be discarded, and the codewords representing the data are sent out to storage 710.

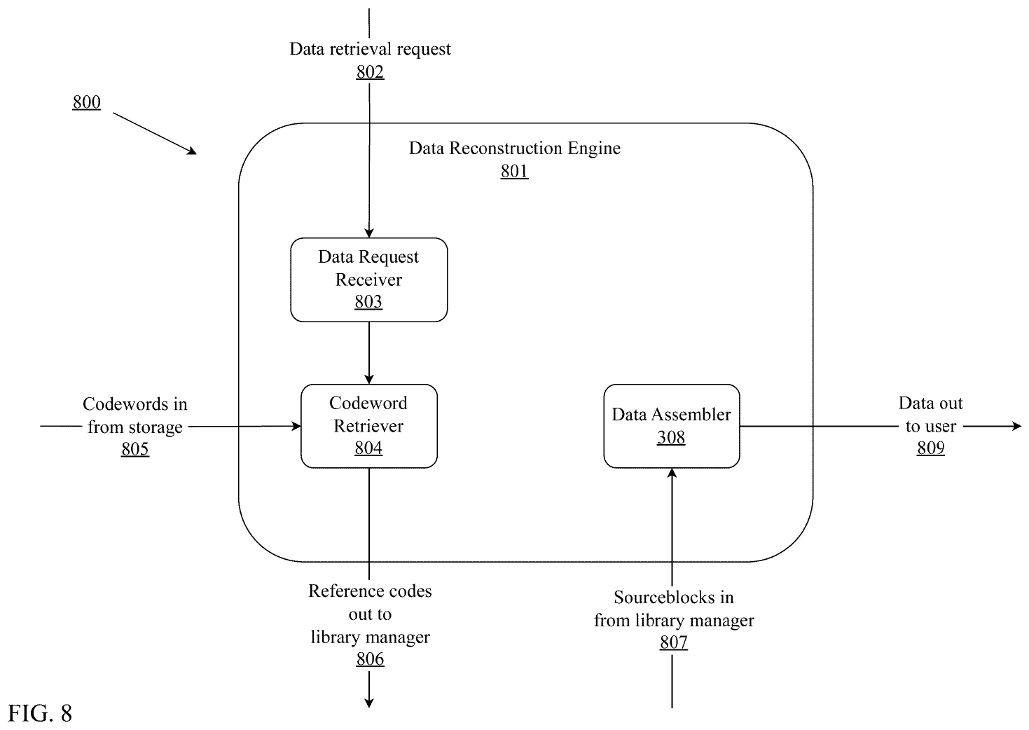

FIG. 8 is a diagram showing an embodiment of another aspect of system 800, specifically data reconstruction engine 801. When a data retrieval request 802 is received by data request receiver 803 (in the form of a plurality of codewords corresponding to a desired final data set), it passes the information to data retriever 804, which obtains the requested data 805 from storage. Data retriever 804 sends, for each codeword received, a reference code from the codeword 806 to library manager 603 for retrieval of the specific sourceblock associated with the reference code. Data assembler 808 receives the sourceblock 807 from library manager 603 and, after receiving a plurality of sourceblocks corresponding to a plurality of codewords, assembles them into the proper order based on the location information contained in each codeword (recall each codeword comprises a sourceblock reference code and a location identifier that specifies where in the resulting data set the specific sourceblock should be restored to. The requested data is then sent to user 809 in its original form.

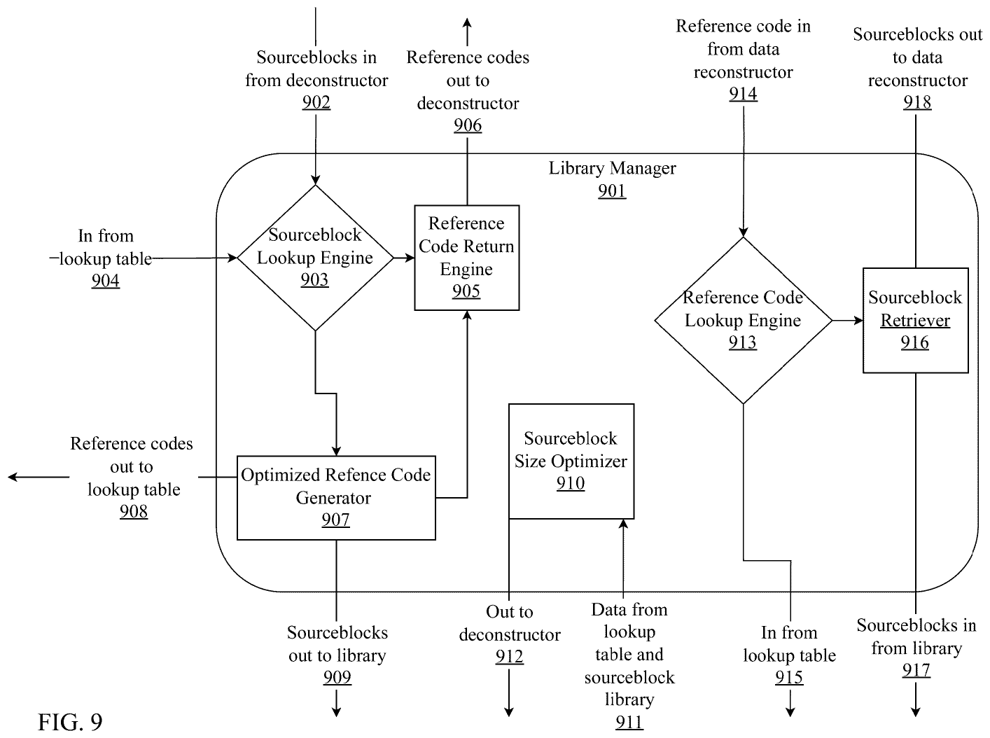

FIG. 9 is a diagram showing an embodiment of another aspect of the system 900, specifically library manager 901. One function of library manager 901 is to generate reference codes from sourceblocks received from data deconstruction engine 801. As sourceblocks are received 902 from data deconstruction engine 801, sourceblock lookup engine 903 checks sourceblock library lookup table 904 to determine whether those sourceblocks already exist in sourceblock library storage 605. If a particular sourceblock exists in sourceblock library storage 605, reference code return engine 905 sends the appropriate reference code 906 to data deconstruction engine 801. If the sourceblock does not exist in sourceblock library storage 605, optimized reference code generator 907 generates a new, optimized reference code based on machine learning algorithms. Optimized reference code generator 907 then saves the reference code 908 to sourceblock library lookup table 604; saves the associated sourceblock 909 to sourceblock library storage 605; and passes the reference code to reference code return engine 905 for sending 906 to data deconstruction engine 801. Another function of library manager 901 is to optimize the size of sourceblocks in the system. Based on information 911 contained in sourceblock library lookup table 604, sourceblock size optimizer 910 dynamically adjusts the size of sourceblocks in the system based on machine learning algorithms and outputs that information 912 to data analyzer 703. Another function of library manager 901 is to return sourceblocks associated with reference codes received from data reconstruction engine 801. As reference codes are received 914 from data reconstruction engine 801, reference code lookup engine 413 checks sourceblock library lookup table 915 to identify the associated sourceblocks; passes that information to sourceblock retriever 916, which obtains the sourceblocks 917 from sourceblock library storage 605; and passes them 918 to data reconstruction engine 801.

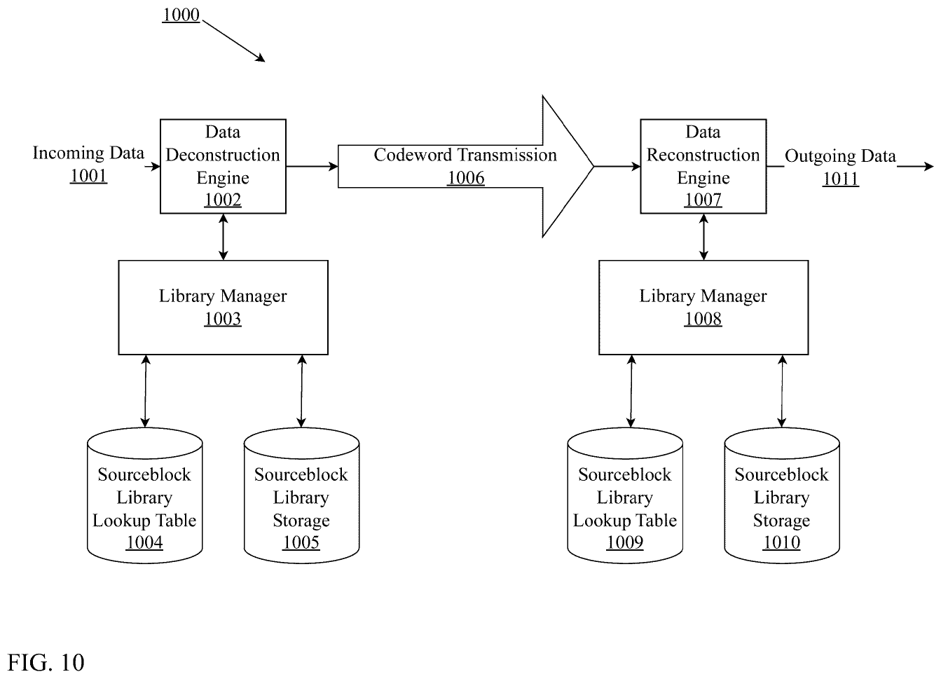

FIG. 10 is a diagram showing another embodiment of system 1000, in which data is transferred between remote locations. As incoming data 1001 is received by data deconstruction engine 1002 at Location 1, data deconstruction engine 801 breaks the incoming data into sourceblocks, which are then sent to library manager 1003 at Location 1. Using the information contained in sourceblock library lookup table 1004 at Location 1 and sourceblock library storage 1005 at Location 1, library manager 1003 returns reference codes to data deconstruction engine 801 for processing into codewords, which are transmitted 1006 to data reconstruction engine 1007 at Location 2. In the case where the reference codes contained in a particular codeword have been newly generated by library manager 1003 at Location 1, the codeword is transmitted along with a copy of the associated sourceblock. As data reconstruction engine 1007 at Location 2 receives the codewords, it passes them to library manager module 1008 at Location 2, which looks up the sourceblock in sourceblock library lookup table 1009 at Location 2 and retrieves the associated from sourceblock library storage 1010. Where a sourceblock has been transmitted along with a codeword, the sourceblock is stored in sourceblock library storage 1010 and sourceblock library lookup table 1004 is updated. Library manager 1003 returns the appropriate sourceblocks to data reconstruction engine 1007, which assembles them into the proper order and sends the data in its original form 1011.

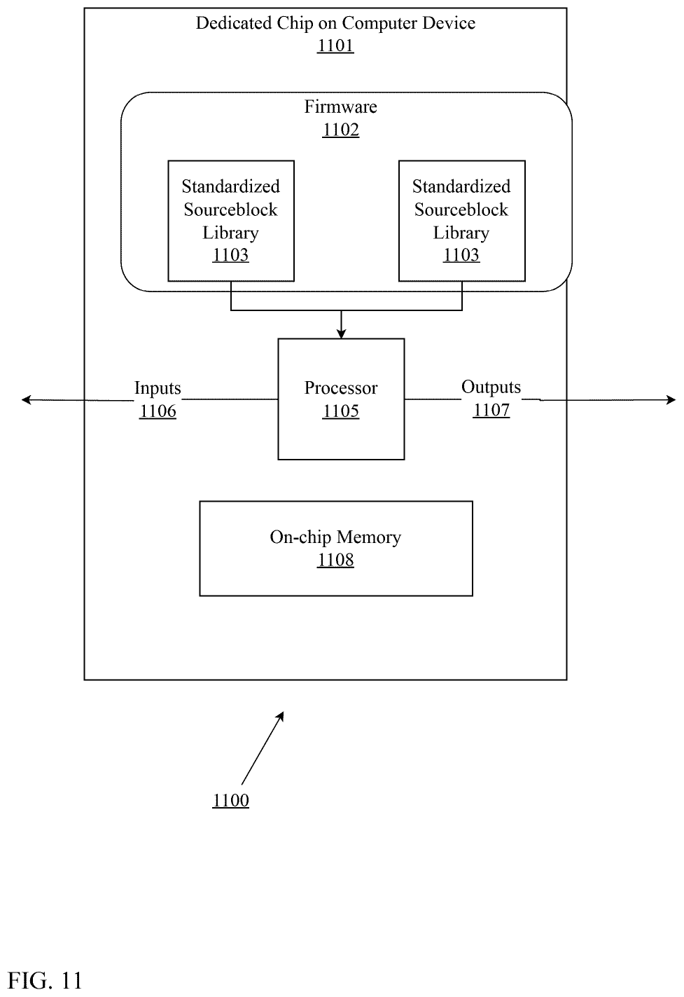

FIG. 11 is a diagram showing an embodiment 1100 in which a standardized version of a sourceblock library 1103 and associated algorithms 1104 would be encoded as firmware 1102 on a dedicated processing chip 1101 included as part of the hardware of a plurality of devices 1100. Contained on dedicated chip 1101 would be a firmware area 1102, on which would be stored a copy of a standardized sourceblock library 1103 and deconstruction/reconstruction algorithms 1104 for processing the data. Processor 605 would have both inputs 606 and outputs 1107 to other hardware on the device 1100. Processor 1105 would store incoming data for processing on on-chip memory 1108, process the data using standardized sourceblock library 1103 and deconstruction/reconstruction algorithms 1104, and send the processed data to other hardware on device 1100. Using this embodiment, the encoding and decoding of data would be handled by dedicated chip 1101, keeping the burden of data processing off device's 1100 primary processors. Any device equipped with this embodiment would be able to store and transmit data in a highly optimized, bandwidth-efficient format with any other device equipped with this embodiment.

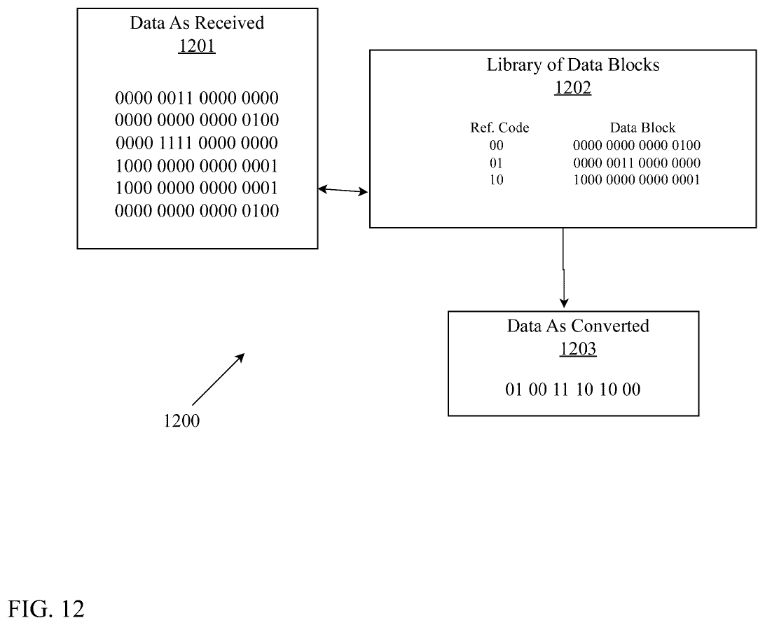

FIG. 12 is a diagram showing an example of how data might be converted into reference codes using an aspect of an embodiment 1200. As data is received 1201, it is read by the processor in sourceblocks of a size dynamically determined by the previously disclosed sourceblock size optimizer 910. In this example, each sourceblock is 16 bits in length, and the library 1202 initially contains three sourceblocks with reference codes 00, 01, and 10. The entry for reference code 11 is initially empty. As each 16-bit sourceblock is received, it is compared with the library. If that sourceblock is already contained in the library, it is assigned the corresponding reference code. So, for example, as the first line of data (0000 0011 0000 0000) is received, it is assigned the reference code (01) associated with that sourceblock in the library. If that sourceblock is not already contained in the library, as is the case with the third line of data (0000 1111 0000 0000) received in the example, that sourceblock is added to the library and assigned a reference code, in this case 11. The data is thus converted 1203 to a series of reference codes to sourceblocks in the library. The data is stored as a collection of codewords, each of which contains the reference code to a sourceblock and information about the location of the sourceblocks in the data set. Reconstructing the data is performed by reversing the process. Each stored reference code in a data collection is compared with the reference codes in the library, the corresponding sourceblock is read from the library, and the data is reconstructed into its original form.

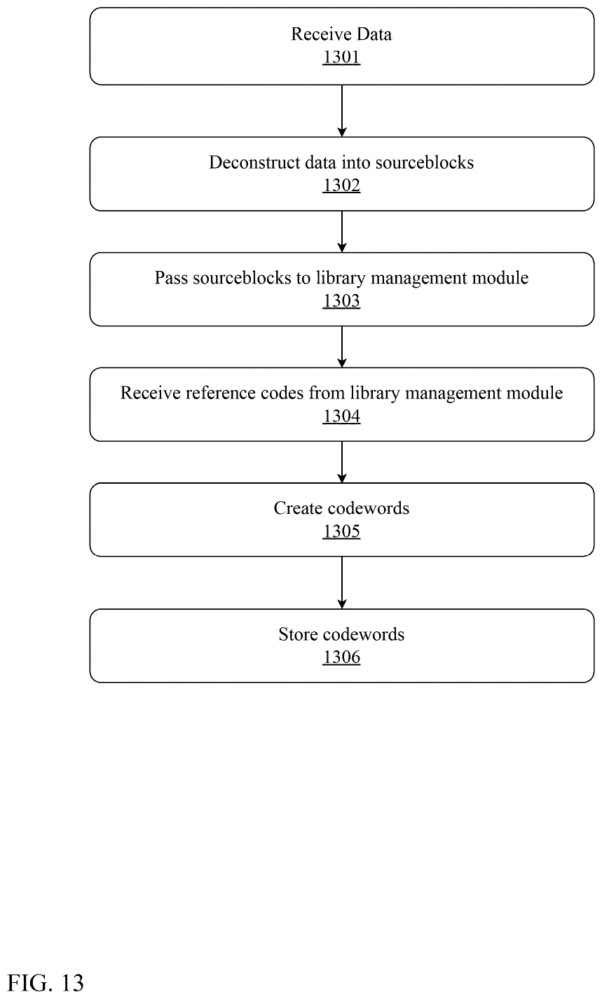

FIG. 13 is a method diagram showing the steps involved in using an embodiment 1300 to store data. As data is received 1301, it would be deconstructed into sourceblocks 1302, and passed 1303 to the library management module for processing. Reference codes would be received back 1304 from the library management module and could be combined with location information to create codewords 1305, which would then be stored 1306 as representations of the original data.

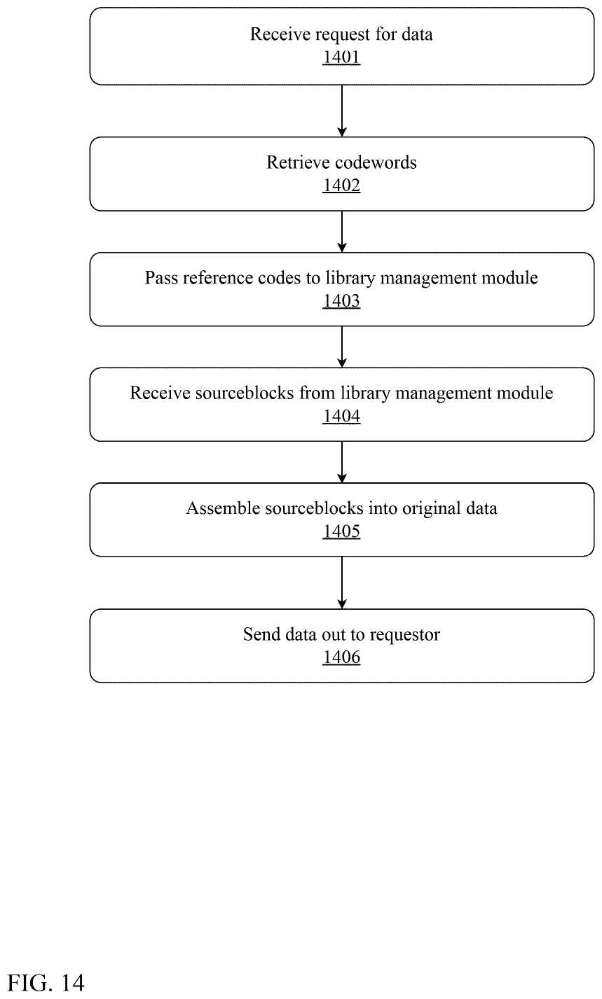

FIG. 14 is a method diagram showing the steps involved in using an embodiment 1400 to retrieve data. When a request for data is received 1401, the associated codewords would be retrieved 1402 from the library. The codewords would be passed 1403 to the library management module, and the associated sourceblocks would be received back 1404. Upon receipt, the sourceblocks would be assembled 1405 into the original data using the location data contained in the codewords, and the reconstructed data would be sent out 1406 to the requestor.

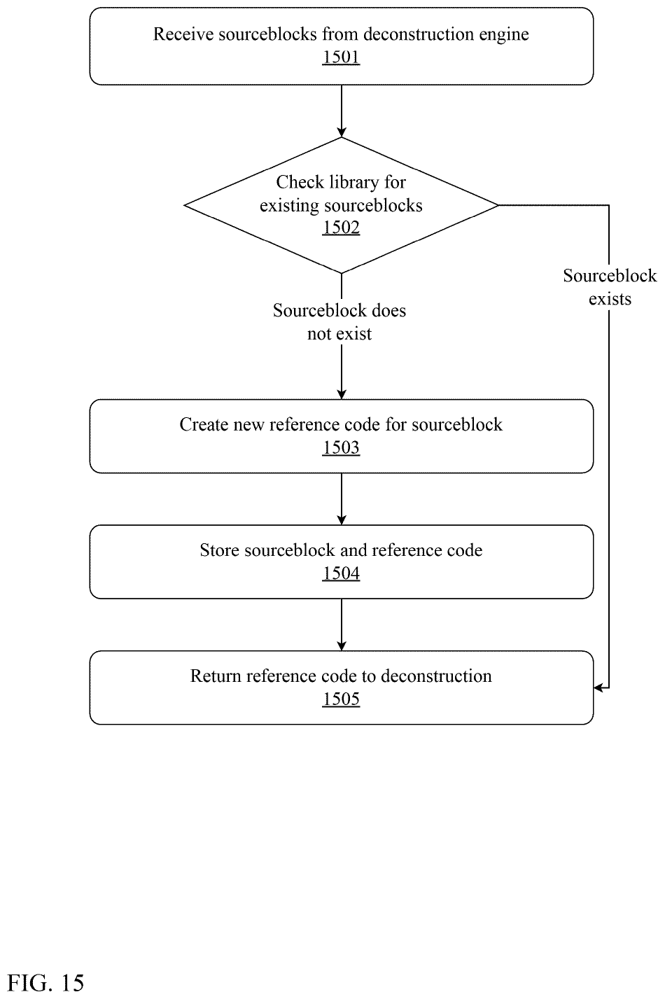

FIG. 15 is a method diagram showing the steps involved in using an embodiment 1500 to encode data. As sourceblocks are received 1501 from the deconstruction engine, they would be compared 1502 with the sourceblocks already contained in the library. If that sourceblock already exists in the library, the associated reference code would be returned 1505 to the deconstruction engine. If the sourceblock does not already exist in the library, a new reference code would be created 1503 for the sourceblock. The new reference code and its associated sourceblock would be stored 1504 in the library, and the reference code would be returned to the deconstruction engine.

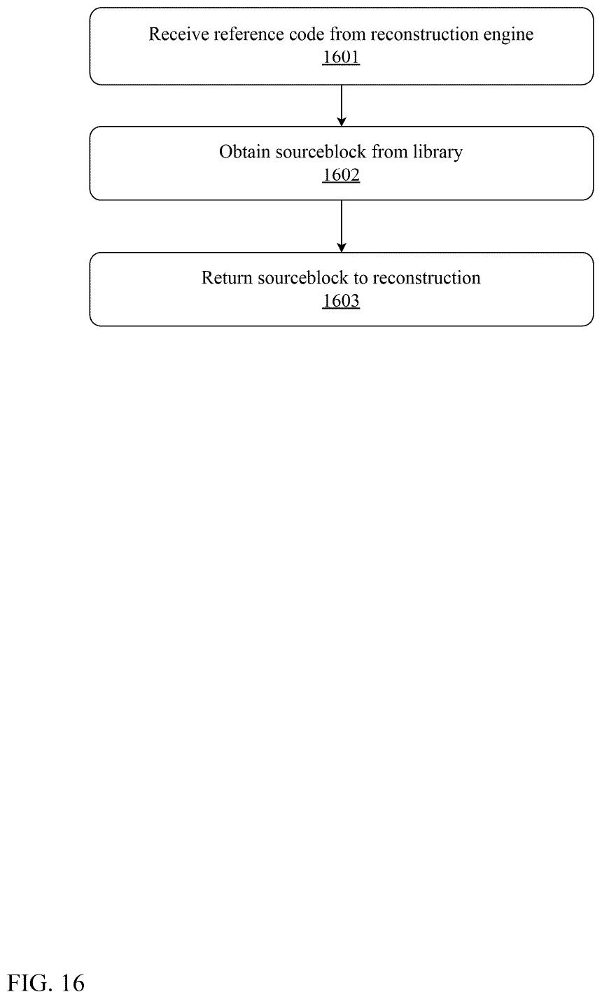

FIG. 16 is a method diagram showing the steps involved in using an embodiment 1600 to decode data. As reference codes are received 1601 from the reconstruction engine, the associated sourceblocks are retrieved 1602 from the library, and returned 1603 to the reconstruction engine.

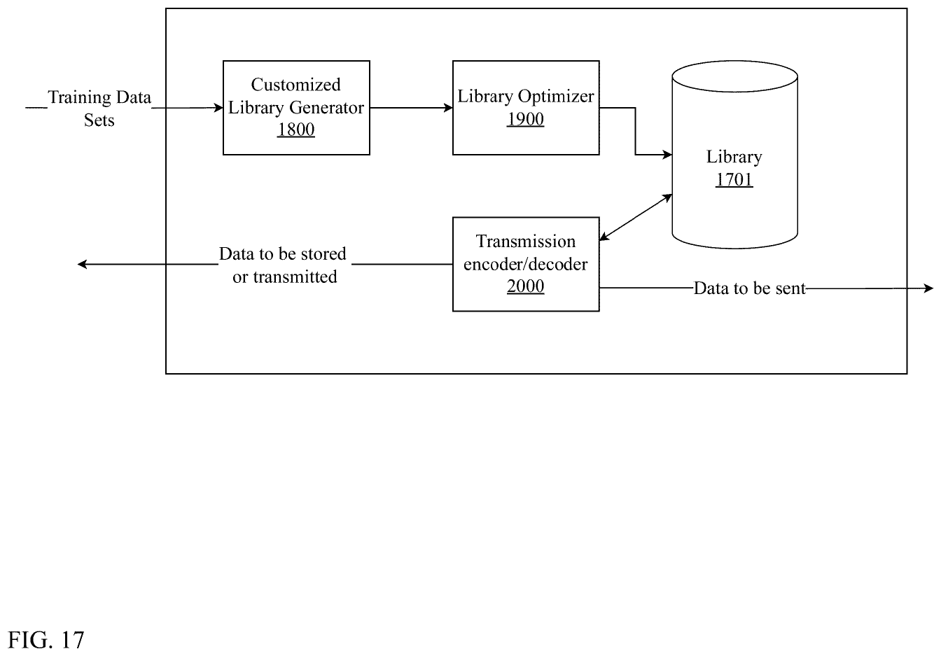

FIG. 17 is a diagram showing an exemplary system architecture 1700, according to a preferred embodiment of the invention. Incoming training data sets may be received at a customized library generator 1800 that processes training data to produce a customized word library 1701 comprising key-value pairs of data words (each comprising a string of bits) and their corresponding calculated binary Huffman codewords. The resultant word library 1701 may then be processed by a library optimizer 1900 to reduce size and improve efficiency, for example by pruning low-occurrence data entries or calculating approximate codewords that may be used to match more than one data word. A transmission encoder/decoder 2000 may be used to receive incoming data intended for storage or transmission, process the data using a word library 1701 to retrieve codewords for the words in the incoming data, and then append the codewords (rather than the original data) to an outbound data stream. Each of these components is described in greater detail below, illustrating the particulars of their respective processing and other functions, referring to FIGS. 2-4.

System 1700 provides near-instantaneous source coding that is dictionary-based and learned in advance from sample training data, so that encoding and decoding may happen concurrently with data transmission. This results in computational latency that is near zero, but the data size reduction is comparable to classical compression. For example, if N bits are to be transmitted from sender to receiver, the compression ratio of classical compression is C, the ratio between the deflation factor of system 1700 and that of multi-pass source coding is p, the classical compression encoding rate is R_{C} bit/s and the decoding rate is R_{D} bit/s, and the transmission speed is S bit/s, the compress-send-decompress time will be

$${T}_{old} = \frac{N}{{R}_{C}} + \frac{N}{CS} + \frac{N}{{CR}_{D}}$$

while the transmit-while-coding time for system 1700 will be (assuming that encoding and decoding happen at least as quickly as network latency):

$${T}_{new} = \frac{{N}_{p}}{cs}$$

so that the total data transit time improvement factor is

$$\frac{{T}_{old}}{{T}_{new}} = \frac{\frac{CS}{{R}_{C}} + 1 + \frac{S}{{R}_{D}}}{p}$$

which presents a savings whenever

$$\frac{CS}{{R}_{C}} + \frac{S}{{R}_{D}} > p - 1.$$

This is a reasonable scenario given that typical values in real-world practice are C=0.32, R_{C}=1.1·10¹², R_{D}=4.2·10¹², S=10¹¹, giving

$$\frac{CS}{{R}_{C}} + \frac{S}{{R}_{D}} = 0.053 … ,$$

such that system 1700 will outperform the total transit time of the best compression technology available as long as its deflation factor is no more than 5% worse than compression. Such customized dictionary-based encoding will also sometimes exceed the deflation ratio of classical compression, particularly when network speeds increase beyond 100 Gb/s.

The delay between data creation and its readiness for use at a receiving end will be equal to only the source word length t (typically 5-15 bytes), divided by the deflation factor C/p and the network speed S, i.e.

$${delay}_{invention} = \frac{tp}{CS}$$

since encoding and decoding occur concurrently with data transmission. On the other hand, the latency associated with classical compression is

$${delay}_{priorart} = \frac{N}{{R}_{C}} + \frac{N}{CS} + \frac{N}{{CR}_{D}}$$

where N is the packet/file size. Even with the generous values chosen above as well as N=512K, t=10, and p=1.05, this results in delayᵢₙᵥₑₙₜᵢₒₙ≈3.3·10⁻¹⁰ while delayₚᵣᵢₒᵣₐᵣₜ≈1.3·10⁻⁷, a more than 400-fold reduction in latency.

A key factor in the efficiency of Huffman coding used by system 1700 is that key-value pairs be chosen carefully to minimize expected coding length, so that the average deflation/compression ratio is minimized. It is possible to achieve the best possible expected code length among all instantaneous codes using Huffman codes if one has access to the exact probability distribution of source words of a given desired length from the random variable generating them. In practice this is impossible, as data is received in a wide variety of formats and the random processes underlying the source data are a mixture of human input, unpredictable (though in principle, deterministic) physical events, and noise. System 1700 addresses this by restriction of data types and density estimation; training data is provided that is representative of the type of data anticipated in “real-world” use of system 1700, which is then used to model the distribution of binary strings in the data in order to build a Huffman code word library 1700.

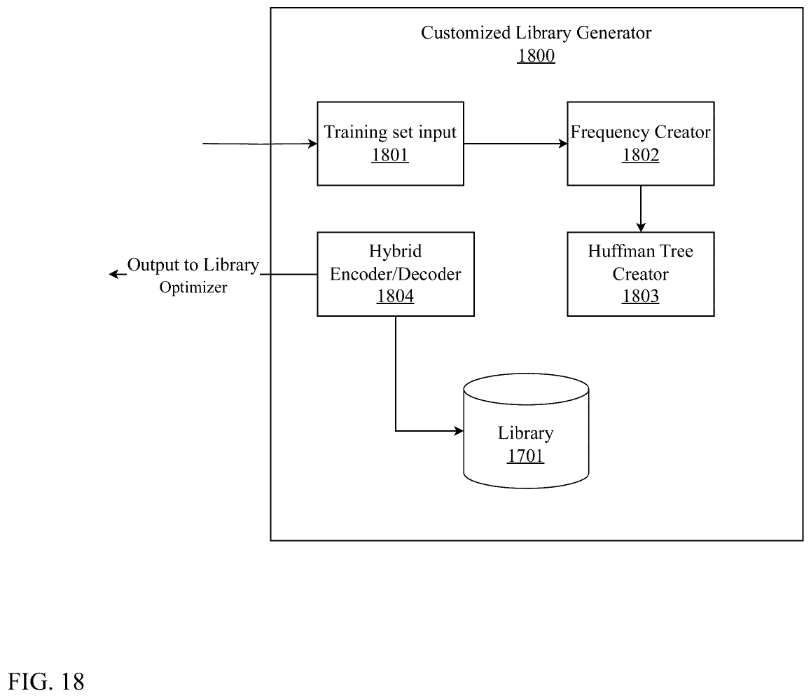

FIG. 18 is a diagram showing a more detailed architecture for a customized library generator 1800. When an incoming training data set 1801 is received, it may be analyzed using a frequency creator 1802 to analyze for word frequency (that is, the frequency with which a given word occurs in the training data set). Word frequency may be analyzed by scanning all substrings of bits and directly calculating the frequency of each substring by iterating over the data set to produce an occurrence frequency, which may then be used to estimate the rate of word occurrence in non-training data. A first Huffman binary tree is created based on the frequency of occurrences of each word in the first dataset, and a Huffman codeword is assigned to each observed word in the first dataset according to the first Huffman binary tree. Machine learning may be utilized to improve results by processing a number of training data sets and using the results of each training set to refine the frequency estimations for non-training data, so that the estimation yields better results when used with real-world data (rather than, for example, being only based on a single training data set that may not be very similar to a received non-training data set). A second Huffman tree creator 1803 may be utilized to identify words that do not match any existing entries in a word library 1701 and pass them to a hybrid encoder/decoder 1804, that then calculates a binary Huffman codeword for the mismatched word and adds the codeword and original data to the word library 1701 as a new key-value pair. In this manner, customized library generator 1800 may be used both to establish an initial word library 1701 from a first training set, as well as expand the word library 1701 using additional training data to improve operation.

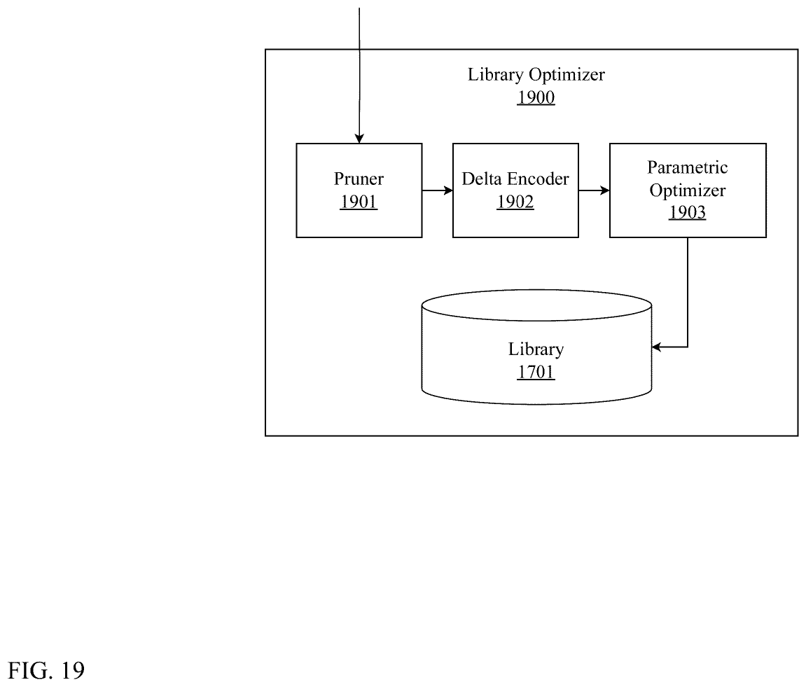

FIG. 19 is a diagram showing a more detailed architecture for a library optimizer 1900. A pruner 1901 may be used to load a word library 1701 and reduce its size for efficient operation, for example by sorting the word library 1701 based on the known occurrence probability of each key-value pair and removing low-probability key-value pairs based on a loaded threshold parameter. This prunes low-value data from the word library to trim the size, eliminating large quantities of very-low-frequency key-value pairs such as single-occurrence words that are unlikely to be encountered again in a data set. Pruning eliminates the least-probable entries from word library 1701 up to a given threshold, which will have a negligible impact on the deflation factor since the removed entries are only the least-common ones, while the impact on word library size will be larger because samples drawn from asymptotically normal distributions (such as the log-probabilities of words generated by a probabilistic finite state machine, a model well-suited to a wide variety of real-world data) which occur in tails of the distribution are disproportionately large in counting measure. A delta encoder 1902 may be utilized to apply delta encoding to a plurality of words to store an approximate codeword as a value in the word library, for which each of the plurality of source words is a valid corresponding key. This may be used to reduce library size by replacing numerous key-value pairs with a single entry for the approximate codeword and then represent actual codewords using the approximate codeword plus a delta value representing the difference between the approximate codeword and the actual codeword. Approximate coding is optimized for low-weight sources such as Golomb coding, run-length coding, and similar techniques. The approximate source words may be chosen by locality-sensitive hashing, so as to approximate Hamming distance without incurring the intractability of nearest-neighbor-search in Hamming space. A parametric optimizer 1903 may load configuration parameters for operation to optimize the use of the word library 1701 during operation. Best-practice parameter/hyperparameter optimization strategies such as stochastic gradient descent, quasi-random grid search, and evolutionary search may be used to make optimal choices for all interdependent settings playing a role in the functionality of system 1700. In cases where lossless compression is not required, the delta value may be discarded at the expense of introducing some limited errors into any decoded (reconstructed) data.

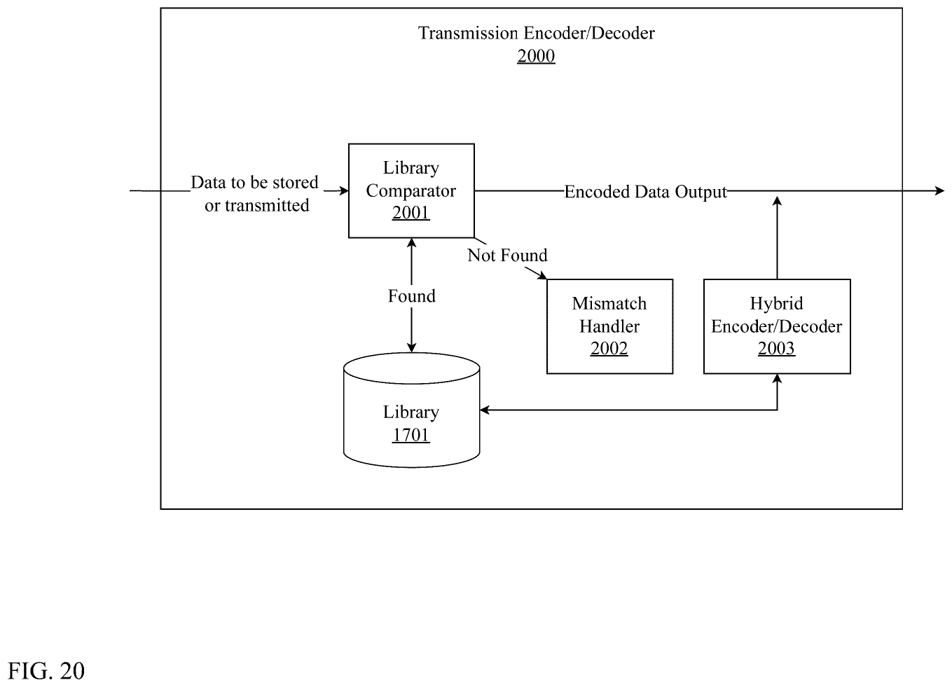

FIG. 20 is a diagram showing a more detailed architecture for a transmission encoder/decoder 2000. According to various arrangements, transmission encoder/decoder 2000 may be used to deconstruct data for storage or transmission, or to reconstruct data that has been received, using a word library 1701. A library comparator 2001 may be used to receive data comprising words or codewords and compare against a word library 1701 by dividing the incoming stream into substrings of length t and using a fast hash to check word library 1701 for each substring. If a substring is found in word library 1701, the corresponding key/value (that is, the corresponding source word or codeword, according to whether the substring used in comparison was itself a word or codeword) is returned and appended to an output stream. If a given substring is not found in word library 1701, a mismatch handler 2002 and hybrid encoder/decoder 2003 may be used to handle the mismatch similarly to operation during the construction or expansion of word library 1701. A mismatch handler 2002 may be utilized to identify words that do not match any existing entries in a word library 1701 and pass them to a hybrid encoder/decoder 2003, that then calculates a binary Huffman codeword for the mismatched word and adds the codeword and original data to the word library 1701 as a new key-value pair. The newly produced codeword may then be appended to the output stream. In arrangements where a mismatch indicator is included in a received data stream, this may be used to preemptively identify a substring that is not in word library 1701 (for example, if it was identified as a mismatch on the transmission end) and handled accordingly without the need for a library lookup.

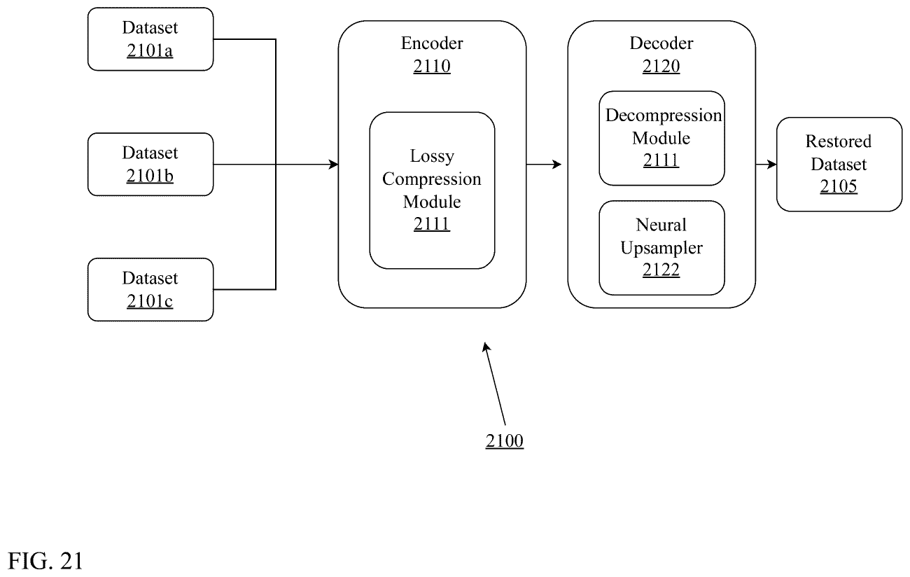

FIG. 21 is a block diagram illustrating an exemplary system architecture 2100 for upsampling of decompressed data after lossy compression using a neural network, according to an embodiment. According to the embodiment, the system 2100 comprises an encoder module 2110 configured to receive two or more datasets 2101a-n which are substantially correlated and perform lossy compression on the received dataset, and a decoder module 2120 configured to receive a compressed bit stream and use a trained neural network to output a reconstructed dataset which can restore most of the “lost” data due to the lossy compression. Datasets 2101a-n may comprise streaming data or data received in a batch format. Datasets 2101a-n may comprise one or more datasets, data streams, data files, or various other types of data structures which may be compressed. Furthermore, dataset 2101a-n may comprise n-channel data comprising a plurality of data channels sent via a single data stream.

Encoder 2110 may utilize a lossy compression module 2111 to perform lossy compression on a received dataset 2101a-n. The type of lossy compression implemented by lossy compression module 2111 may be dependent upon the data type being processed. For example, for SAR imagery data, High Efficiency Video Coding (HEVC) may be used to compress the dataset. In another example, if the data being processed is time-series data, then delta encoding may be used to compress the dataset. The encoder 2110 may then send the compressed data as a compressed data stream to a decoder 2120 which can receive the compressed data stream and decompress the data using a decompression module 2121.

The decompression module 2121 may be configured to perform data decompression a compressed data stream using an appropriate data decompression algorithm. The decompressed data may then be used as input to a neural upsampler 2122 which utilizes a trained neural network to restore the decompressed data to nearly its original state 2105 by taking advantage of the information embedded in the correlation between the two or more datasets 2101a-n.

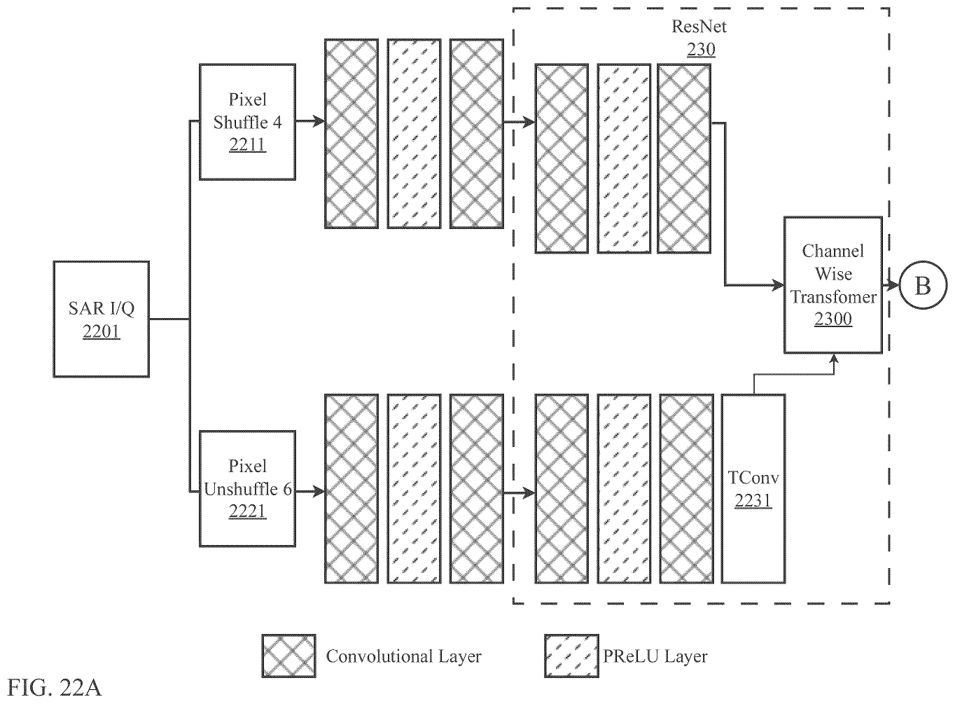

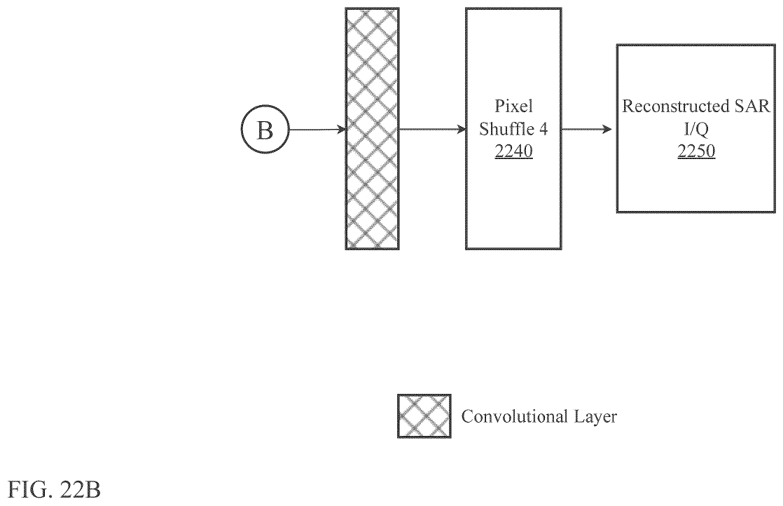

FIGS. 22A and 22B illustrate an exemplary architecture for an AI deblocking network configured to provide deblocking for dual-channel data stream comprising SAR I/Q data, according to an embodiment. In the context of this disclosure, dual-channel data refers to fact that SAR image signal can be represented as two (dual) components (i.e., I and Q) which are correlated to each other in some manner. In the case of I and Q, their correlation is that they can be transformed into phase and amplitude information and vice versa. AI deblocking network utilizes a deep learned neural network architecture for joint frequency and pixel domain learning. According to the embodiment, a network may be developed for joint learning across one or more domains. As shown, the top branch 2210 is associated with the pixel domain learning and the bottom branch 2220 is associated with the frequency domain learning. According to the embodiment, the AI deblocking network receives as input complex-valued SAR image I and Q channels 2201 which, having been encoded via encoder 2110, has subsequently been decompressed via decoder 2120 before being passed to AI deblocking network for image enhancement via artifact removal. Inspired by the residual learning network and the MSAB attention mechanism, AI deblocking network employs resblocks that take two inputs. In some implementations, to reduce complexity the spatial resolution may be downsampled to one-half and one-fourth. During the final reconstruction the data may be upsampled to its original resolution. In one implementation, in addition to downsampling, the network employs deformable convolution to extract initial features, which are then passed to the resblocks. In an embodiment, the network comprises one or more resblocks and one or more convolutional filters. In an embodiment, the network comprises 8 resblocks and 64 convolutional filters.

Deformable convolution is a type of convolutional operation that introduces spatial deformations to the standard convolutional grid, allowing the convolutional kernel to adaptively sample input features based on the learned offsets. It's a technique designed to enhance the modeling of spatial relationships and adapt to object deformations in computer vision tasks. In traditional convolutional operations, the kernel's positions are fixed and aligned on a regular grid across the input feature map. This fixed grid can limit the ability of the convolutional layer to capture complex transformations, non-rigid deformations, and variations in object appearance. Deformable convolution aims to address this limitation by introducing the concept of spatial deformations. Deformable convolution has been particularly effective in tasks like object detection and semantic segmentation, where capturing object deformations and accurately localizing object boundaries are important. By allowing the convolutional kernels to adaptively sample input features from different positions based on learned offsets, deformable convolution can improve the model's ability to handle complex and diverse visual patterns.

According to an embodiment, the network may be trained as a two-stage process, each utilizing specific loss functions. During the first stage, a mean squared error (MSE) function is used in the I/Q domain as a primary loss function for the AI deblocking network. The loss function of the SAR I/Q channel L_{SAR} is defined as:

$${L}_{SAR} = 𝔼 [ {‖ I - {I}_{amp} ‖}_{2} ]$$

Moving to the second stage, the network reconstructs the amplitude component and computes the amplitude loss using MSE as follows:

$${L}_{amp} = 𝔼 [ {‖ {I}_{amp} - {I}_{dec , amp} ‖}_{2} ]$$

To calculate the overall loss, the network combines the SAR loss and the amplitude loss, incorporating a weighting factor, α, for the amplitude loss. The total loss is computed as:

$${L}_{total} = {L}_{SAR} + α \times {L}_{amp}$$

The weighting factor value may be selected based on the dataset used during network training. In an embodiment, the network may be trained using two different SAR datasets: the National Geospatial-Intelligence Agency (NGA) SAR dataset and the Sandia National Laboratories Mini SAR Complex Imagery dataset, both of which feature complex-valued SAR images. In an embodiment, the weighting factor is set to 0.0001 for the NGA dataset and 0.00005 for the Sandia dataset. By integrating both the SAR and amplitude losses in the total loss function, the system effectively guides the training process to simultaneously address the removal of the artifacts and maintain the fidelity of the amplitude information. The weighting factor, α, enables AI deblocking network to balance the importance of the SAR loss and the amplitude loss, ensuring comprehensive optimization of the network during the training stages. In some implementations, diverse data augmentation techniques may be used to enhance the variety of training data. For example, techniques such as horizontal and vertical flops and rotations may be implemented on the training dataset. In an embodiment, model optimization is performed using MSE loss and Adam optimizer with a learning rate initially set to 1×10⁻⁴ and decreased by a factor of 2 at epochs 100, 200, and 250, with a total of 300 epochs. In an implementation, the batch size is set to 256×256 with each batch containing 16 images.

Both branches first pass through a pixel unshuffling layer 2211, 2221 which implements a pixel unshuffling process on the input data. Pixel unshuffling is a process used in image processing to reconstruct a high-resolution image from a low-resolution image by rearranging or “unshuffling” the pixels. The process can involve the following steps, low-resolution input, pixel arrangement, interpolation, and enhancement. The input to the pixel unshuffling algorithm is a low-resolution image (i.e., decompressed, quantized SAR I/Q data). This image is typically obtained by downscaling a higher-resolution image such as during the encoding process executed by encoder 110. Pixel unshuffling aims to estimate the original high-resolution pixel values by redistributing and interpolating the low-resolution pixel values. The unshuffling process may involve performing interpolation techniques, such as nearest-neighbor, bilinear, or more sophisticated methods like bicubic or Lanczos interpolation, to estimate the missing pixel values and generate a higher-resolution image.

The output of the unshuffling layers 2211, 2221 may be fed into a series of layers which can include one or more convolutional layers and one or more parametric rectified linear unit (PReLU) layers. A legend is depicted for both FIG. 22A and FIG. 22B which indicates the cross hatched block represents a convolutional layer and the dashed block represents a PReLU layer. Convolution is the first layer to extract features from an input image. Convolution preserves the relationship between pixels by learning image features using small squares of input data. It is a mathematical operation that takes two inputs such as an image matrix and a filter or kernel. The embodiment features a cascaded ResNet-like structure comprising 8 ResBlocks to effectively process the input data. The filter size associated with each convolutional layer may be different. The filter size used for the pixel domain of the top branch may be different than the filter size used for the frequency domain of the bottom branch.

A PReLU layer is an activation function used in neural networks. The PReLU activation function extends the ReLU by introducing a parameter that allows the slope for negative values to be learned during training. The advantage of PReLU over ReLU is that it enables the network to capture more complex patterns and relationships in the data. By allowing a small negative slope for the negative inputs, the PReLU can learn to handle cases where the output should not be zero for all negative values, as is the case with the standard ReLU. In other implementations, other non-linear functions such as tanh or sigmoid can be used instead of PReLU.

After passing through a series of convolutional and PReLU layers, both branches enter the resnet 2230 which further comprises more convolutional and PReLU layers. The frequency domain branch is slightly different than the pixel domain branch once inside ResNet 2230, specifically the frequency domain is processed by a transposed convolutional (TConv) layer 2231. Transposed convolutions are a type of operation used in neural networks for tasks like image generation, image segmentation, and upsampling. They are used to increase the spatial resolution of feature maps while maintaining the learned relationships between features. Transposed convolutions aim to increase spatial dimensions of feature maps, effectively “upsampling” them. This is typically done by inserting zeros (or other values) between existing values to create more space for new values.

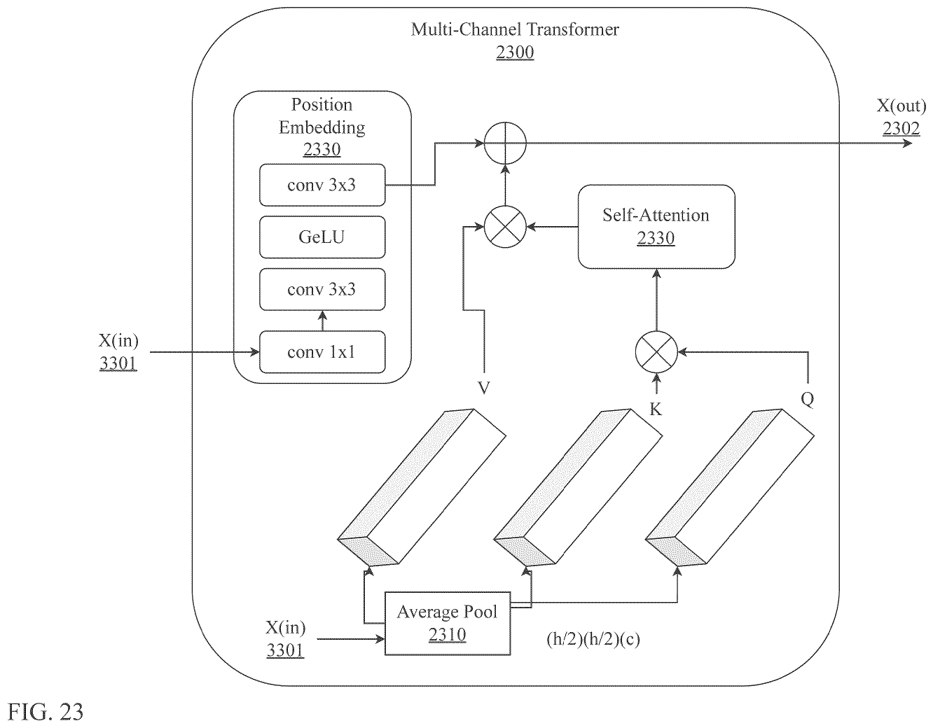

Inside ResBlock 2230 the data associated with the pixel and frequency domains are combined back into a single stream by using the output of the Tconv 2231 and the output of the top branch. The combined data may be used as input for a channel-wise transformer 2300. In some embodiments, the channel-wise transformer may be implemented as a multi-scale attention block utilizing the attention mechanism. For more detailed information about the architecture and functionality of channel-wise transformer 2300 refer to FIG. 23. The output of channel-wise transformer 2300 may be a bit stream suitable for reconstructing the original SAR I/Q image. FIG. 22B shows the output of ResBlock 2230 is passed through a final convolutional layer before being processed by a pixel shuffle layer 2240 which can perform upsampling on the data prior to image reconstruction. The output of the AI deblocking network may be passed through a quantizer 2124 for dequantization prior to producing a reconstructed SAR I/Q image 2250.

FIG. 23 is a block diagram illustrating an exemplary architecture for a component of the system for SAR image compression, the channel-wise transformer 2300. According to the embodiment, channel-wise transformer receives an input signal, xᵢₙ 2301, the input signal comprising SAR I/Q data which is being processed by AI deblocking network 2123. The input signal may be copied and follow two paths through multi-channel transformer 2300.

A first path may process input data through a position embedding module 2330 comprising series of convolutional layers as well as a Gaussian Error Linear Unit (GeLU). In traditional recurrent neural networks or convolutional neural networks, the order of input elements is inherently encoded through the sequential or spatial nature of these architectures. However, in transformer-based models, where the attention mechanism allows for non-sequential relationships between tokens, the order of tokens needs to be explicitly conveyed to the model. Position embedding module 2330 may represent a feedforward neural network (position-wise feedforward layers) configured to add position embeddings to the input data to convey the spatial location or arrangement of pixels in an image. The output of position embedding module 2330 may be added to the output of the other processing path the received input signal is processed through.

A second path may process the input data. It may first be processed via a channel-wise configuration and then through a self-attention layer 2320. The signal may be copied/duplicated such that a copy of the received signal is passed through an average pool layer 2310 which can perform a downsampling operation on the input signal. It may be used to reduce the spatial dimensions (e.g., width and height) of feature maps while retaining the most important information. Average pooling functions by dividing the input feature map into non-overlapping rectangular or square regions (often referred to as pooling windows or filters) and replacing each region with the average of the values within that region. This functions to downsample the input by summarizing the information within each pooling window.

Self-attention layer 2320 may be configured to provide an attention to AI deblocking network 2123. The self-attention mechanism, also known as intra-attention or scaled dot-product attention, is a fundamental building block used in various deep learning models, particularly in transformer-based models. It plays a crucial role in capturing contextual relationships between different elements in a sequence or set of data, making it highly effective for tasks involving sequential or structured data like complex-valued SAR I/Q channels. Self-attention layer 320 allows each element in the input sequence to consider other elements and weigh their importance based on their relevance to the current element. This enables the model to capture dependencies between elements regardless of their positional distance, which is a limitation in traditional sequential models like RNNs and LSTMs.

The input 2301 and downsampled input sequence is transformed into three different representations: Query (Q), Key (K), and Value (V). These transformations (w^{V}, w^{K}, and w^{Q}) are typically linear projections of the original input. For each element in the sequence, the dot product between its Query and the Keys of all other elements is computed. The dot products are scaled by a factor to control the magnitude of the attention scores. The resulting scores may be normalized using a softmax function to get attention weights that represent the importance of each element to the current element. The Values (V) of all elements are combined using the attention weights as coefficients. This produces a weighted sum, where elements with higher attention weights contribute more to the final representation of the current element. The weighted sum is the output of the self-attention mechanism for the current element. This output captures contextual information from the entire input sequence.

The output of the two paths (i.e., position embedding module 2330 and self-attention layer 320) may be combined into a single output data stream xₒᵤₜ 2302.

### Detailed Description of Exemplary Aspects

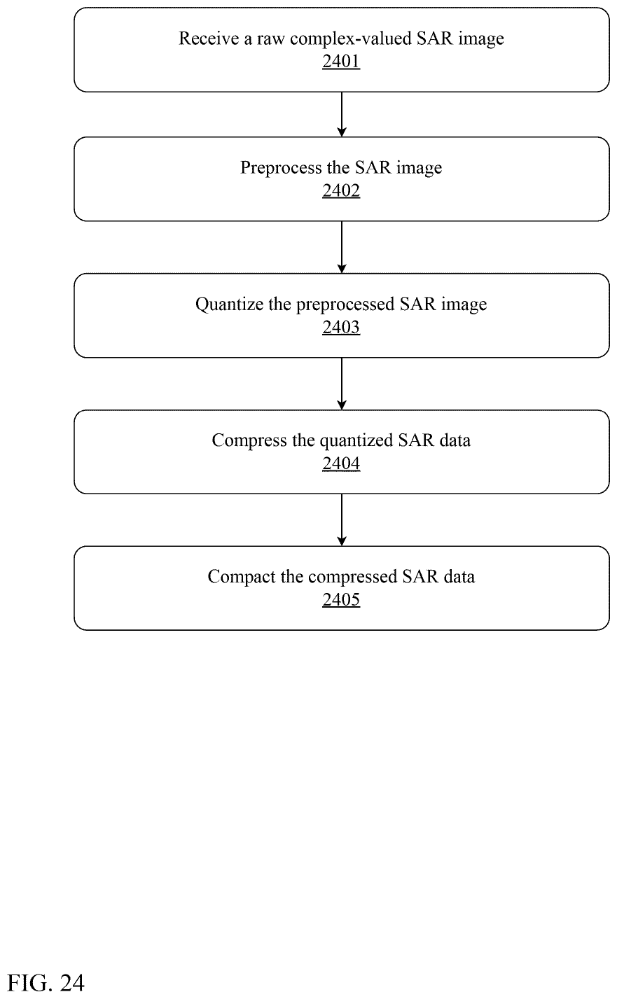

FIG. 24 is a flow diagram illustrating an exemplary method 2400 for complex-valued SAR image compression, according to an embodiment. According to the embodiment, the process begins at step 2401 when encoder 2410 receives a raw complex-valued SAR image. The complex-valued SAR image comprises both I and Q components. In some embodiments, the I and Q components may be processed as separate channels. At step 2402, the received SAR image may be preprocessed for further processing by encoder 2110. For example, the input image may be clipped or otherwise transformed in order to facilitate further processing. As a next step 2403, the preprocessed data may be passed to quantizer 2112 which quantizes the data. The next step 2404, comprises compressing the quantized SAR data using a compression algorithm known to those with skill in the art. In an embodiment, the compression algorithm may comprise HEVC encoding for both compression and decompression of SAR data. As a last step 2405, the compressed data may be compacted. The compaction may be a lossless compaction technique. The output of method 2400 is a compressed, compacted bit stream of SAR image data which can be stored in a database, requiring much less storage space than would be required to store the original, raw SAR image. The compressed and compacted bit stream may be transmitted to an endpoint for storage or processing. Transmission of the compressed and compacted data require less bandwidth and computing resources than transmitting raw SAR image data.

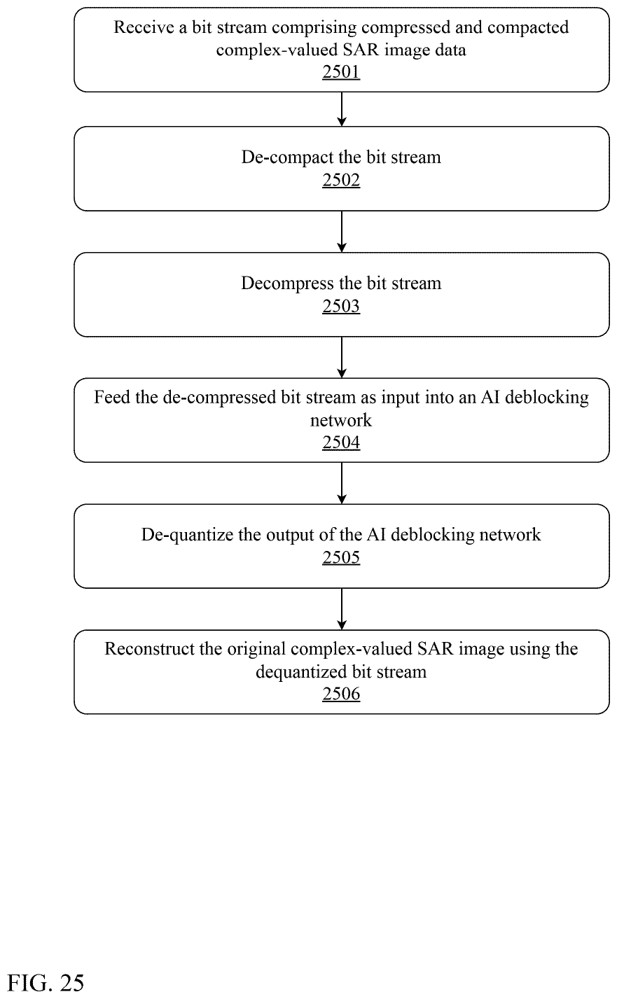

FIG. 25 is a flow diagram illustrating and exemplary method 2500 for decompression of a complex-valued SAR image, according to an embodiment. According to the embodiment, the process begins at step 2501 when decoder 2120 receives a bit stream comprising compressed and compacted complex-valued SAR image data. The compressed bit stream may be received from encoder 2110 or from a suitable data storage device. At step 2502, the received bit stream is first de-compacted to produce an encoded (compressed) bit stream. In some embodiments, a data reconstruction engine may be implemented as a system for de-compacting a received bit stream. The next step 2503, comprising decompressing the de-compacted bit stream using a suitable compression algorithm known to those with skill in the art, such as HEVC encoding. At step 2504, the de-compressed SAR data may be fed as input into AI deblocking network 2123 for image enhancement via a trained deep learning network. The AI deblocking network may utilize a series of convolutional layers and/or ResBlocks to process the input data and perform artifact removal on the de-compressed SAR image data. AI deblocking network may be further configured to implement an attention mechanism for the model to capture dependencies between elements regardless of their positional distance. In an embodiment, during training of AI deblocking network, the amplitude loss in conjunction with the SAR loss may be computed and accounted for, further boosting the compression performance of system 2100. The output of AI deblocking network 123 can be sent to a quantizer 2124 which can execute step 2505 by de-quantizing the output bit stream from AI deblocking network. As a last step 2506, system can reconstruct the original complex-valued SAR image using the de-quantized bit stream.

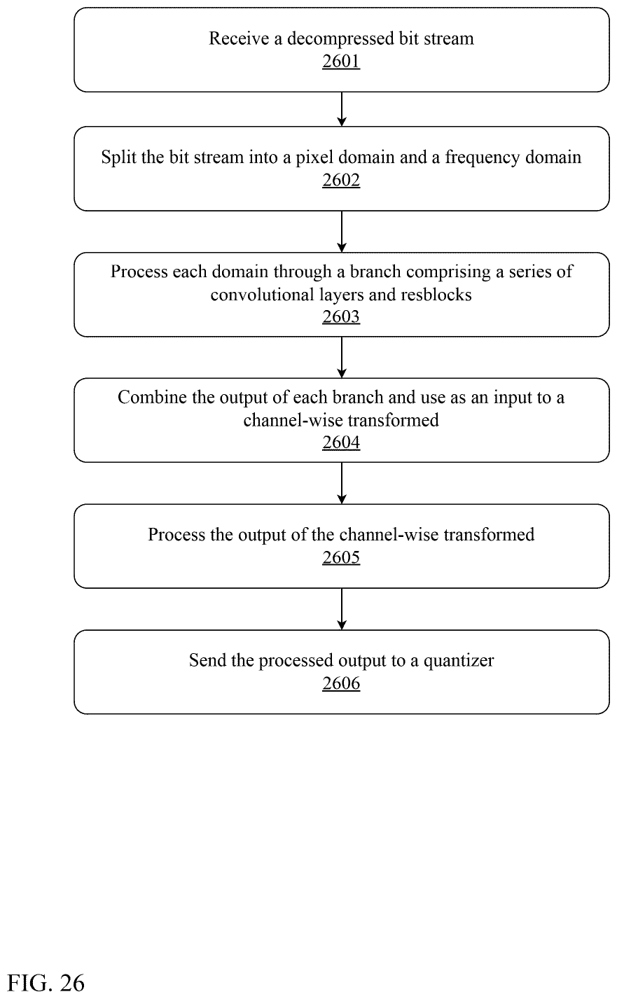

FIG. 26 is a flow diagram illustrating an exemplary method for deblocking using a trained deep learning algorithm, according to an embodiment. According to the embodiment, the process begins at step 2601 wherein the trained deep learning algorithm (i.e., AI deblocking network 2123) receives a decompressed bit stream comprising SAR I/Q image data. At step 2602, the bit stream is split into a pixel domain and a frequency domain. Each domain may pass through AI deblocking network, but have separate, almost similar processing paths. As a next step 2603, each domain is processed through its respective branch, the branch comprising a series of convolutional layers and ResBlocks. In some implementations, frequency domain may be further processed by a transpose convolution layer. The two branches are combined and used as input for a multi-channel transformer with attention mechanism at step 2604. Multi-channel transformer 2300 may perform functions such as downsampling, positional embedding, and various transformations, according to some embodiments. Multi-channel transformer 2300 may comprise one or more of the following components: channel-wise attention, transformer self-attention, and/or feedforward layers. In an implementation, the downsampling may be performed via average pooling. As a next step 2605, the AI deblocking network processes the output of the channel-wise transformer. The processing may include the steps of passing the output through one or more convolutional or PReLU layers and/or upsampling the output. As a last step 2606, the processed output may be forwarded to quantizer 2124 or some other endpoint for storage or further processing.

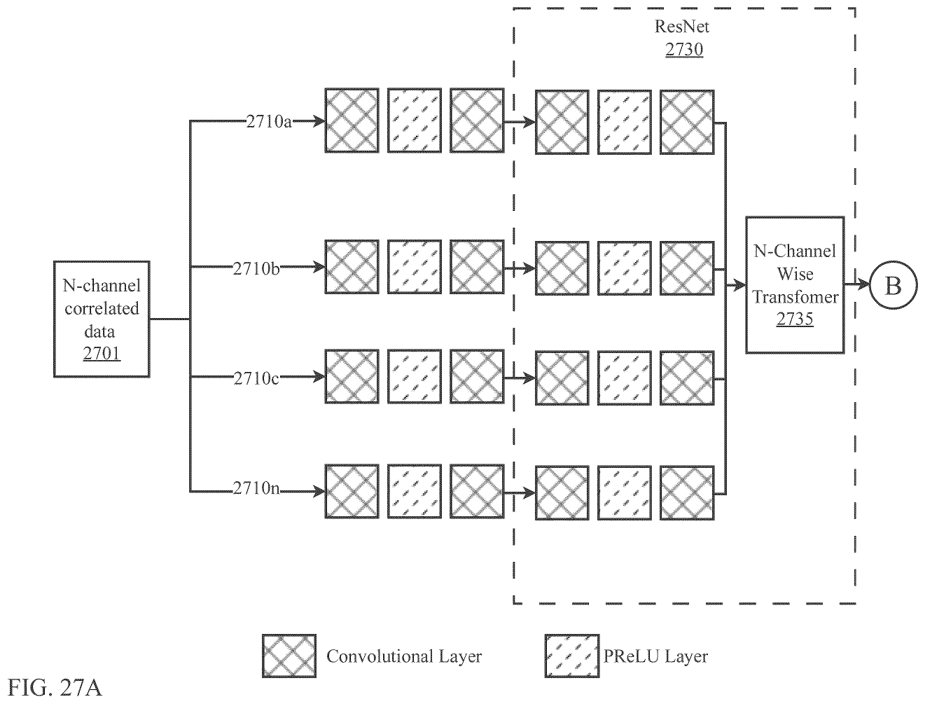

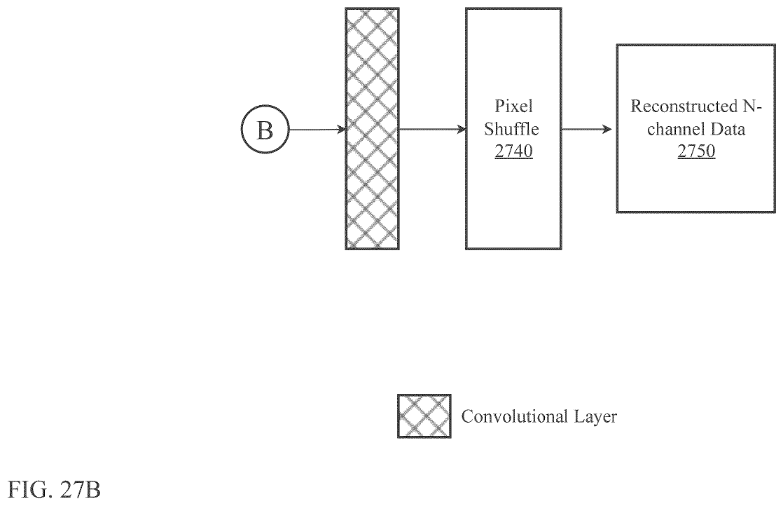

FIGS. 27A and 27B illustrate an exemplary architecture for an AI deblocking network configured to provide deblocking for a general N-channel data stream, according to an embodiment. The term “N-channel” refers to data that is composed of multiple distinct channels of modalities, where each channel represents a different aspect of type of information. These channels can exist in various forms, such as sensor readings, image color channels, or data streams, and they are often used together to provide a more comprehensive understanding of the underlying phenomenon. Examples of N-channel data include, but is not limited to, RGB images (e.g., in digital images, the red, green, and blue channels represent different color information; combining these channels allows for the representation of a wide range of colors), medical imaging (e.g., may include Magnetic Resonance Imaging scans with multiple channels representing different tissue properties, or Computed Tomography scans with channels for various types of X-ray attenuation), audio data (e.g., stereo or multi-channel audio recordings where each channel corresponds to a different microphone or audio source), radar and lidar (e.g., in autonomous vehicles, radar and lidar sensors provide multi-channel data, with each channel capturing information about objects' positions, distances, and reflectivity) SAR image data, text data (e.g., in natural language processing, N-channel data might involve multiple sources of text, such as social media posts and news articles, each treated as a separate channel to capture different textual contexts), sensor networks (e.g., environmental monitoring systems often employ sensor networks with multiple sensors measuring various parameters like temperature, humidity, air quality, and more. Each sensor represents a channel), climate data, financial data, and social network data.

The disclosed AI deblocking network may be trained to process any type of N-channel data, if the N-channel data has a degree of correlation. More correlation between and among the multiple channels yields a more robust and accurate AI deblocking network capable of performing high quality compression artifact removal on the N-channel data stream. A high degree of correlation implies a strong relationship between channels. Using SAR image data has been used herein as an exemplary use case for an AI deblocking network for a N-channel data stream comprising 2 channels, the In-phase and Quadrature components (i.e., I and Q, respectively).

Exemplary data correlations that can be exploited in various implementations of AI deblocking network can include, but are not limited to, spatial correlation, temporal correlation, cross-sectional correlation (e.g., This occurs when different variables measured at the same point in time are related to each other), longitudinal correlation, categorical correlation, rank correlation, time-space correlation, functional correlation, and frequency domain correlation, to name a few.

As shown, an N-channel AI deblocking network may comprise a plurality of branches 2710a-n. The number of branches is determined by the number of channels associated with the data stream. Each branch may initially be processed by a series of convolutional and PReLU layers. Each branch may be processed by resnet 2730 wherein each branch is combined back into a single data stream before being input to N-channel wise transformer 2735, which may be a specific configuration of transformer 2300. The output of N-channel wise transformer 2735 may be sent through a final convolutional layer before passing through a last pixel shuffle layer 2740. The output of AI deblocking network for N-channel video/image data is the reconstructed N-channel data 2750.

As an exemplary use case, video/image data may be processed as a 3-channel data stream comprising Green (G), Red (R), and Blue (B) channels. An AI deblocking network may be trained that provides compression artifact removal of video/image data. Such a network would comprise 3 branches, wherein each branch is configured to process one of the three channels (R, G, or B). For example, branch 2710a may correspond to the R-channel, branch 2710b to the G-channel, and branch 2710c to the B-channel. Each of these channels may be processed separately via their respective branches before being combined back together inside resnet 2730 prior to being processed by N-channel wise transformer 2735.

As another exemplary use case, a sensor network comprising a half dozen sensors may be processed as a 6-channel data stream. The exemplary sensor network may include various types of sensors collecting different types of, but still correlated, data. For example, sensor networks can include a pressure sensor, a thermal sensor, a barometer, a wind speed sensor, a humidity sensor, and an air quality sensor. These sensors may be correlated to one another in at least one way. For example, the six sensors in the sensor network may be correlated both temporally and spatially, wherein each sensor provides a time series data stream which can be processed by one of the 6 channels 2710a-n of AI deblocking network. As long as AI deblocking network is trained on N-channel data with a high degree of correlation and which is representative of the N-channel data it will encounter during model deployment, it can reconstruct the original data using the methods described herein.

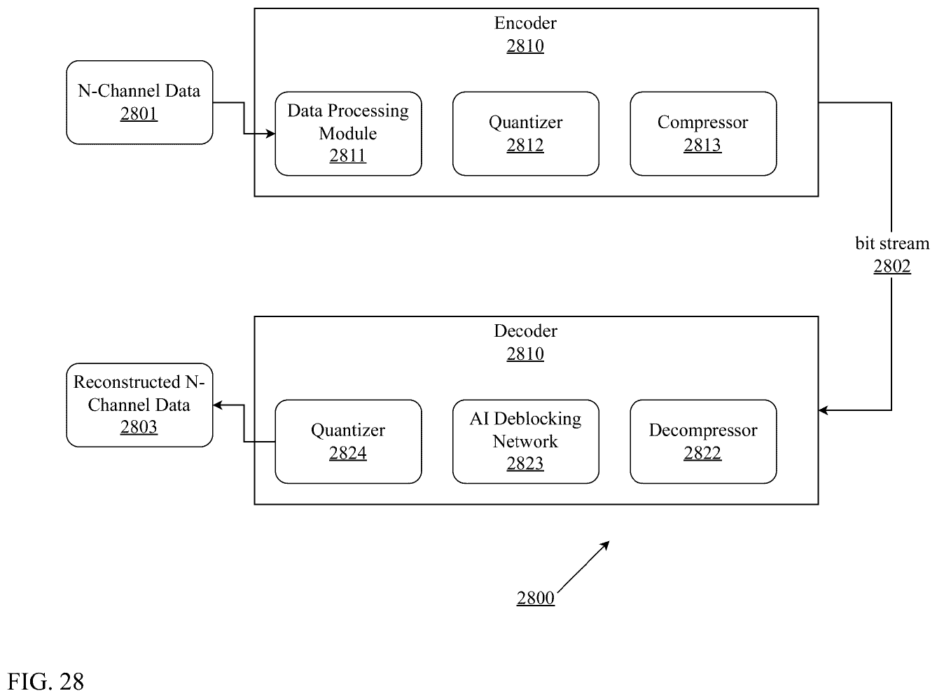

FIG. 28 is a block diagram illustrating an exemplary system architecture 2800 for N-channel data compression with predictive recovery, according to an embodiment. According to the embodiment, the system 2800 comprises an encoder module 2810 configured to receive as input N-channel data 2801 and compress and compact the input data into a bitstream 2102, and a decoder module 2120 configured to receive and decompress the bitstream 2802 to output a reconstructed N-channel data 2803.

A data processor module 2811 may be present and configured to apply one or more data processing techniques to the raw input data to prepare the data for further processing by encoder 2810. Data processing techniques can include (but are not limited to) any one or more of data cleaning, data transformation, encoding, dimensionality reduction, data slitting, and/or the like.

After data processing, a quantizer 2812 performs uniform quantization on the n-number of channels. Quantization is a process used in various fields, including signal processing, data compression, and digital image processing, to represent continuous or analog data using a discrete set of values. It involves mapping a range of values to a smaller set of discrete values. Quantization is commonly employed to reduce the storage requirements or computational complexity of digital data while maintaining an acceptable level of fidelity or accuracy. Compressor 2813 may be configured to perform data compression on quantized N-channel data using a suitable conventional compression algorithm.

At the endpoint which receives the transmitted compacted bitstream 2802 may be decoder module 2820 configured to restore the compacted data into the original SAR image by essentially reversing the process conducted at encoder module 2810. The received bitstream may first be (optionally) passed through a lossless compactor which de-compacts the data into an encoded bitstream. In an embodiment, a data reconstruction engine may be implemented to restore the compacted bitstream into its encoded format. The encoded bitstream may flow from compactor to decompressor 2822 wherein a data compaction technique may be used to decompress the encoded bitstream into the I/Q channels. It should be appreciated that lossless compactor components are optional components of the system and may or may not be present in the system, dependent upon the embodiment.

According to the embodiment, an Artificial Intelligence (AI) deblocking network 2823 is present and configured to utilize a trained deep learning network to provide compression artifact removal as part of the decoding process. AI deblocking network 2823 may leverage the relationship demonstrated between the various N-channels of a data stream to enhance the reconstructed N-channel data 2803. Effectively, AI deblocking network 2823 provides an improved and novel method for removing compression artifacts that occur during lossy compression/decompression using a network designed during the training process to simultaneously address the removal of artifacts and maintain fidelity of the original N-channel data signal, ensuring a comprehensive optimization of the network during the training stages.

The output of AI deblocking network 2823 may be dequantized by quantizer 2824, restoring the n-channels to their initial dynamic range. The dequantized n-channel data may be reconstructed and output 32803 by decoder module 2820 or stored in a database.

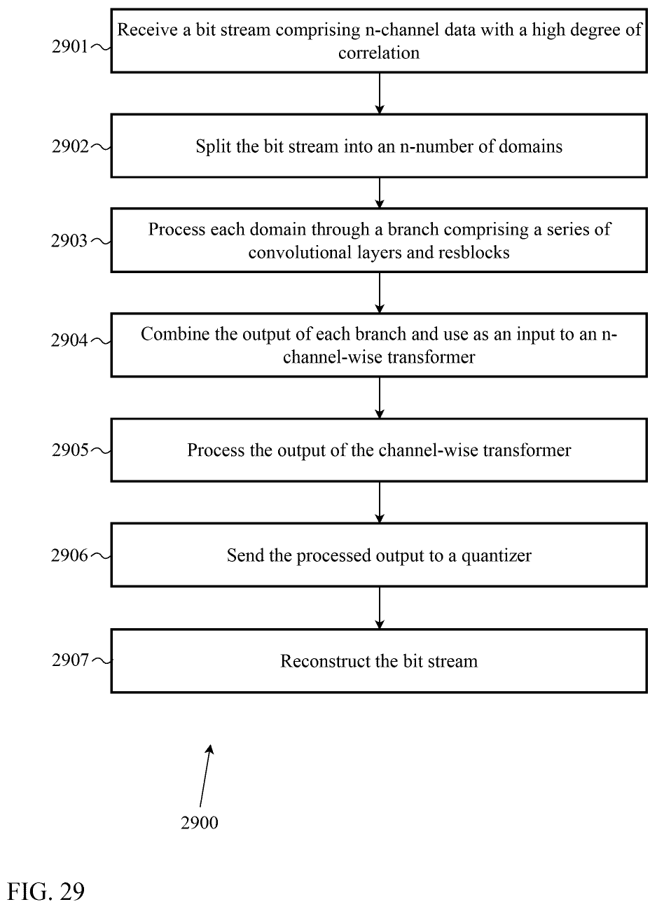

FIG. 29 is a flow diagram illustrating an exemplary method for processing a compressed n-channel bit stream using an AI deblocking network, according to an embodiment. According to the embodiment, the process begins at step 2901 when a decoder module 2820 receives, retrieves, or otherwise obtains a bit stream comprising n-channel data with a high degree of correlation. At step 2902, the bit stream is split into an n-number of domains. For example, if the received bit stream comprises image data in the form of R-, G,- and B-channels, then the bit stream would be split into 3 domains, one for each color (RGB). At step 2903, each domain is processed through a branch comprising a series of convolutional layers and ResBlocks. The number of layers and composition of said layers may depend upon the embodiment and the n-channel data being processed. At step 2904, the output of each branch is combined back into a single bitstream and used as an input into an n-channel wise transformer 2735. At step 2905, the output of the channel-wise transformer may be processed through one or more convolutional layers and/or transformation layers, according to various implementations. At step 2906, the processed output may be sent to a quantizer for upscaling and other data processing tasks. As a last step 2907, the bit stream may be reconstructed into its original uncompressed form.

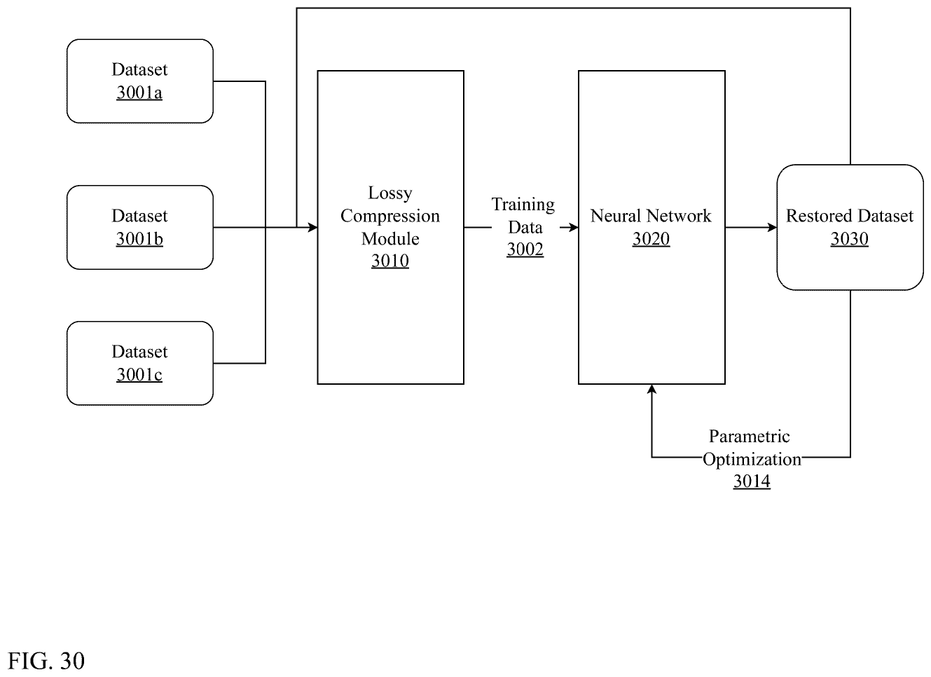

FIG. 30 is a block diagram illustrating a system for training a neural network to perform upsampling of decompressed data after lossy compression, according to an embodiment. The neural network may be referred to herein as a neural upsampler. According to the embodiment, a neural upsampler 3030 may be trained by taking training data 3002 which may comprise sets of two or more correlated datasets 2101a-n and performing whatever processing that is done to compress the data. This processing is dependent upon the type of data and may be different in various embodiments of the disclosed system and methods. For example, in the SAR imagery use case, the processing and lossy compression steps used quantization and HEVC compression of the I and Q images. The sets of compressed data may be used as input training data 3002 into the neural network 3020 wherein the target output is the original uncompressed data. Because there is correlation between the two or more datasets, the neural upsampler learns how to restore “lost” data by leveraging the cross-correlations.

For each type of input data, there may be different compression techniques used, and different data conditioning for feeding into the neural upsampler. For example, if the input datasets 2101a-n comprise a half dozen correlated time series from six sensors arranged on a machine, then delta encoding, or a swinging door algorithm may be implemented for data compression and processing.

The neural network 3020 may process the training data 3002 to generate model training output in the form of restored dataset 3030. The neural network output may be compared against the original dataset to check the model's precision and performance. If the model output does not satisfy a given criteria or some performance threshold, then parametric optimization 3015 may occur wherein the training parameters and/or network hyperparameters may be updated and applied to the next round of neural network training.

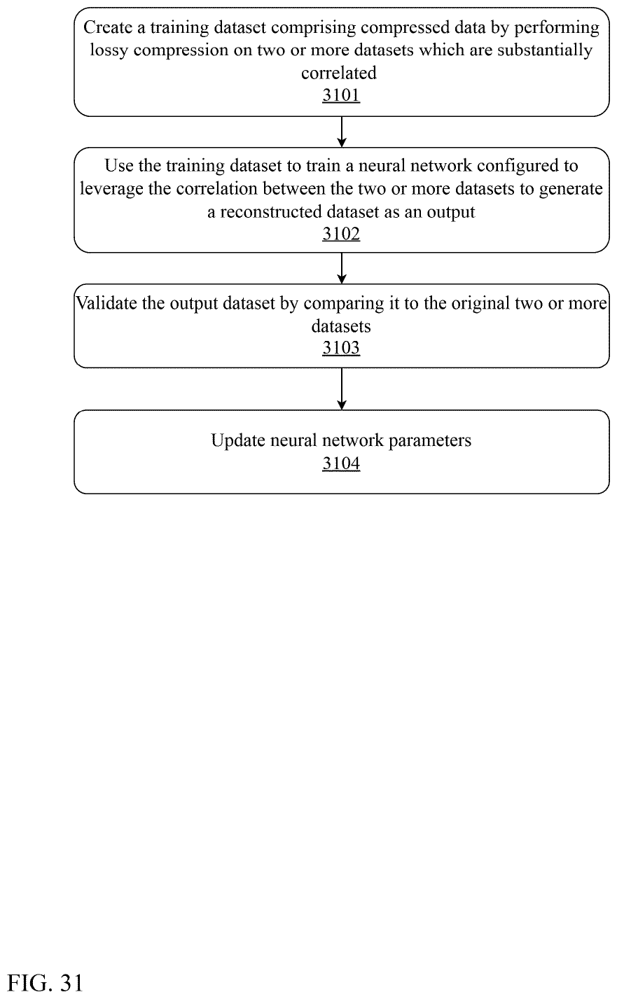

FIG. 31 is a flow diagram illustrating an exemplary method 3100 for training a neural network to perform upsampling of decompressed data after lossy compression, according to an embodiment. According to an embodiment, the process begins at step 3101 by creating a training dataset comprising compressed data by performing lossy compression on two or more datasets which are substantially correlated. As a next step 3102, the training dataset is used to train a neural network (i.e., neural upsampler) configured to leverage the correlation between the two or more datasets to generate as output a reconstructed dataset. At step 3103, the output of the neural network is compared to the original two more datasets to determine if the performance of the neural network at reconstructing the compressed data. If the model performance is not satisfactory, which may be determined by a set of criteria or some performance metric or threshold, then the neural network model parameters and/or hyperparameters may be updated 3104 and applied to the next round of training as the process moves to step 3102 and iterates through the method again.

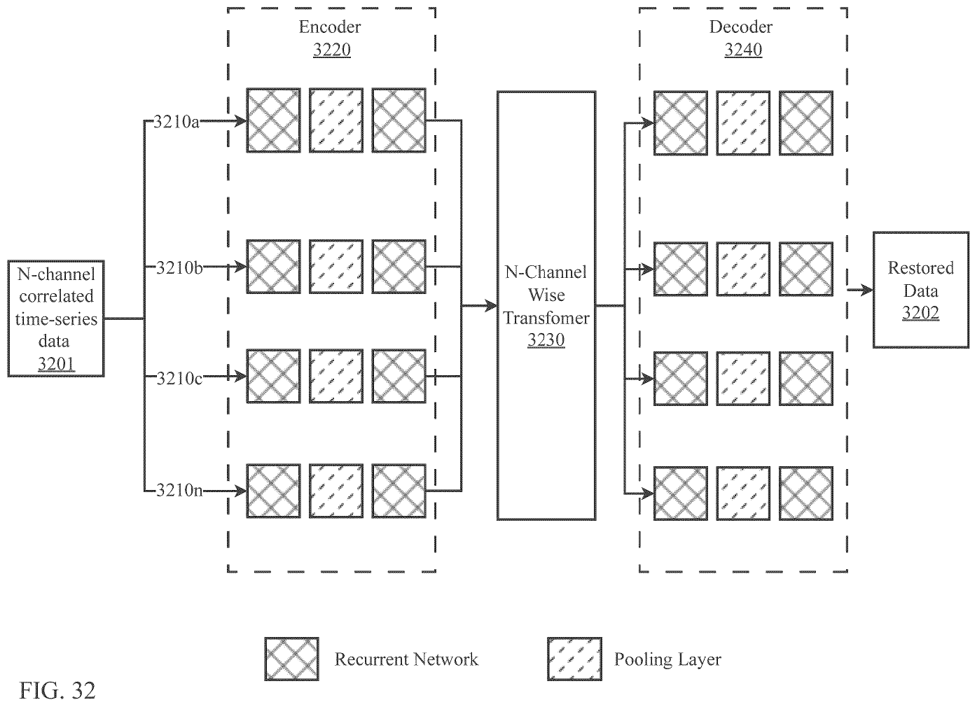

FIG. 32 is a block diagram illustrating an exemplary architecture for a neural upsampler configured to process N-channel time-series data, according to an embodiment. The neural upsampler may comprise a trained deep learning algorithm. According to the embodiment, a neural upsampler configured to process time-series data may comprise a recurrent autoencoder with an n-channel transformer attention network. In such an embodiment, the neural upsampler may be trained to process decompressed time-series data wherein the output of the upsampler is restored time-series data (i.e., restore most of the lost data due to the lossy compression). The upsampler may receive decompressed n-channel time-series data comprising two or more data sets of time-series data which are substantially correlated. For example, the two or more data sets may comprise multiple sets of Internet of Things (IoT) sensor data from sensors that are likely to be temporally correlated. For instance, consider a large number of sensors on a single complex machine (e.g., a combine tractor, a 3D printer, construction equipment, etc.) or a large number of sensors in a complex system such as a pipeline or refinery.

The n-channel time-series data may be received split into separate channels 3210a-n to be processed individually by encoder 3220. In some embodiments, encoder 3220 may employ a series of various data processing layers which may comprise recurrent neural network (RNN) layers, pooling layers, PReLU layers, and/or the like. In some implementations, one or more of the RNN layers may comprise a Long Short-Term Memory (LSTM) network. In some implementations, one or more of the RNN layers may comprise a sequence-to-sequence model. In yet another implementation, the one or more RNN layer may comprise a gate recurrent unit (GRU). Each channel may be processed by its own series of network layers wherein the encoder 3220 can learn a representation of the input data which can be used to determine the defining features of the input data. Each individual channel then feeds into an n-channel wise transformer 3230 which can learn the interdependencies between the two or more channels of correlated time-series data. The output of the n-channel wise transformer 3230 is fed into the decoder 3240 component of the recurrent autoencoder in order to restore missing data lost due to a lossy compression implemented on the time-series data. N-channel wise transformer 3230 is designed so that it can weigh the importance of different parts of the input data and then capture long-range dependencies between and among the input data. The decoder may process the output of the n-channel wise transformer 3230 into separate channels comprising various layers as described above. The output of decoder 3240 is the restored time-series data 3202, wherein most of the data which was “lost” during lossy compression can be recovered using the neural upsampler which leverages the interdependencies hidden within correlated datasets.

In addition to RNNs and their variants, other neural network architectures like CNNs and hybrid models that combine CNNs and RNNs can also be implemented for processing time series and sensor data, particularly when dealing with sensor data that can be structured as images or spectrograms. For example, if you had, say, 128 time series streams, it could be structured as two 64×64-pixel images (64 times series each, each with 64 time steps), and then use the same approach as the described above with respect to the SAR image use case. In an embodiment, a one-dimensional CNN can be used as a data processing layer in encoder 3220 and/or decoder 3240. The selection of the neural network architecture for time series data processing may be based on various factors including, but not limited to, the length of the input sequences, the frequency and regularity of the data points, the need to handle multivariate input data, the presence of exogenous variables or covariates, the computational resources available, and/or the like.

The exemplary time-series neural upsampler described in FIG. 32 may be trained on a training dataset comprising a plurality of compressed time-series data sourced from two or more datasets which are substantially correlated. For example, in a use case directed towards neural upsampling of IoT sensor data, the neural upsampler may be trained on a dataset comprising compressed IoT sensor data. During training, the output of the neural upsampler may be compared against the non-compressed version of the IoT sensor data to determine the neural upsampler's performance on restoring lost information.

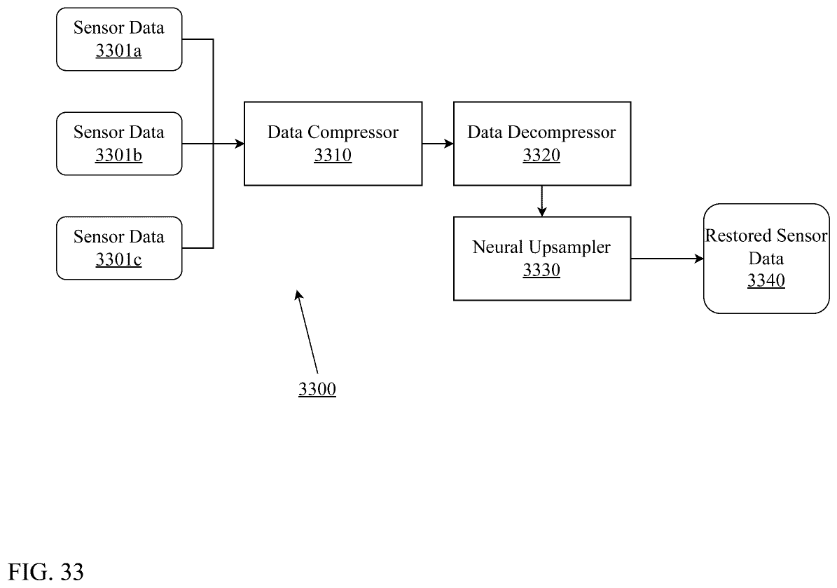

FIG. 33 is a block diagram illustrating an exemplary system architecture 3300 for upsampling of decompressed sensor data after lossy compression using a neural network, according to an embodiment. According to the embodiment, a neural upsampler 3330 is present and configured to receive decompressed sensor data (e.g., time-series data obtained from an IoT device) and restore the decompressed data by leveraging learned data correlations and inter- and intra-dependencies. According to an embodiment, the system may receive a plurality of sensor data 3301a-n from two or more sensors/devices, wherein the sensor data are substantially correlated. In an embodiment, the plurality of sensor data 3301a-n comprises time-series data. Time-series data received from two or more sensors may be temporally correlated, for example, IoT data from a personal fitness device and a blood glucose monitoring device during the time when a user of both devices is exercising may be correlated in time and by heart rate. As another example, a large number of sensors used to monitor a manufacturing facility may be correlated temporally.

A data compressor 3310 is present and configured to utilize one or more data compression methods on received sensor data 3301a-n. The data compression method chosen must be a lossy compression method. Exemplary types of lossy compression that may be used in some embodiments may be directed towards image or audio compression such as JPEG and MP3, respectively. For time series data lossy compression methods that may be implemented include (but is not limited to) one or more of the following: delta encoding, swinging door algorithm, batching, data aggregation, feature extraction. In an implementation, data compressor 3310 may implement network protocols specific for IoT such as message queuing telemetry transport (MQTT) for supporting message compression on the application layer and/or constrained application protocol (CoAP) which supports constrained nodes and networks and can be used with compression.

The compressed multi-channel sensor data 3301a-n may be decompressed by a data decompressor 3320 which can utilize one or more data decompression methods known to those with skill in the art. The output of data decompressor 3320 is a sensor data stream(s) of decompressed data which is missing information due to the lossy nature of the compression/decompression methods used. The decompressed sensor data stream(s) may be passed to neural upsampler 3330 which can utilize a trained neural network to restore most of the “lost” information associated with the decompressed sensor data stream(s) by leveraging the learned correlation(s) between and among the various sensor data streams. The output of neural upsampler 3330 is restored sensor data 3340.

### Exemplary Computing Environment

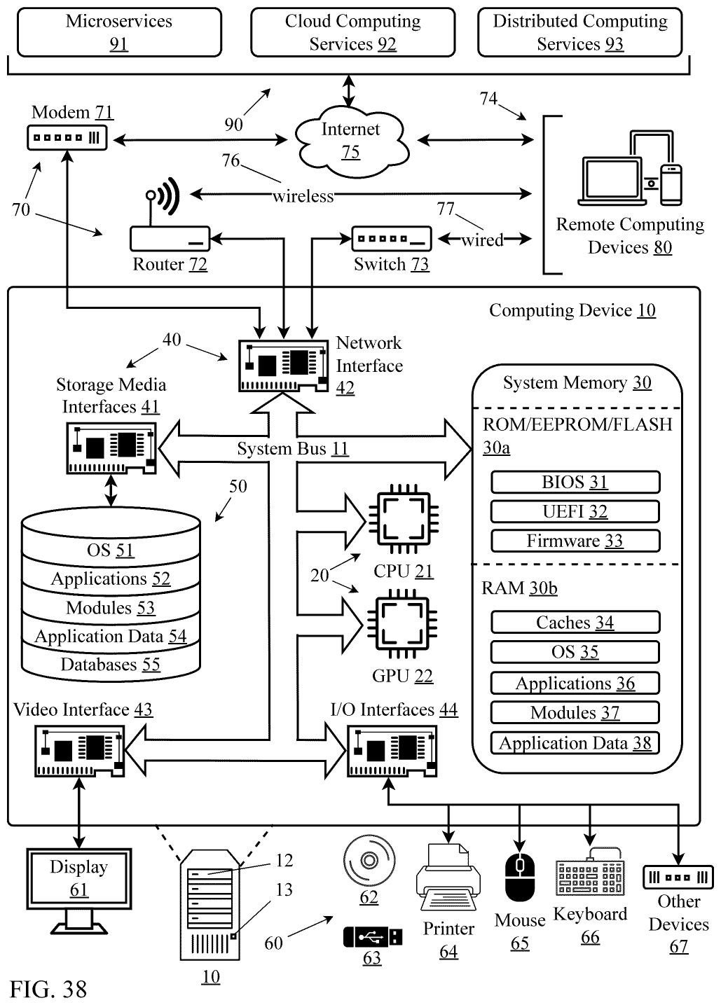

FIG. 38 illustrates an exemplary computing environment on which an embodiment described herein may be implemented, in full or in part. This exemplary computing environment describes computer-related components and processes supporting enabling disclosure of computer-implemented embodiments. Inclusion in this exemplary computing environment of well-known processes and computer components, if any, is not a suggestion or admission that any embodiment is no more than an aggregation of such processes or components. Rather, implementation of an embodiment using processes and components described in this exemplary computing environment will involve programming or configuration of such processes and components resulting in a machine specially programmed or configured for such implementation. The exemplary computing environment described herein is only one example of such an environment and other configurations of the components and processes are possible, including other relationships between and among components, and/or absence of some processes or components described. Further, the exemplary computing environment described herein is not intended to suggest any limitation as to the scope of use or functionality of any embodiment implemented, in whole or in part, on components or processes described herein.

The exemplary computing environment described herein comprises a computing device 10 (further comprising a system bus 11, one or more processors 20, a system memory 30, one or more interfaces 40, one or more non-volatile data storage devices 50), external peripherals and accessories 60, external communication devices 70, remote computing devices 80, and cloud-based services 90.

System bus 11 couples the various system components, coordinating operation of and data transmission between those various system components. System bus 11 represents one or more of any type or combination of types of wired or wireless bus structures including, but not limited to, memory busses or memory controllers, point-to-point connections, switching fabrics, peripheral busses, accelerated graphics ports, and local busses using any of a variety of bus architectures. By way of example, such architectures include, but are not limited to, Industry Standard Architecture (ISA) busses, Micro Channel Architecture (MCA) busses, Enhanced ISA (EISA) busses, Video Electronics Standards Association (VESA) local busses, a Peripheral Component Interconnects (PCI) busses also known as a Mezzanine busses, or any selection of, or combination of, such busses. Depending on the specific physical implementation, one or more of the processors 20, system memory 30 and other components of the computing device 10 can be physically co-located or integrated into a single physical component, such as on a single chip. In such a case, some or all of system bus 11 can be electrical pathways within a single chip structure.

Computing device may further comprise externally-accessible data input and storage devices 12 such as compact disc read-only memory (CD-ROM) drives, digital versatile discs (DVD), or other optical disc storage for reading and/or writing optical discs 62; magnetic cassettes, magnetic tape, magnetic disk storage, or other magnetic storage devices; or any other medium which can be used to store the desired content and which can be accessed by the computing device 10. Computing device may further comprise externally accessible data ports or connections 12 such as serial ports, parallel ports, universal serial bus (USB) ports, and infrared ports and/or transmitter/receivers. Computing device may further comprise hardware for wireless communication with external devices such as IEEE 1394 (“Firewire”) interfaces, IEEE 802.11 wireless interfaces, BLUETOOTH® wireless interfaces, and so forth. Such ports and interfaces may be used to connect any number of external peripherals and accessories 60 such as visual displays, monitors, and touch-sensitive screens 61, USB solid state memory data storage drives (commonly known as “flash drives” or “thumb drives”) 63, printers 64, pointers and manipulators such as mice 65, keyboards 66, and other devices 67 such as joysticks and gaming pads, touchpads, additional displays and monitors, and external hard drives (whether solid state or disc-based), microphones, speakers, cameras, and optical scanners.

Processors 20 are logic circuitry capable of receiving programming instructions and processing (or executing) those instructions to perform computer operations such as retrieving data, storing data, and performing mathematical calculations. Processors 20 are not limited by the materials from which they are formed, or the processing mechanisms employed therein, but are typically comprised of semiconductor materials into which many transistors are formed together into logic gates on a chip (i.e., an integrated circuit or IC). The term processor includes any device capable of receiving and processing instructions including, but not limited to, processors operating on the basis of quantum computing, optical computing, mechanical computing (e.g., using nanotechnology entities to transfer data), and so forth. Depending on configuration, computing device 10 may comprise more than one processor. For example, computing device 10 may comprise one or more central processing units (CPUs) 21, each of which itself has multiple processors or multiple processing cores, each capable of independently or semi-independently processing programming instructions. Further, computing device 10 may comprise one or more specialized processors such as a graphics processing unit (GPU) 22 configured to accelerate processing of computer graphics and images via a large array of specialized processing cores arranged in parallel.

System memory 30 is processor-accessible data storage in the form of volatile and/or nonvolatile memory. System memory 30 may be either or both of two types: non-volatile memory and volatile memory. Non-volatile memory 30a is not erased when power to the memory is removed and includes memory types such as read only memory (ROM), electronically erasable programmable memory (EEPROM), and rewritable solid state memory (commonly known as “flash memory”). Non-volatile memory 30a is typically used for long-term storage of a basic input/output system (BIOS) 31, containing the basic instructions, typically loaded during computer startup, for transfer of information between components within computing device, or a unified extensible firmware interface (UEFI), which is a modern replacement for BIOS that supports larger hard drives, faster boot times, more security features, and provides native support for graphics and mouse cursors. Non-volatile memory 30a may also be used to store firmware comprising a complete operating system 35 and applications 36 for operating computer-controlled devices. The firmware approach is often used for purpose-specific computer-controlled devices such as appliances and Internet-of-Things (IoT) devices where processing power and data storage space is limited. Volatile memory 30b is erased when power to the memory is removed and is typically used for short-term storage of data for processing. Volatile memory 30b includes memory types such as random-access memory (RAM), and is normally the primary operating memory into which the operating system 35, applications 36, program modules 37, and application data 38 are loaded for execution by processors 20. Volatile memory 30b is generally faster than non-volatile memory 30a due to its electrical characteristics and is directly accessible to processors 20 for processing of instructions and data storage and retrieval. Volatile memory 30b may comprise one or more smaller cache memories which operate at a higher clock speed and are typically placed on the same IC as the processors to improve performance.

Interfaces 40 may include, but are not limited to, storage media interfaces 41, network interfaces 42, display interfaces 43, and input/output interfaces 44. Storage media interface 41 provides the necessary hardware interface for loading data from non-volatile data storage devices 50 into system memory 30 and storage data from system memory 30 to non-volatile data storage device 50. Network interface 42 provides the necessary hardware interface for computing device 10 to communicate with remote computing devices 80 and cloud-based services 90 via one or more external communication devices 70. Display interface 43 allows for connection of displays 61, monitors, touchscreens, and other visual input/output devices. Display interface 43 may include a graphics card for processing graphics-intensive calculations and for handling demanding display requirements. Typically, a graphics card includes a graphics processing unit (GPU) and video RAM (VRAM) to accelerate display of graphics. One or more input/output (I/O) interfaces 44 provide the necessary support for communications between computing device 10 and any external peripherals and accessories 60. For wireless communications, the necessary radio-frequency hardware and firmware may be connected to I/O interface 44 or may be integrated into I/O interface 44.

Non-volatile data storage devices 50 are typically used for long-term storage of data. Data on non-volatile data storage devices 50 is not erased when power to the non-volatile data storage devices 50 is removed. Non-volatile data storage devices 50 may be implemented using any technology for non-volatile storage of content including, but not limited to, CD-ROM drives, digital versatile discs (DVD), or other optical disc storage; magnetic cassettes, magnetic tape, magnetic disc storage, or other magnetic storage devices; solid state memory technologies such as EEPROM or flash memory; or other memory technology or any other medium which can be used to store data without requiring power to retain the data after it is written. Non-volatile data storage devices 50 may be non-removable from computing device 10 as in the case of internal hard drives, removable from computing device 10 as in the case of external USB hard drives, or a combination thereof, but computing device will typically comprise one or more internal, non-removable hard drives using either magnetic disc or solid-state memory technology. Non-volatile data storage devices 50 may store any type of data including, but not limited to, an operating system 51 for providing low-level and mid-level functionality of computing device 10, applications 52 for providing high-level functionality of computing device 10, program modules 53 such as containerized programs or applications, or other modular content or modular programming, application data 54, and databases 55 such as relational databases, non-relational databases, object oriented databases, BOSQL databases, and graph databases.

Applications (also known as computer software or software applications) are sets of programming instructions designed to perform specific tasks or provide specific functionality on a computer or other computing devices. Applications are typically written in high-level programming languages such as C++, Java, and Python, which are then either interpreted at runtime or compiled into low-level, binary, processor-executable instructions operable on processors 20. Applications may be containerized so that they can be run on any computer hardware running any known operating system. Containerization of computer software is a method of packaging and deploying applications along with their operating system dependencies into self-contained, isolated units known as containers. Containers provide a lightweight and consistent runtime environment that allows applications to run reliably across different computing environments, such as development, testing, and production systems.

The memories and non-volatile data storage devices described herein do not include communication media. Communication media are means of transmission of information such as modulated electromagnetic waves or modulated data signals configured to transmit, not store, information. By way of example, and not limitation, communication media includes wired communications such as sound signals transmitted to a speaker via a speaker wire, and wireless communications such as acoustic waves, radio frequency (RF) transmissions, infrared emissions, and other wireless media.

External communication devices 70 are devices that facilitate communications between computing devices and either remote computing devices 80, or cloud-based services 90, or both. External communication devices 70 include, but are not limited to, data modems 71 which facilitate data transmission between computing device and the Internet 75 via a common carrier such as a telephone company or internet service provider (ISP), routers 72 which facilitate data transmission between computing device and other devices, and switches 73 which provide direct data communications between devices on a network. Here, modem 71 is shown connecting computing device 10 to both remote computing devices 80 and cloud-based services 90 via the Internet 75. While modem 71, router 72, and switch 73 are shown here as being connected to network interface 42, many different network configurations using external communication devices 70 are possible. Using external communication devices 70, networks may be configured as local area networks (LANs) for a single location, building, or campus, wide area networks (WANs) comprising data networks that extend over a larger geographical area, and virtual private networks (VPNs) which can be of any size but connect computers via encrypted communications over public networks such as the Internet 75. As just one exemplary network configuration, network interface 42 may be connected to switch 73 which is connected to router 72 which is connected to modem 71 which provides access for computing device 10 to the Internet 75. Further, any combination of wired 77 or wireless 76 communications between and among computing device 10, external communication devices 70, remote computing devices 80, and cloud-based services 90 may be used. Remote computing devices 80, for example, may communicate with computing device through a variety of communication channels 74 such as through switch 73 via a wired 77 connection, through router 72 via a wireless connection 76, or through modem 71 via the Internet 75. Furthermore, while not shown here, other hardware that is specifically designed for servers may be employed. For example, secure socket layer (SSL) acceleration cards can be used to offload SSL encryption computations, and transmission control protocol/internet protocol (TCP/IP) offload hardware and/or packet classifiers on network interfaces 42 may be installed and used at server devices.

In a networked environment, certain components of computing device 10 may be fully or partially implemented on remote computing devices 80 or cloud-based services 90. Data stored in non-volatile data storage device 50 may be received from, shared with, duplicated on, or offloaded to a non-volatile data storage device on one or more remote computing devices 80 or in a cloud computing service 92. Processing by processors 20 may be received from, shared with, duplicated on, or offloaded to processors of one or more remote computing devices 80 or in a distributed computing service 93. By way of example, data may reside on a cloud computing service 92, but may be usable or otherwise accessible for use by computing device 10. Also, certain processing subtasks may be sent to a microservice 91 for processing with the result being transmitted to computing device 10 for incorporation into a larger processing task. Also, while components and processes of the exemplary computing environment are illustrated herein as discrete units (e.g., OS 51 being stored on non-volatile data storage device 51 and loaded into system memory 35 for use) such processes and components may reside or be processed at various times in different components of computing device 10, remote computing devices 80, and/or cloud-based services 90.

In an implementation, the disclosed systems and methods may utilize, at least in part, containerization techniques to execute one or more processes and/or steps disclosed herein. Containerization is a lightweight and efficient virtualization technique that allows you to package and run applications and their dependencies in isolated environments called containers. One of the most popular containerization platforms is Docker, which is widely used in software development and deployment. Containerization, particularly with open-source technologies like Docker and container orchestration systems like Kubernetes, is a common approach for deploying and managing applications. Containers are created from images, which are lightweight, standalone, and executable packages that include application code, libraries, dependencies, and runtime. Images are often built from a Dockerfile or similar, which contains instructions for assembling the image. Docker files are configuration files that specify how to build a Docker image. Systems like Kubernetes also support containerd or CRI-O. They include commands for installing dependencies, copying files, setting environment variables, and defining runtime configurations. Docker images are stored in repositories, which can be public or private. Docker Hub is an exemplary public registry, and organizations often set up private registries for security and version control using tools such as Hub, JFrog Artifactory and Bintray, Github Packages or Container registries. Containers can communicate with each other and the external world through networking. Docker provides a bridge network by default but can be used with custom networks. Containers within the same network can communicate using container names or IP addresses.

Remote computing devices 80 are any computing devices not part of computing device 10. Remote computing devices 80 include, but are not limited to, personal computers, server computers, thin clients, thick clients, personal digital assistants (PDAs), mobile telephones, watches, tablet computers, laptop computers, multiprocessor systems, microprocessor based systems, set-top boxes, programmable consumer electronics, video game machines, game consoles, portable or handheld gaming units, network terminals, desktop personal computers (PCs), minicomputers, main frame computers, network nodes, virtual reality or augmented reality devices and wearables, and distributed or multi-processing computing environments. While remote computing devices 80 are shown for clarity as being separate from cloud-based services 90, cloud-based services 90 are implemented on collections of networked remote computing devices 80.

Cloud-based services 90 are Internet-accessible services implemented on collections of networked remote computing devices 80. Cloud-based services are typically accessed via application programming interfaces (APIs) which are software interfaces which provide access to computing services within the cloud-based service via API calls, which are pre-defined protocols for requesting a computing service and receiving the results of that computing service. While cloud-based services may comprise any type of computer processing or storage, three common categories of cloud-based services 90 are microservices 91, cloud computing services 92, and distributed computing services 93.

Microservices 91 are collections of small, loosely coupled, and independently deployable computing services. Each microservice represents a specific computing functionality and runs as a separate process or container. Microservices promote the decomposition of complex applications into smaller, manageable services that can be developed, deployed, and scaled independently. These services communicate with each other through well-defined application programming interfaces (APIs), typically using lightweight protocols like HTTP, gRPC, or message queues such as Kafka. Microservices 91 can be combined to perform more complex processing tasks.

Cloud computing services 92 are delivery of computing resources and services over the Internet 75 from a remote location. Cloud computing services 92 provide additional computer hardware and storage on as needed or subscription basis. Cloud computing services 92 can provide large amounts of scalable data storage, access to sophisticated software and powerful server-based processing, or entire computing infrastructures and platforms. For example, cloud computing services can provide virtualized computing resources such as virtual machines, storage, and networks, platforms for developing, running, and managing applications without the complexity of infrastructure management, and complete software applications over the Internet on a subscription basis.

Distributed computing services 93 provide large-scale processing using multiple interconnected computers or nodes to solve computational problems or perform tasks collectively. In distributed computing, the processing and storage capabilities of multiple machines are leveraged to work together as a unified system. Distributed computing services are designed to address problems that cannot be efficiently solved by a single computer or that require large-scale computational power. These services enable parallel processing, fault tolerance, and scalability by distributing tasks across multiple nodes.

Although described above as a physical device, computing device 10 can be a virtual computing device, in which case the functionality of the physical components herein described, such as processors 20, system memory 30, network interfaces 40, and other like components can be provided by computer-executable instructions. Such computer-executable instructions can execute on a single physical computing device, or can be distributed across multiple physical computing devices, including being distributed across multiple physical computing devices in a dynamic manner such that the specific, physical computing devices hosting such computer-executable instructions can dynamically change over time depending upon need and availability. In the situation where computing device 10 is a virtualized device, the underlying physical computing devices hosting such a virtualized computing device can, themselves, comprise physical components analogous to those described above, and operating in a like manner. Furthermore, virtual computing devices can be utilized in multiple layers with one virtual computing device executing within the construct of another virtual computing device. Thus, computing device 10 may be either a physical computing device or a virtualized computing device within which computer-executable instructions can be executed in a manner consistent with their execution by a physical computing device. Similarly, terms referring to physical components of the computing device, as utilized herein, mean either those physical components or virtualizations thereof performing the same or equivalent functions.

The skilled person will be aware of a range of possible modifications of the various aspects described above. Accordingly, the present invention is defined by the claims and their equivalents.

What is claimed is:

1. A system for network-optimized multi-type data compression and transmission, comprising:
a plurality of network nodes, each node comprising at least a memory and a processor;
a plurality of programming instructions stored in the memory and operable on the processor of each node, wherein the programming instructions, when operating on the processor, cause each network node to:
maintain a synchronized codebook repository;
analyze incoming data flows to:
classify data segments as either latency-critical or bandwidth-critical; and
determine optimal coding selection for bandwidth-critical segments;
process the data flows by:
transmitting latency-critical segments without compression;
compressing bandwidth-critical segments using at least one selected coding method from the synchronized codebook repository; and
maintain network synchronization by:
monitoring codebook utilization across nodes;
updating shared codebooks based on data flow patterns; and
propagating codebook updates to connected nodes.

2. The system of claim 1, wherein determining optimal coding selection comprises:
analyzing data characteristics, the data characteristics comprising one or more of symbol distribution patterns, sequence repetitions, ordering requirements, and compression ratio targets;
evaluating network conditions, the network conditions comprising one or more of available processing capacity, current bandwidth utilization, and end-to-end latency requirements.

3. The system of claim 1, wherein processing the data flows further comprises:
maintaining separate optimization strategies for:
different data types;
different flow characteristics; and
different network conditions; and
implementing dynamic switching between coding methods based on:
observed performance metrics;
changing data patterns; and
network state changes.

4. The system of claim 1, wherein maintaining network synchronization further comprises:
implementing version control for codebooks through:
tracking codebook versions across nodes;
managing atomic updates; and
maintaining rollback capabilities; and
coordinating updates between nodes using:
distributed consensus protocols;
conflict resolution mechanisms; and
consistency verification checks.

5. The system of claim 1, wherein each network node is further caused to:
monitor compression performance through:
tracking compression ratios;
measuring processing overhead;
calculating end-to-end latency; and
evaluating resource utilization; and
adapt compression strategies based on:
historical performance data;
current network conditions; and
application requirements.

6. The system of claim 1, wherein processing the data flows further comprises:
implementing hybrid coding approaches by:
applying different coding methods to different parts of the same data flow;
maintaining coding method boundaries; and
managing coding method transitions; and
optimizing coding parameters based on:
observed data characteristics;
available resources; and
performance requirements.

7. The system of claim 1, wherein each network node is further caused to:
implement route optimization by:
maintaining topology awareness;
monitoring path performance metrics; and
selecting optimal routes based on flow classification; and
manage network resources through:
dynamic resource allocation;
load balancing; and
congestion avoidance.

8. The system of claim 1, wherein classifying data segments comprises:
analyzing incoming flows using:
pattern recognition algorithms;
temporal characteristics; and
application-specific requirements; and
maintaining adaptive classification thresholds based on:
historical performance data;
current network conditions; and
observed flow patterns.

9. The system of claim 1, wherein the synchronized codebook repository comprises at least:
a first codebook implementing Huffman coding;
a second codebook implementing alphabetic coding; and
a third codebook implementing Tunstall coding.

10. A method for network-optimized multi-type data compression and transmission, comprising the steps of:
maintaining, on each node of a plurality of network nodes, a synchronized codebook repository;
analyzing incoming data flows to:
classify data segments as either latency-critical or bandwidth-critical; and
determine optimal coding selection for bandwidth-critical segments;
processing the data flows by:
transmitting latency-critical segments without compression;
compressing bandwidth-critical segments using at least one selected coding method from the synchronized codebook repository; and
maintaining network synchronization by:
monitoring codebook utilization across nodes;
updating shared codebooks based on data flow patterns; and
propagating codebook updates to connected nodes.

11. The method of claim 10, wherein determining optimal coding selection comprises:
analyzing data characteristics, the data characteristics comprising one or more of symbol distribution patterns, sequence repetitions, ordering requirements, and compression ratio targets;
evaluating network conditions, the network conditions comprising one or more of available processing capacity, current bandwidth utilization, and end-to-end latency requirements.

12. The method of claim 10, wherein processing the data flows further comprises:
maintaining separate optimization strategies for:
different data types;
different flow characteristics; and
different network conditions; and
implementing dynamic switching between coding methods based on:
observed performance metrics;
changing data patterns; and
network state changes.

13. The method of claim 10, wherein maintaining network synchronization further comprises:
implementing version control for codebooks through:
tracking codebook versions across nodes;
managing atomic updates; and
maintaining rollback capabilities; and
coordinating updates between nodes using:
distributed consensus protocols;
conflict resolution mechanisms; and
consistency verification checks.

14. The method of claim 10, further comprising the steps of:
monitoring compression performance through:
tracking compression ratios;
measuring processing overhead;
calculating end-to-end latency; and
evaluating resource utilization; and
adapting compression strategies based on:
historical performance data;
current network conditions; and
application requirements.

15. The method of claim 10, wherein processing the data flows further comprises:
implementing hybrid coding approaches by:
applying different coding methods to different parts of the same data flow;
maintaining coding method boundaries; and
managing coding method transitions; and
optimizing coding parameters based on:
observed data characteristics;
available resources; and
performance requirements.

16. The method of claim 10, further comprising the steps of:
implementing route optimization by:
maintaining topology awareness;
monitoring path performance metrics; and
selecting optimal routes based on flow classification; and
managing network resources through:
dynamic resource allocation;
load balancing; and
congestion avoidance.

17. The method of claim 10, wherein classifying data segments comprises:
analyzing incoming flows using:
pattern recognition algorithms;
temporal characteristics; and
application-specific requirements; and
maintaining adaptive classification thresholds based on:
historical performance data;
current network conditions; and
observed flow patterns.

18. The method of claim 10, wherein the synchronized codebook repository comprises at least:
a first codebook implementing Huffman coding;
a second codebook implementing alphabetic coding; and
a third codebook implementing Tunstall coding.
